(19) United States
(12) Patent Application Publication
(10) Pub. No.: US 2025/0263425 A1
(43) Pub. Date: Aug. 21, 2025

(54) ORGANIC COMPOUND, COMPOSITION CONTAINING ORGANIC COMPOUND, AND ORGANIC ELECTROLUMINESCENT DEVICE

(71) Applicant: Shijiazhuang Chengzhi Yonghua Display Material Co., Ltd., Shijiazhuang, Hebei (CN)

(72) Inventors: Songyuan LIU, Shijiazhuang, Hebei (CN); Zaifeng XIE, Shijiazhuang, Hebei (CN); Feng LIANG, Shijiazhuang, Hebei (CN); Tianyu WEI, Shijiazhuang, Hebei (CN)

(73) Assignee: Shijiazhuang Chengzhi Yonghua Display Material Co., Ltd., Shijiazhuang, Hebei (CN)

(21) Appl. No.: 18/292,965

(22) PCT Filed: Dec. 13, 2023
(86) PCT No.: PCT/CN2023/138450

§ 371 Date: Jan. 29, 2024

(30) Foreign Application Priority Data
Oct. 31, 2023 (CN) 202311436169.7

(51) Int. Cl. C07F 7/08; C07F 5/02; C09K 11/06; H10K 50/12; H10K 85/40; H10K 85/60

(52) U.S. Cl. CPC C07F 7/0807; C07F 5/027; C09K 11/06; H10K 50/12; H10K 85/40; H10K 85/615; H10K 85/622; H10K 85/626; H10K 85/633; H10K 85/654; H10K 85/6574; H10K 85/658; C09K 2211/1022

(57) ABSTRACT

The present disclosure provides an organic compound, a composition containing the organic compound, and an organic electroluminescent device. The general structural formula of the organic compound is as shown in Formula I. The organic compound has a better electron-donating ability and a larger steric hindrance, which can effectively avoid the aggregation between doping material molecules and avoid the problem of a decreased efficiency of an organic electroluminescent device caused by concentration quenching; in addition, the composition containing the organic compound can not only regulate the balance of carrier transport by means of interaction and reduce the energy difference between a singlet state and a triplet state of the doping material, but also make the energy transmission in the luminescent material more sufficient. When the composition provided by the present invention is applied to a luminescent layer of a blue organic electroluminescent device, the luminescent layer material can improve the luminous efficiency of the blue organic electroluminescent device, prolong the lifetime of the blue organic electroluminescent device and overcome the defects in the prior art.

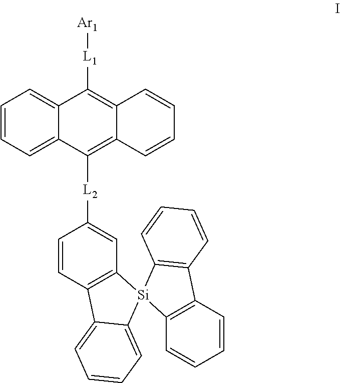

### TECHNICAL FIELD

The present invention belongs to the technical field of OLED and in particular relates to an organic compound, a composition containing the organic compound, and an organic electroluminescent device.

### BACKGROUND ART

Organic Light-Emitting Diode (OLED) is a display lighting technology which have been developed gradually in recent years. Especially in the display industry, OLED display has been widely concerned due to its advantages of high response, high contrast, flexibility, etc. At present, pixel units of full-color OLED display screens on the market are all composed of three primary colors, i.e., red, green and blue. According to the trichromatic theory, various colors can be generated by controlling the gray scales of the monochromatic colors red, green and blue of sub-pixel units, thus displaying color pictures. In three-color light-emitting devices, compared with red light and green light materials, a blue light material has a higher energy and can undergo energy transfer to low-energy organic luminescent materials of green light, yellow light, red light, etc., and according to the trichromatic theory, blue light emission is the basis of realizing white and colored display. Therefore, blue light materials are the focus of research in the field of organic photoelectric materials.

At present, in almost all luminescent layers in blue organic electroluminescent devices, host-guest doped luminescent systems are used, that is, electroluminescence is realized by doping a host material with a guest doping material. Generally, the luminous energy of the host material is necessarily larger than that of the guest doping material, and the luminescent layer where the host material is located is the main area for carrier recombination, and the carriers recombine in the luminescent layer to generate excitons. After absorbing the energy of the excitons, the host material transfers or transmits it to the guest doping material by means of Forster and Dexter energy transfers, so that the guest doping material is excited and emits light.

However, luminescent layers in existing blue organic electroluminescent devices are mainly made of a single host material, which cannot effectively regulate the transport of holes and electrons. Usually, the transport speed of holes is faster than that of electrons, which easily leads to imbalanced carrier recombination and in severe cases may affect the range of the exciton recombination region, thus reducing the luminous efficiency of the organic electroluminescent device. In addition, commonly used blue boron-nitrogen doping materials have planarity in their parent nucleus structures, and the doping material molecules tend to aggregate during film formation, causing concentration quenching, which seriously affects the efficiency and lifetime of organic electroluminescent devices. Therefore, it is urgent to develop a new luminescent layer material for organic electroluminescent devices.

### SUMMARY OF THE INVENTION

In view of this, the present invention provides an organic compound, a composition containing the organic compound, and an organic electroluminescent device. The organic compound has a better electron-donating ability and a larger steric hindrance, which can effectively avoid the aggregation between doping material molecules and avoid the problem of a decreased efficiency of the organic electroluminescent device caused by concentration quenching; in addition, the composition containing the organic compound can not only regulate the balance of carrier transport by means of interaction and reduce the energy difference between a singlet state and a triplet state of the doping material, but also make the energy transmission in the luminescent material more sufficient. When the composition provided by the present invention is applied to a luminescent layer of a blue organic electroluminescent device, the luminescent layer material can improve the luminous efficiency of the blue organic electroluminescent device, prolong the lifetime of the blue organic electroluminescent device and overcome the defects in the prior art.

In order to achieve the object of the present invention, the present invention uses the following technical solution: a first aspect of the present invention provides an organic compound, and the general structural formula of the organic compound is as shown in Formula I:

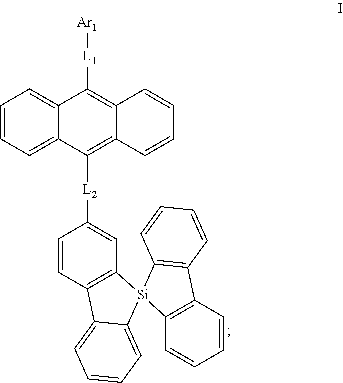

wherein Ar₁ is selected from a substituted or unsubstituted aryl group with a carbon atom number of 6 to 60 and a substituted or unsubstituted fused cyclic aryl group with a carbon atom number of 10 to 60;
L₁ and L₂ are each independently selected from a single bond and a substituted or unsubstituted arylene group with a carbon atom number of 6 to 30; and
when any one of Ar₁, L₁, and L₂ has substituents, Ar₁, L₁, or L₂ can have one or more substituents, and each of the substituents is independently selected from deuterium, an aryl group with a carbon atom number of 6 to 30, and a fused cyclic aryl group with a carbon atom number of 10 to 30.

Comparing the compound containing a 5,5-spirosilafluorene structure provided according to the first aspect of the present invention with a compound containing only carbon or aryl silane, the compound containing the 5,5-spirosilafluorene structure as provided by the first aspect of the present invention has a better electron-donating ability, and the 5,5-spirosilafluorene structure has a larger steric hindrance, which can effectively avoid the aggregation between doping material molecules and avoid the problem of a decreased efficiency of the organic electroluminescent device caused by concentration quenching.

In conjunction with the first aspect, Ar₁ is selected from any one of or a combination of any two of phenyl, naphthyl, phenanthryl, pyrenyl, dimethylfluorenyl, and dimethylbenzofluorenyl.

In conjunction with the first aspect, the compound represented by Formula I is selected from any one of the following compounds:

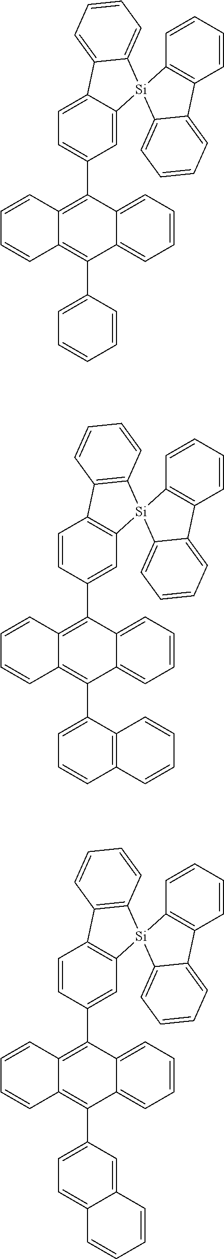 [SMILES: c1ccc(-c2c3ccccc3c(-c3ccc4c(c3)[Si]3(c5ccccc5-c5ccccc53)c3ccccc3-4)c3ccccc23)cc1 ; c1ccc2c(c1)-c1ccccc1[Si]21c2ccccc2-c2ccc(-c3c4ccccc4c(-c4cccc5ccccc45)c4ccccc34)cc21 ; c1ccc2c(c1)-c1ccccc1[Si]21c2ccccc2-c2ccc(-c3c4ccccc4c(-c4ccc5ccccc5c4)c4ccccc34)cc21]

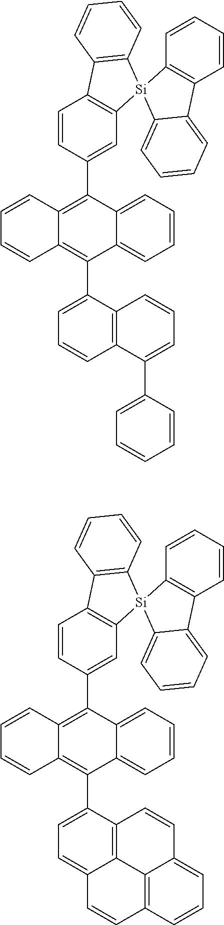 [SMILES: c1ccc(-c2cccc3c(-c4c5ccccc5c(-c5ccc6c(c5)[Si]5(c7ccccc7-c7ccccc75)c5ccccc5-6)c5ccccc45)cccc23)cc1 ; c1ccc2c(c1)-c1ccccc1[Si]21c2ccccc2-c2ccc(-c3c4ccccc4c(-c4ccc5ccc6cccc7ccc4c5c67)c4ccccc34)cc21]

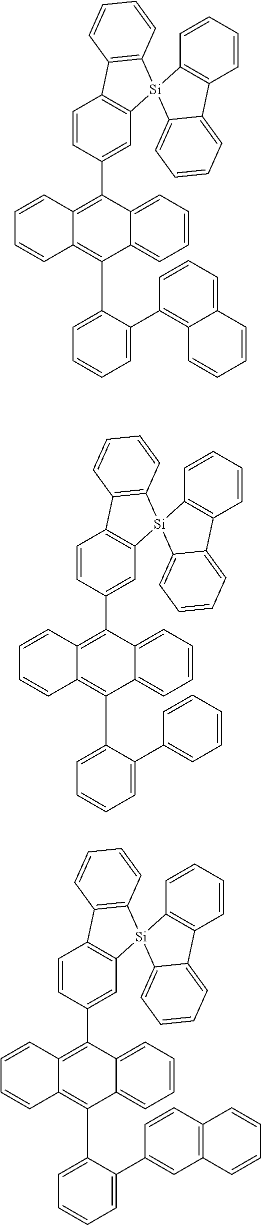

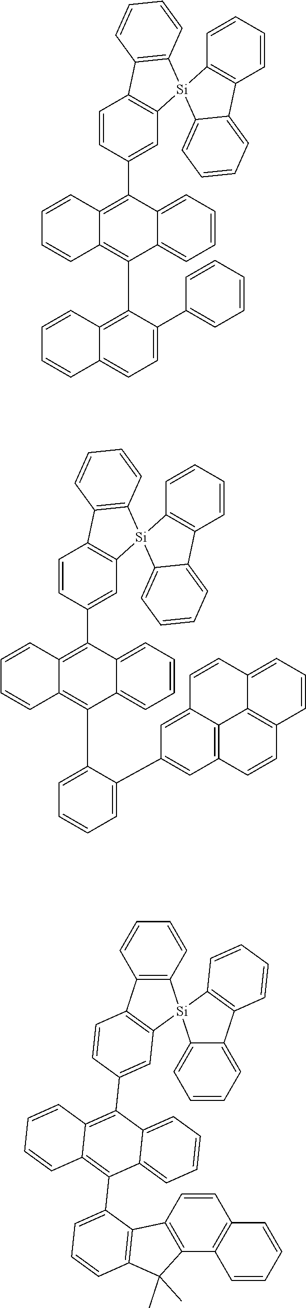 [SMILES: c1ccc(-c2ccc3ccccc3c2-c2c3ccccc3c(-c3ccc4c(c3)[Si]3(c5ccccc5-c5ccccc53)c3ccccc3-4)c3ccccc23)cc1 ; c1ccc(-c2c3ccccc3c(-c3ccc4c(c3)[Si]3(c5ccccc5-c5ccccc53)c3ccccc3-4)c3ccccc23)c(-c2cc3ccc4cccc5ccc(c2)c3c45)c1 ; CC1(C)c2cccc(-c3c4ccccc4c(-c4ccc5c(c4)[Si]4(c6ccccc6-c6ccccc64)c4ccccc4-5)c4ccccc34)c2-c2ccc3ccccc3c21]

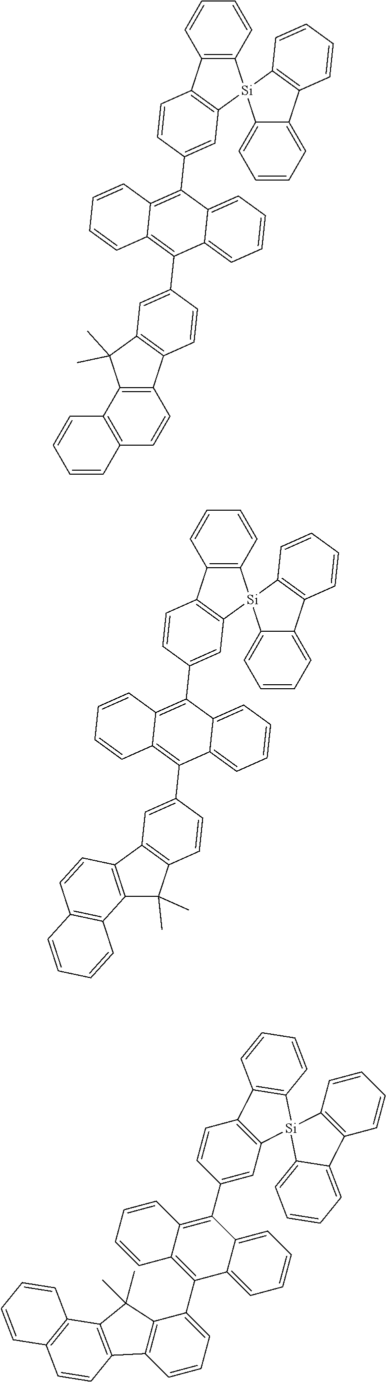 [SMILES: CC1(C)c2cc(-c3c4ccccc4c(-c4ccc5c(c4)[Si]4(c6ccccc6-c6ccccc64)c4ccccc4-5)c4ccccc34)ccc2-c2ccc3ccccc3c21 ; CC1(C)c2ccc(-c3c4ccccc4c(-c4ccc5c(c4)[Si]4(c6ccccc6-c6ccccc64)c4ccccc4-5)c4ccccc34)cc2-c2ccc3ccccc3c21 ; CC1(C)c2c(cccc2-c2c3ccccc3c(-c3ccc4c(c3)[Si]3(c5ccccc5-c5ccccc53)c3ccccc3-4)c3ccccc23)-c2ccc3ccccc3c21]

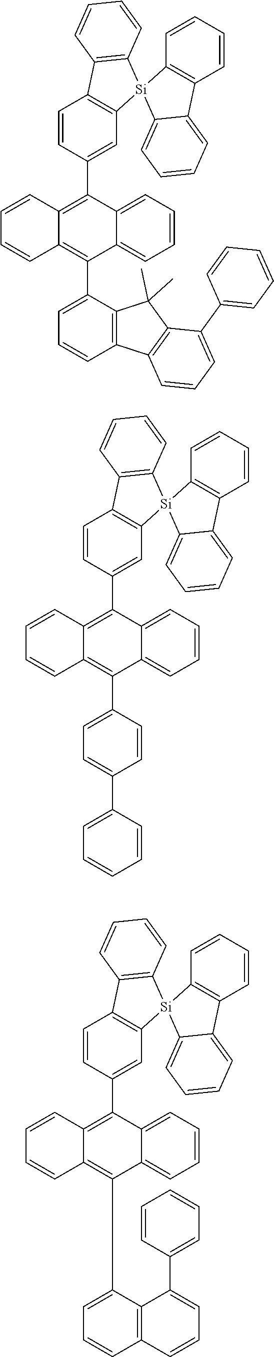

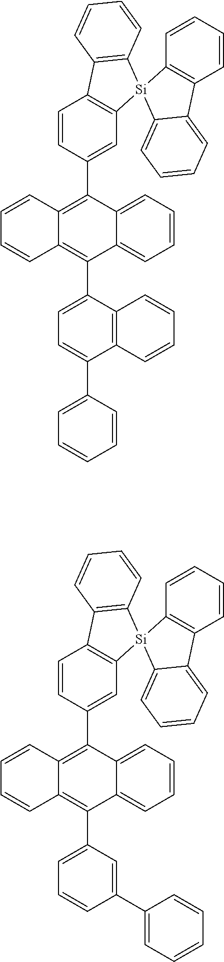 [SMILES: c1ccc(-c2ccc(-c3c4ccccc4c(-c4ccc5c(c4)[Si]4(c6ccccc6-c6ccccc64)c4ccccc4-5)c4ccccc34)c3ccccc23)cc1 ; c1ccc(-c2cccc(-c3c4ccccc4c(-c4ccc5c(c4)[Si]4(c6ccccc6-c6ccccc64)c4ccccc4-5)c4ccccc34)c2)cc1]

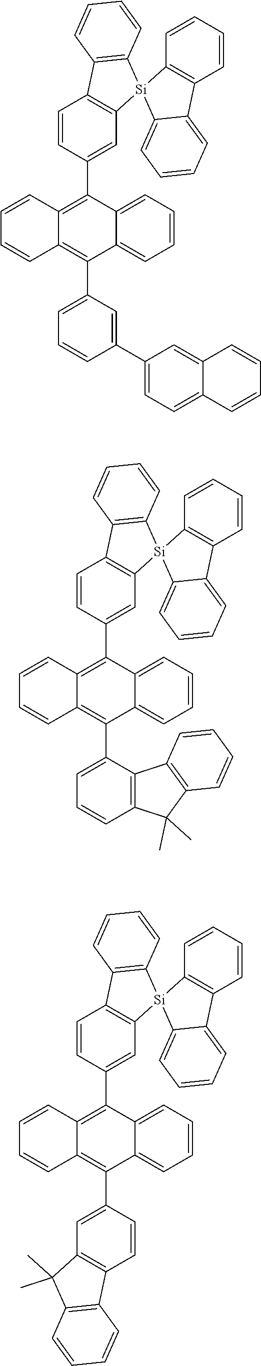 [SMILES: c1cc(-c2ccc3ccccc3c2)cc(-c2c3ccccc3c(-c3ccc4c(c3)[Si]3(c5ccccc5-c5ccccc53)c3ccccc3-4)c3ccccc23)c1 ; CC1(C)c2ccccc2-c2c(-c3c4ccccc4c(-c4ccc5c(c4)[Si]4(c6ccccc6-c6ccccc64)c4ccccc4-5)c4ccccc34)cccc21 ; CC1(C)c2ccccc2-c2ccc(-c3c4ccccc4c(-c4ccc5c(c4)[Si]4(c6ccccc6-c6ccccc64)c4ccccc4-5)c4ccccc34)cc21]

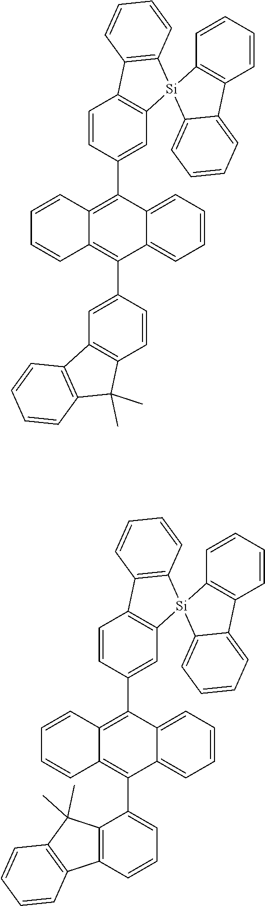 [SMILES: CC1(C)c2ccccc2-c2cc(-c3c4ccccc4c(-c4ccc5c(c4)[Si]4(c6ccccc6-c6ccccc64)c4ccccc4-5)c4ccccc34)ccc21 ; CC1(C)c2ccccc2-c2cccc(-c3c4ccccc4c(-c4ccc5c(c4)[Si]4(c6ccccc6-c6ccccc64)c4ccccc4-5)c4ccccc34)c21]

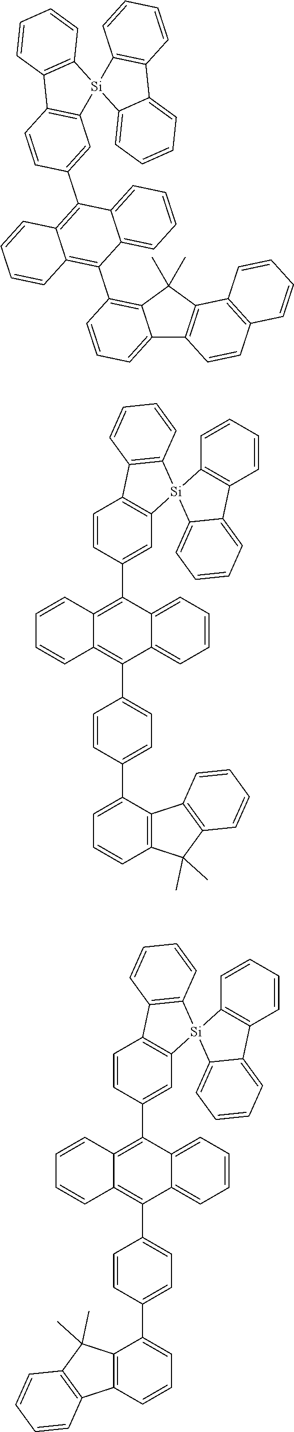

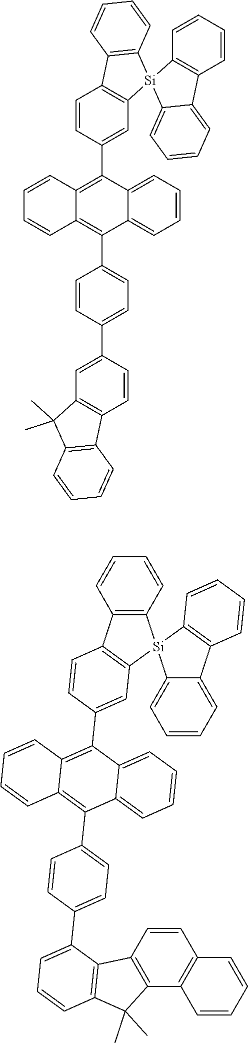 [SMILES: CC1(C)c2ccccc2-c2ccc(-c3ccc(-c4c5ccccc5c(-c5ccc6c(c5)[Si]5(c7ccccc7-c7ccccc75)c5ccccc5-6)c5ccccc45)cc3)cc21 ; CC1(C)c2cccc(-c3ccc(-c4c5ccccc5c(-c5ccc6c(c5)[Si]5(c7ccccc7-c7ccccc75)c5ccccc5-6)c5ccccc45)cc3)c2-c2ccc3ccccc3c21]

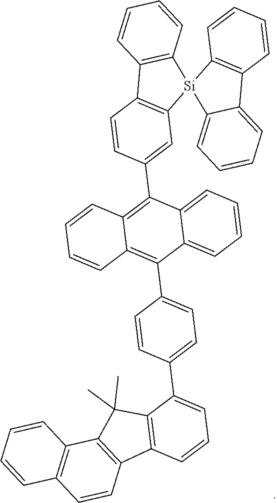 [SMILES: CC1(C)c2c(-c3ccc(-c4c5ccccc5c(-c5ccc6c(c5)[Si]5(c7ccccc7-c7ccccc75)c5ccccc5-6)c5ccccc45)cc3)cccc2-c2ccc3ccccc3c21]

A second aspect of the present invention provides a composition, comprising one or more organic compounds as described in the first aspect and further comprising one or more compounds represented by Formula II and one or more compounds represented by Formula III:

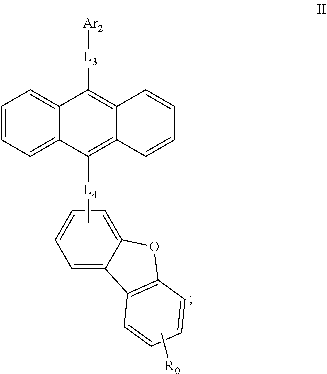

wherein Ar₂ is selected from a substituted or unsubstituted aryl group with a carbon atom number of 6 to 60 and a substituted or unsubstituted fused cyclic aryl group with a carbon atom number of 10 to 60; further preferably, Ar₂ is selected from phenyl or naphthyl;
R₀ represents a single substituent to the maximum allowable number of substituents, and each of the substituents is independently selected from hydrogen, deuterium, a substituted or unsubstituted alkyl group with a carbon atom number of 1 to 10, and a substituted or unsubstituted alkenyl group with a carbon atom number of 2 to 10, wherein two or more of the substituents can be bonded to each other via a linker group or a single bond to form a benzene ring or a fused ring;
L₃ and L₄ are each independently selected from a single bond and a substituted or unsubstituted arylene group with a carbon atom number of 6 to 30; and
when any one of Ar₂, R₀, L₃, and La has substituents, Ar₂, R₀, L₃, or L₄ can have one or more substituents, and each of the substituents is independently selected from deuterium, an aryl group with a carbon atom number of 6 to 30, and a fused cyclic aryl group with a carbon atom number of 10 to 30; and

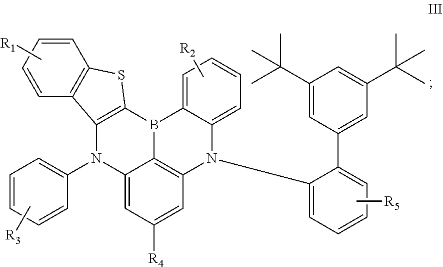

wherein R₁, R₂, R₃, and R₄ each independently represent a single substituent to the maximum allowable number of substituents, and each of the substituents is independently selected from any one of or a combination of any two or more of hydrogen, deuterium, a substituted or unsubstituted alkyl group with a carbon atom number of 1 to 10, a substituted or unsubstituted cycloalkyl group with a carbon atom number of 3 to 30, a substituted or unsubstituted aryl group with a carbon atom number of 6 to 30, and a substituted or unsubstituted arylamine group with a carbon atom number of 12 to 30, wherein two or more of the substituents can be bonded to each other via a linker group or a single bond to form an aliphatic ring, an aromatic ring, a heteroaromatic ring, a fused ring, or a fused heterocyclic ring;
R₅ represents a single substituent to the maximum allowable number of substituents, and each of the substituents is independently selected from hydrogen, deuterium, a substituted or unsubstituted alkyl group with a carbon atom number of 1 to 10, wherein two or more of the substituents can be bonded to each other via a linker group or a single bond to form an aliphatic ring, an aromatic ring, a heteroaromatic ring, a fused ring, or a fused heterocyclic ring; and when any one of R₁, R₂, R₃, R₄, and R₅ has substituents, R₁, R₂, R₃, R₄, or R₅ can have one or more substituents, and each of the substituents is independently selected from any one of deuterium, an alkyl group with a carbon atom number of 1 to 10 and a cycloalkyl group with a carbon atom number of 3 to 30.

In conjunction with the second aspect, in the composition, the mass ratio of the compound represented by Formula I to the compound represented by Formula II to the compound represented by Formula III is 49:49:2.

The composition provided according to the second aspect of the present invention comprises the organic compound represented by Formula I as described in the first aspect and further comprises a compound represented by Formula II containing a furan structure and a compound represented by Formula III containing a large steric hindrance and a thiophene structure. The compound represented by Formula I provided by the present invention contains a 5,5-spirosilafluorene structure, which has electron-pushing property and can adjust the electron cloud density on the anthracene ring so as to facilitate hole transport. The compound represented by Formula II provided by the present invention contains a furan structure, which has electron-pulling property and can adjust the electron cloud density on the anthracene ring so as to facilitate electron transport. In the present invention, the balance of carrier transport can be regulated by means of the interaction between the compound represented by Formula I and the compound represented by Formula II. The compound represented by Formula III provided by the present invention contains a large steric hindrance and a thiophene fragment, forming an asymmetric structure that has a relatively large dipole moment. There is a relatively strong dipole-dipole interaction between the compound represented by Formula II and the compound represented by Formula III, as provided by the present invention, which can enhance the FORSTER energy transmission process and contributes to reverse inter-system crossing.

In conjunction with the second aspect, the compound represented by Formula II is selected from any one of the following structures represented by Formulas II-1 to II-2:

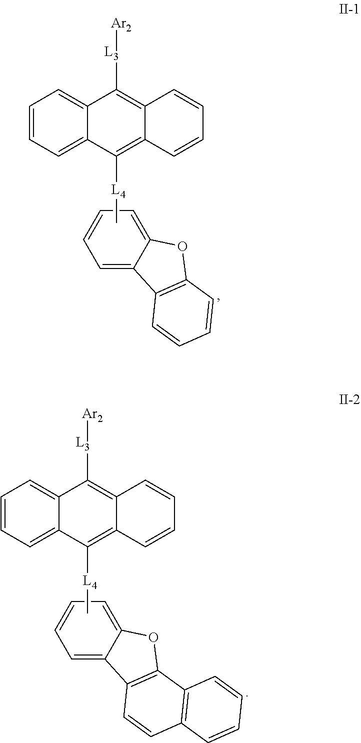

In conjunction with the second aspect, the structures represented by Formulas II-1 to II-2 are selected from any one of the following structures represented by Formulas II-11 to II-24:

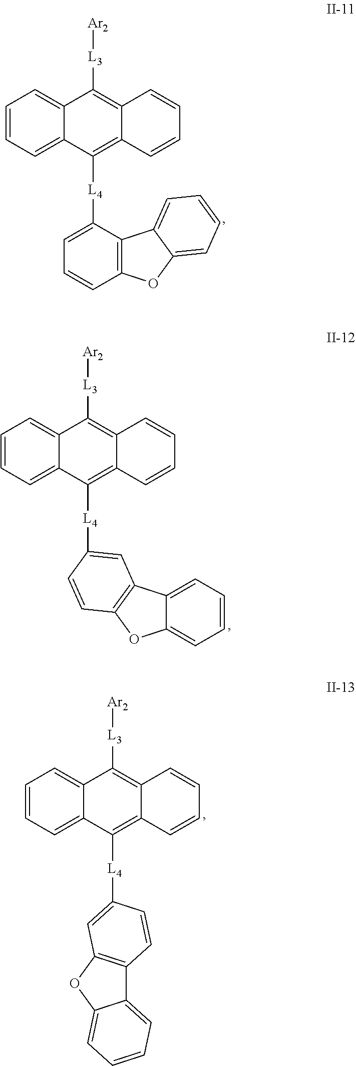

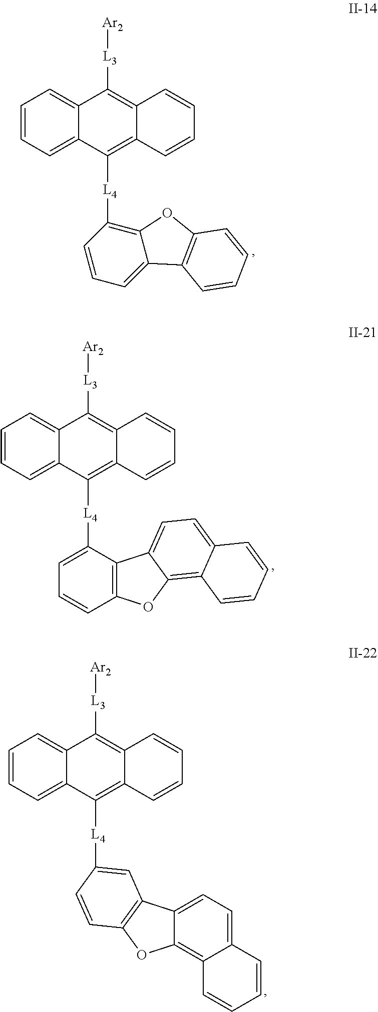

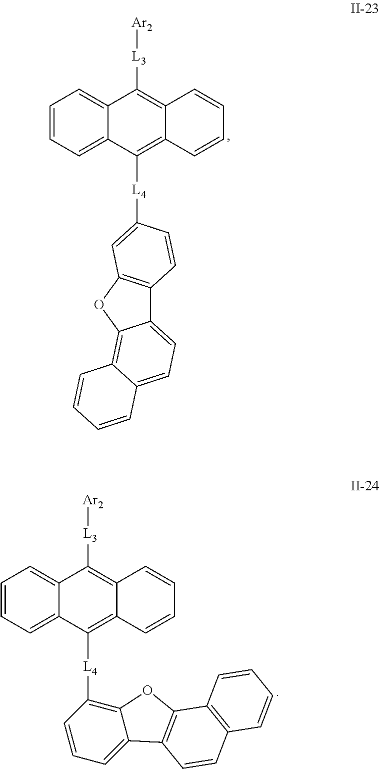

In conjunction with the second aspect, the compound represented by Formula II is selected from any one of the following compounds:

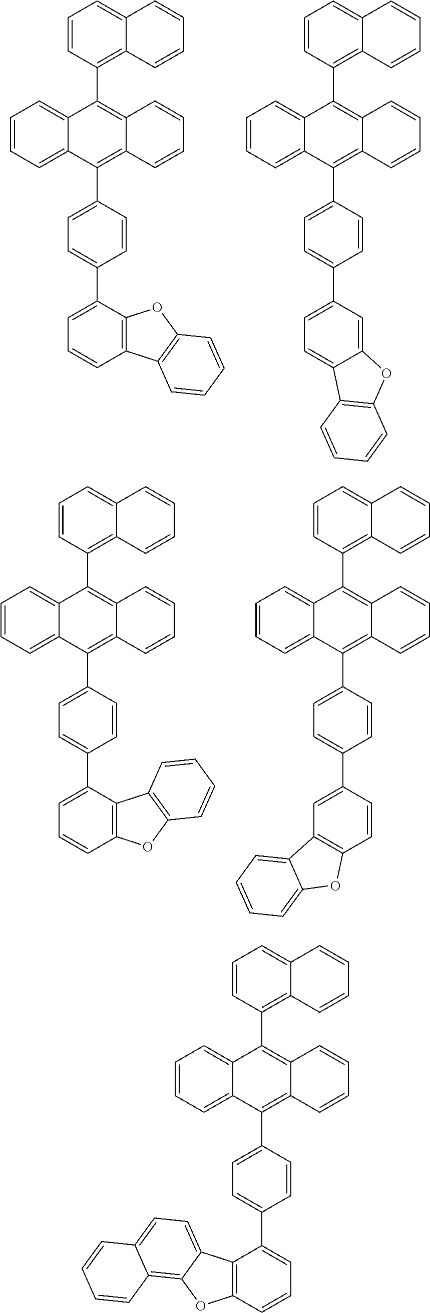

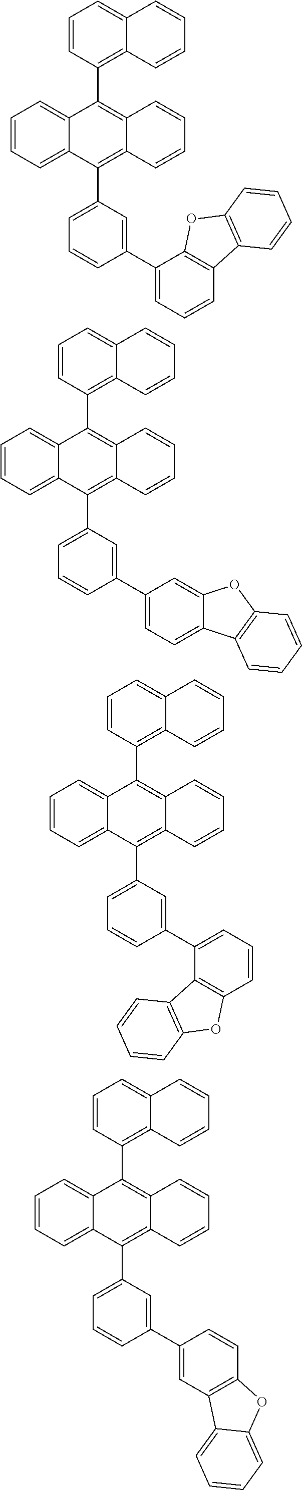

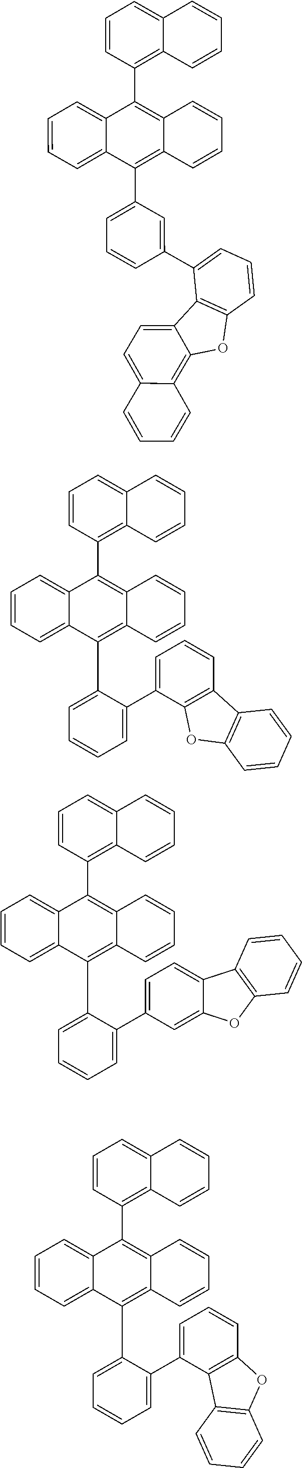

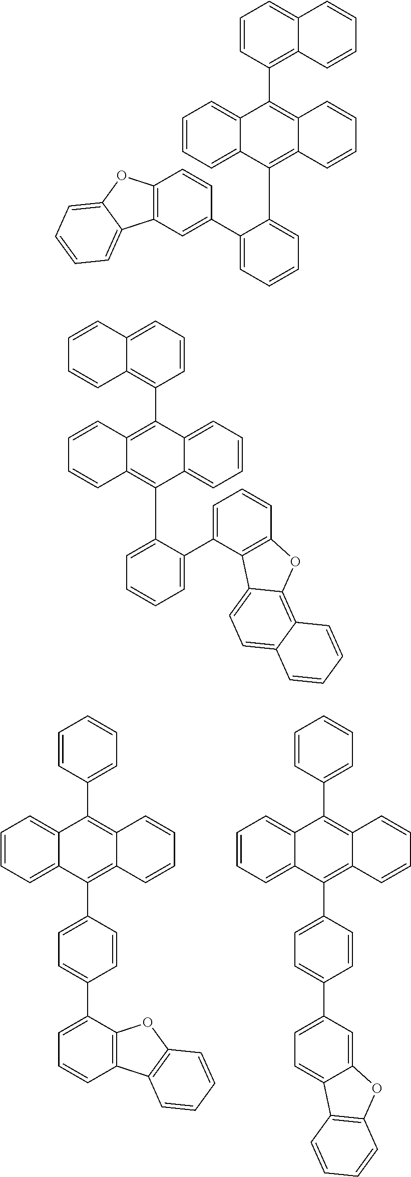

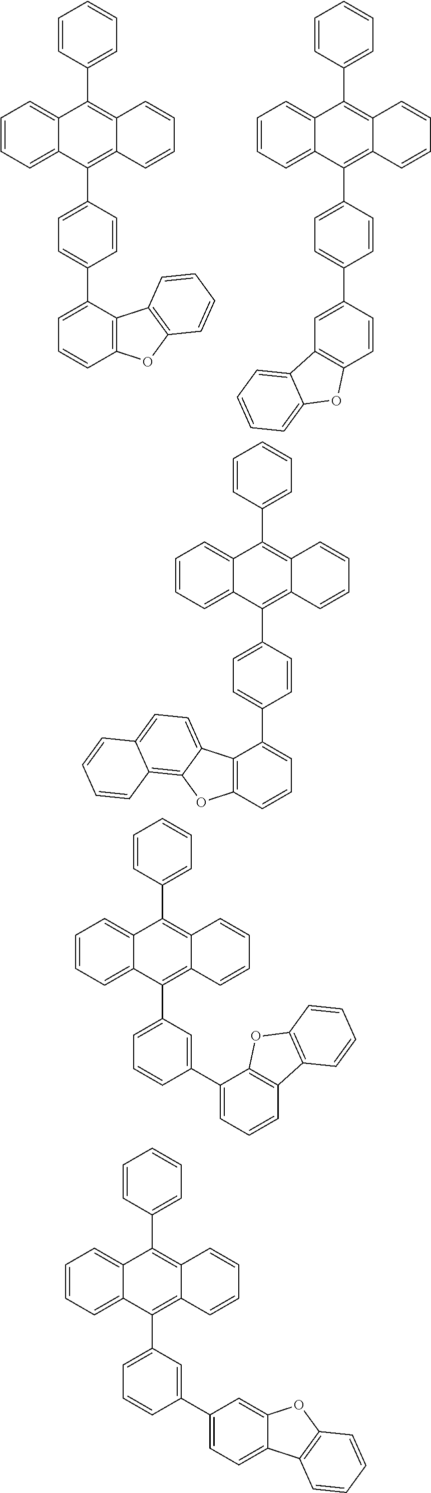

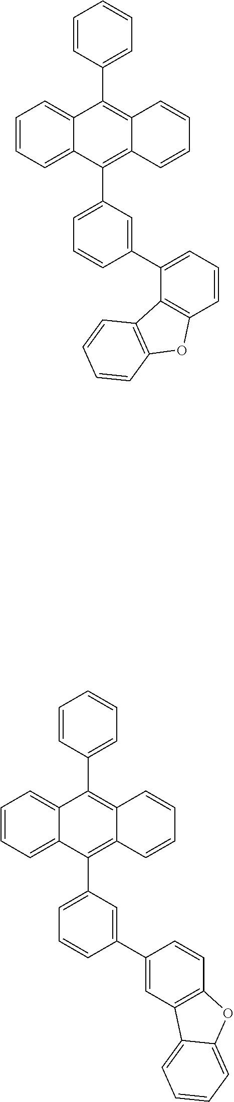 [SMILES: c1ccc(-c2c3ccccc3c(-c3cccc(-c4cccc5oc6ccccc6c45)c3)c3ccccc23)cc1 ; c1ccc(-c2c3ccccc3c(-c3cccc(-c4ccc5oc6ccccc6c5c4)c3)c3ccccc23)cc1]

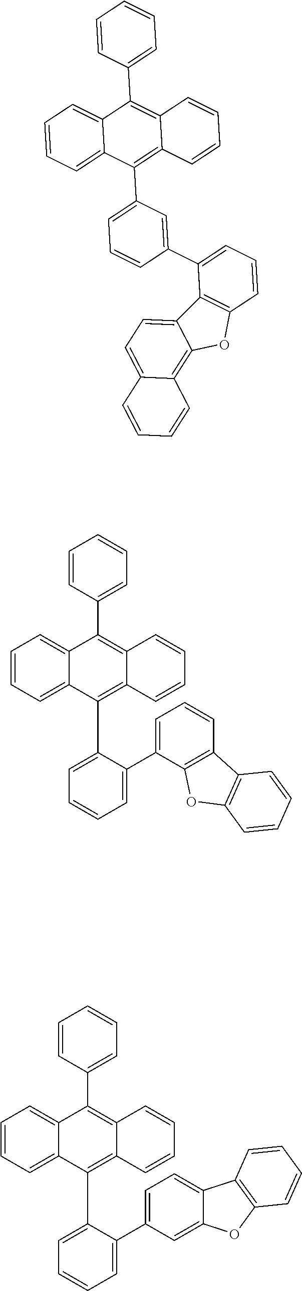 [SMILES: c1ccc(-c2c3ccccc3c(-c3cccc(-c4cccc5oc6c7ccccc7ccc6c45)c3)c3ccccc23)cc1 ; c1ccc(-c2c3ccccc3c(-c3ccccc3-c3cccc4c3oc3ccccc34)c3ccccc23)cc1 ; c1ccc(-c2c3ccccc3c(-c3ccccc3-c3ccc4c(c3)oc3ccccc34)c3ccccc23)cc1]

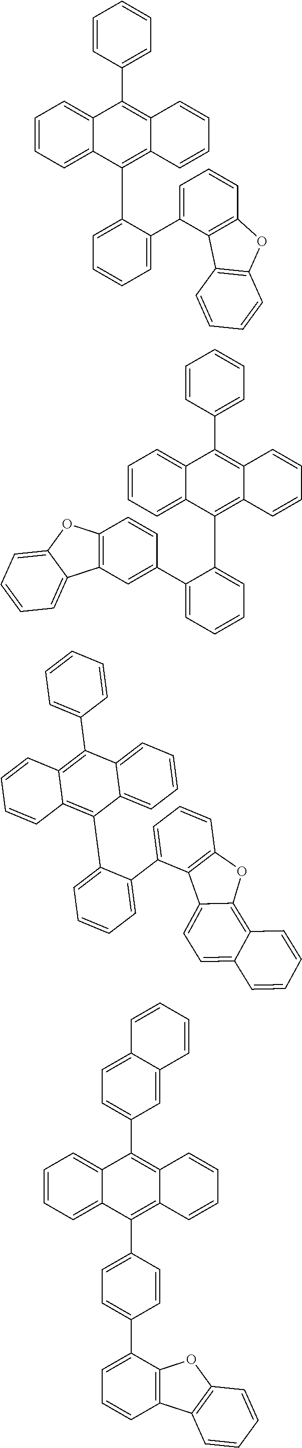

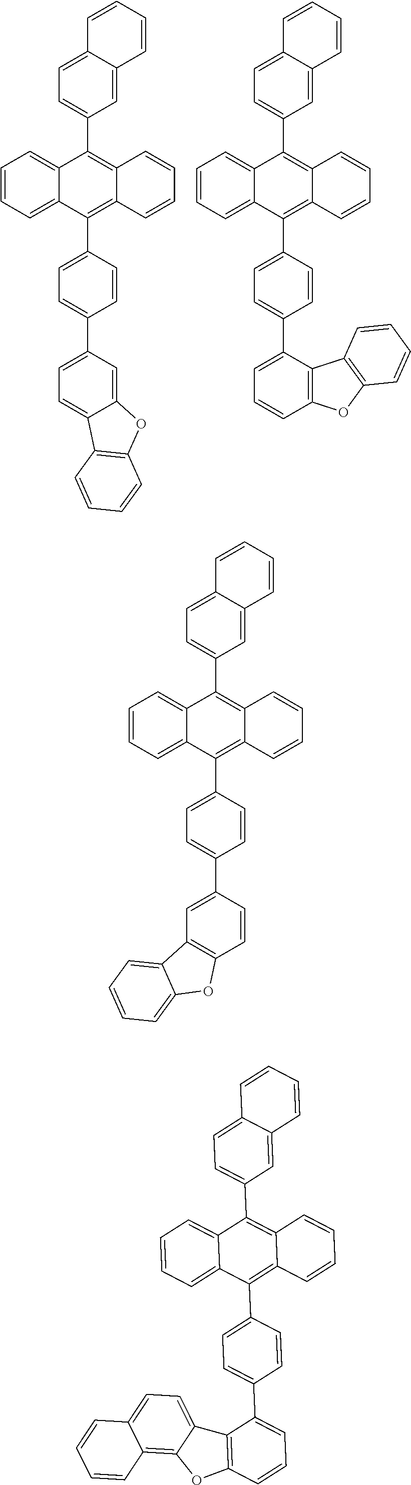

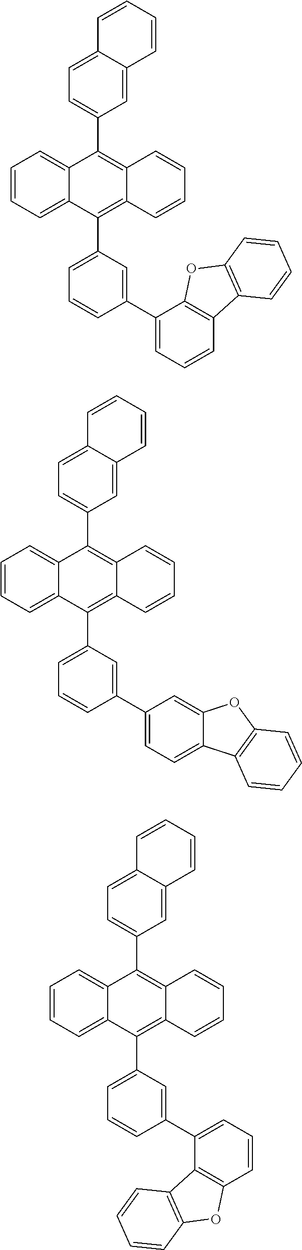 [SMILES: c1cc(-c2c3ccccc3c(-c3ccc4ccccc4c3)c3ccccc23)cc(-c2cccc3c2oc2ccccc23)c1 ; c1cc(-c2ccc3c(c2)oc2ccccc23)cc(-c2c3ccccc3c(-c3ccc4ccccc4c3)c3ccccc23)c1 ; c1cc(-c2c3ccccc3c(-c3ccc4ccccc4c3)c3ccccc23)cc(-c2cccc3oc4ccccc4c23)c1]

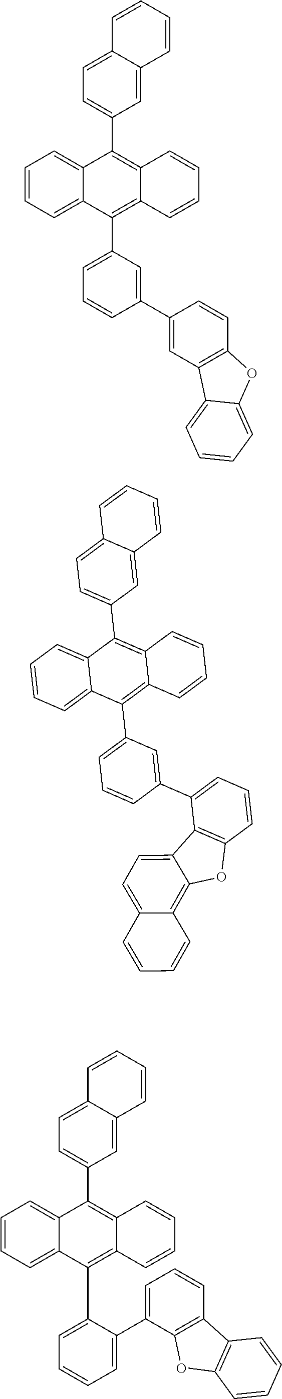 [SMILES: c1cc(-c2ccc3oc4ccccc4c3c2)cc(-c2c3ccccc3c(-c3ccc4ccccc4c3)c3ccccc23)c1 ; c1cc(-c2c3ccccc3c(-c3ccc4ccccc4c3)c3ccccc23)cc(-c2cccc3oc4c5ccccc5ccc4c23)c1 ; c1ccc(-c2cccc3c2oc2ccccc23)c(-c2c3ccccc3c(-c3ccc4ccccc4c3)c3ccccc23)c1]

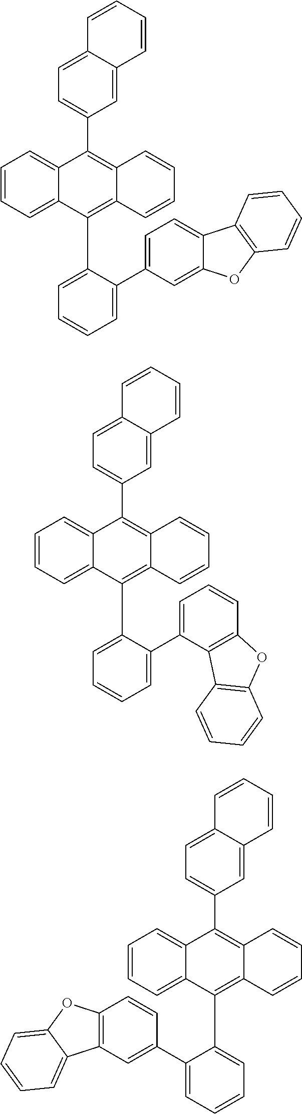

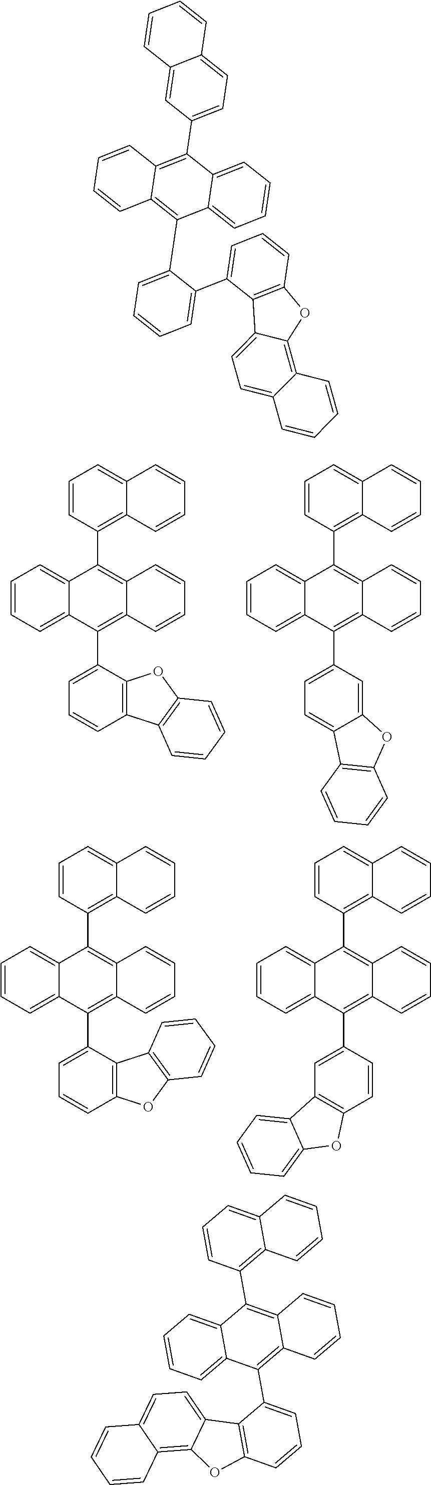

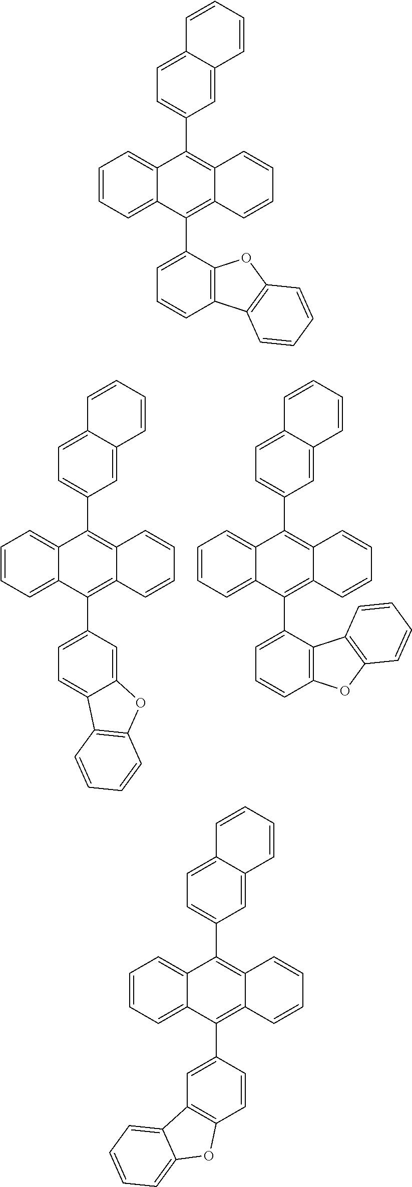

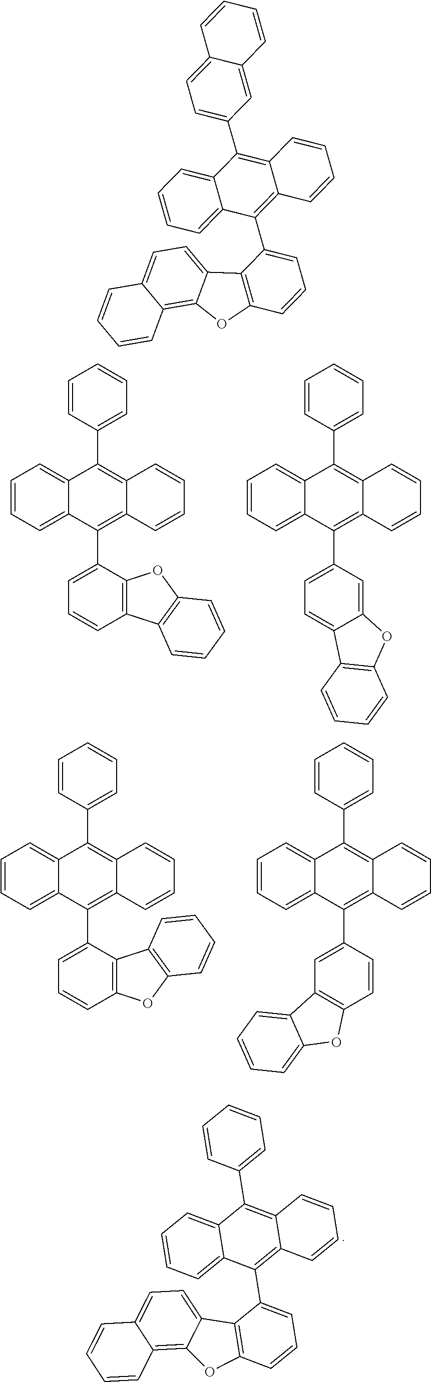

In conjunction with the second aspect, the compound represented by Formula III is selected from any one of the following structures represented by Formulas III-1 to III-2:

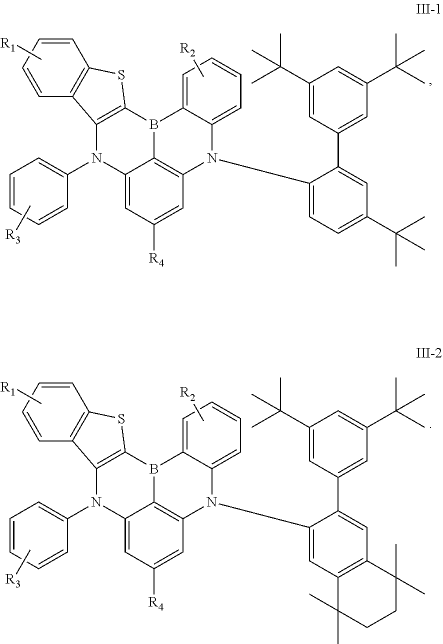

In conjunction with the second aspect, the structure represented by Formula III-1 is selected from any one of the following structures represented by Formulas III-11 to III-23:

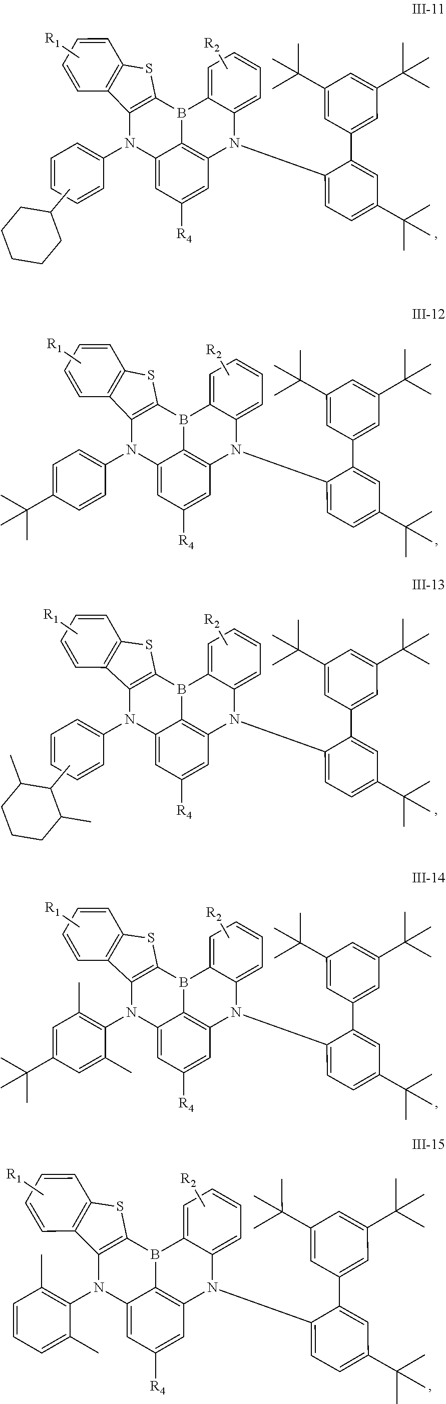

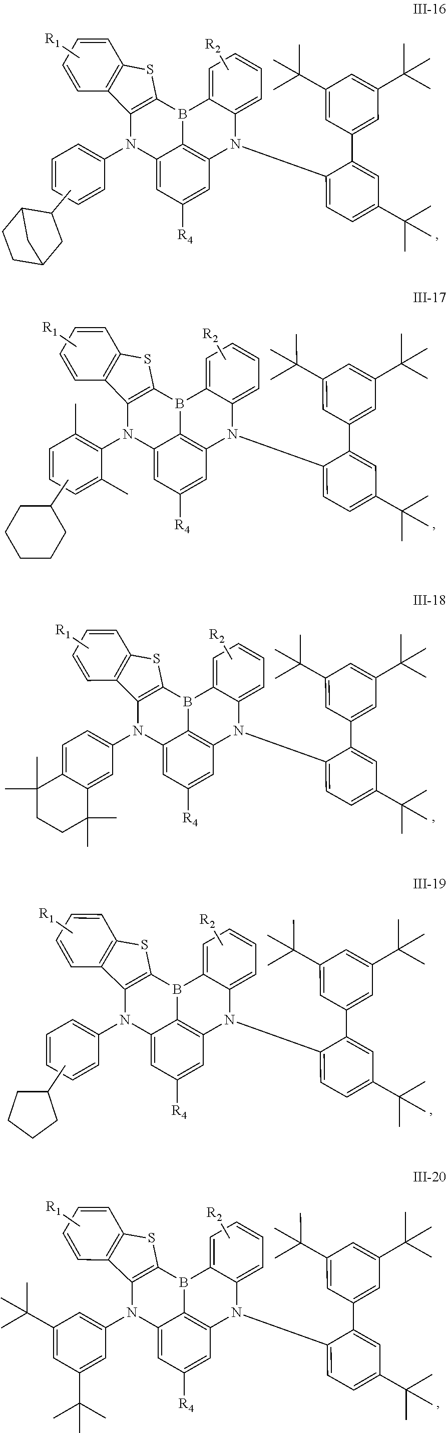

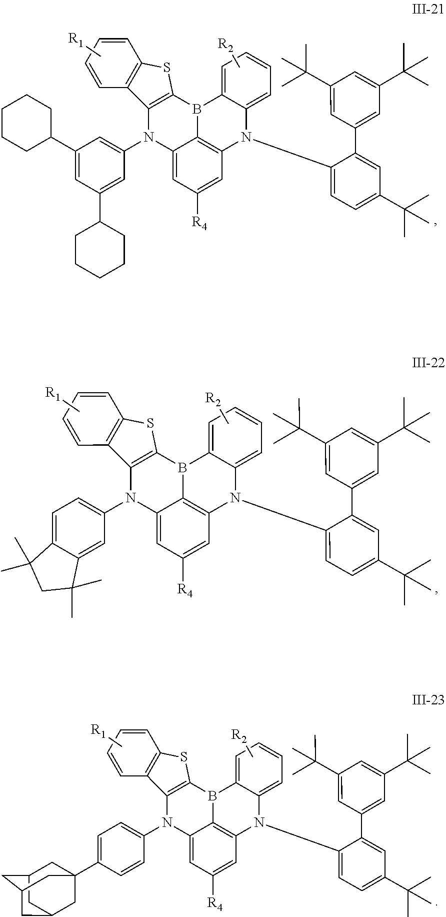

In conjunction with the second aspect, the compound represented by Formula III is selected from any one of the following compounds:

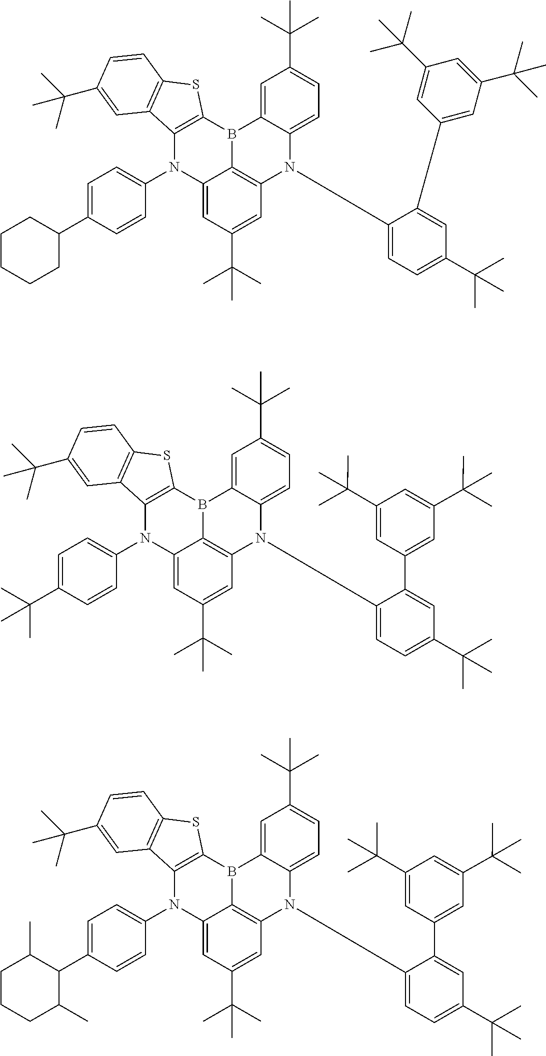

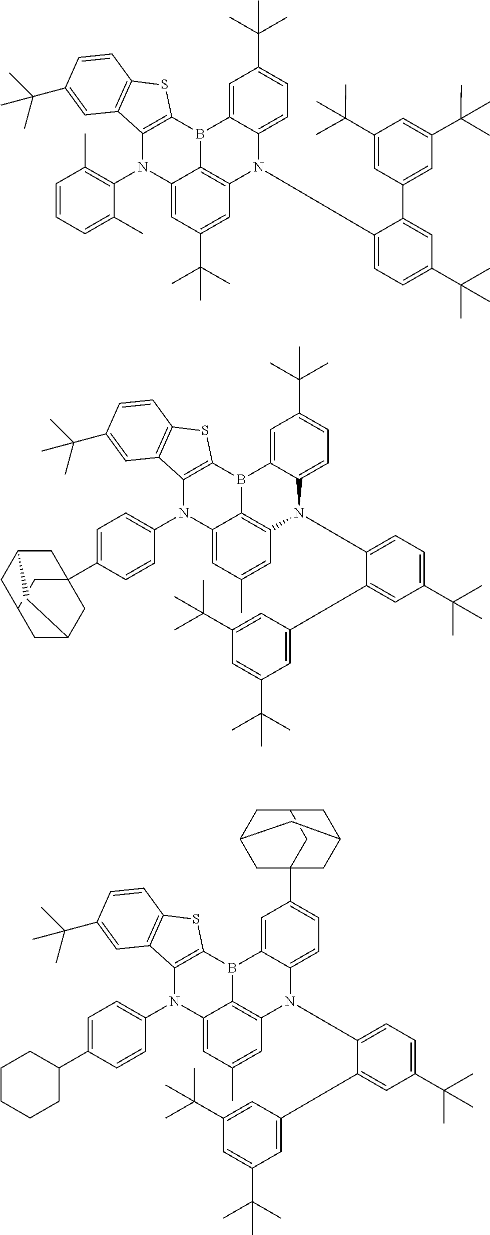

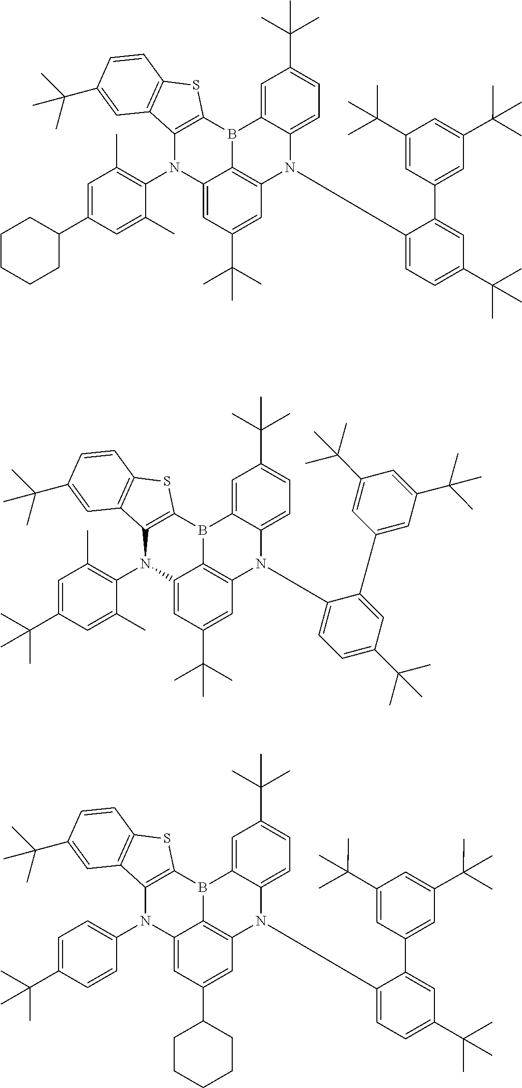

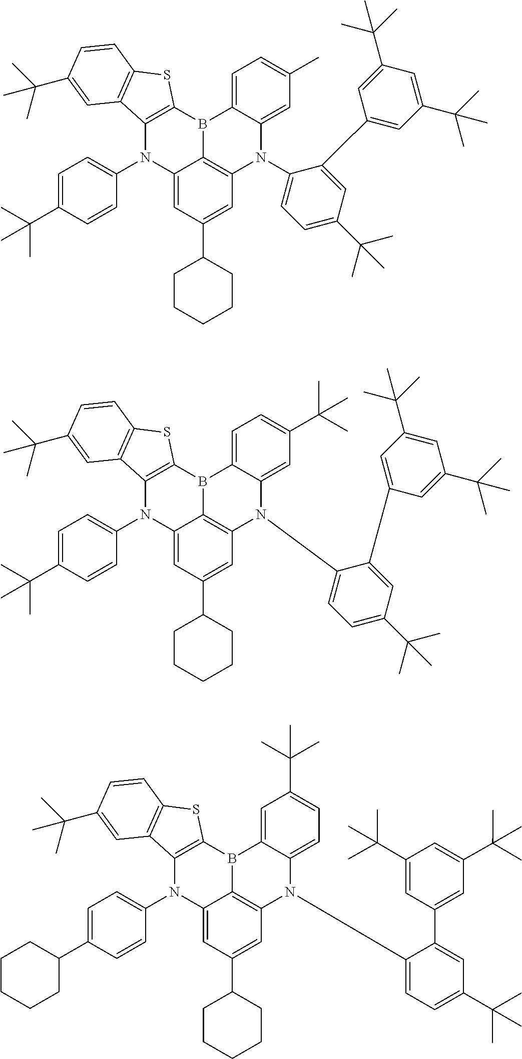

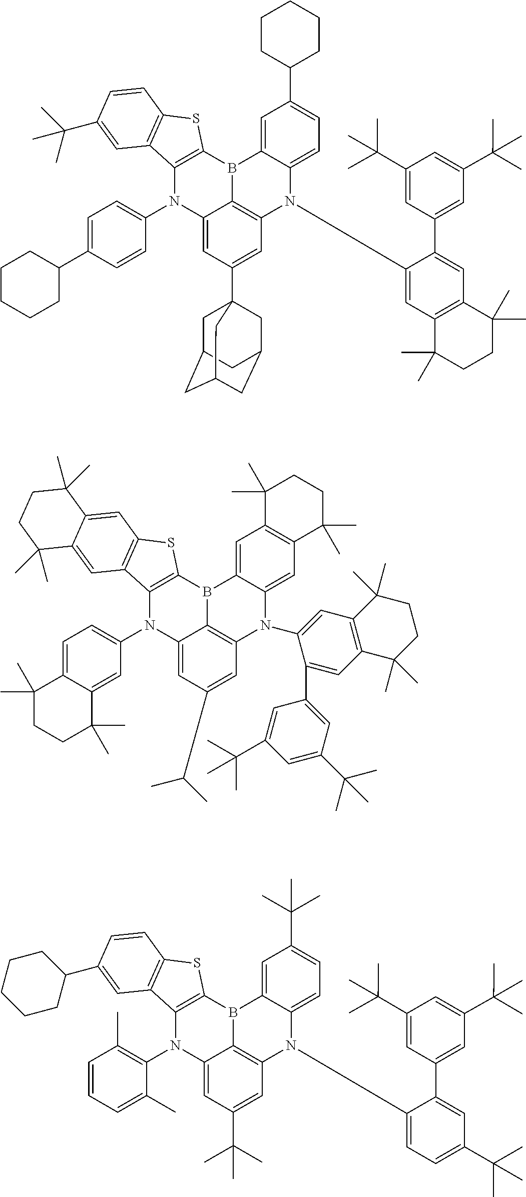

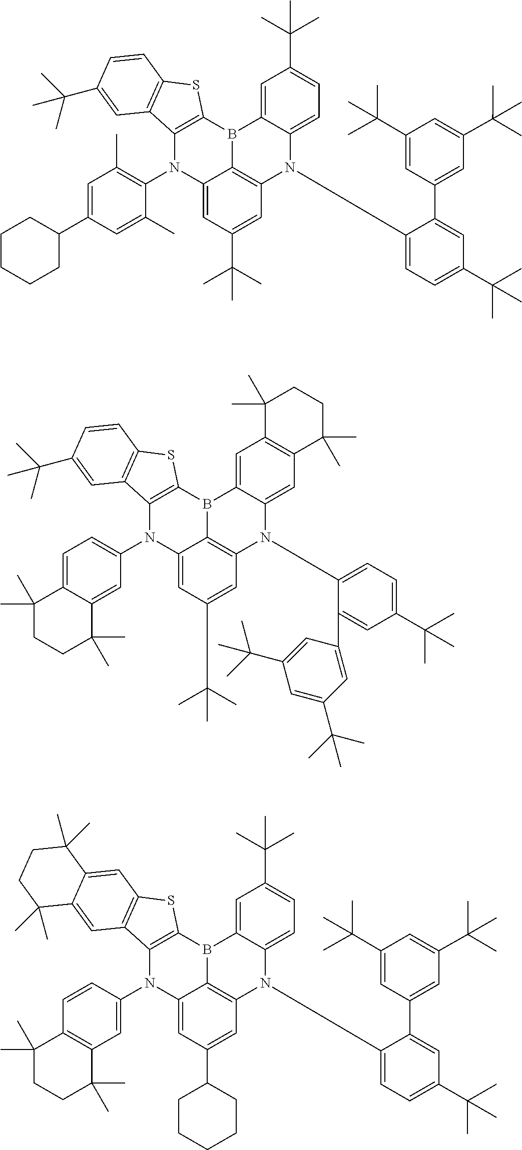

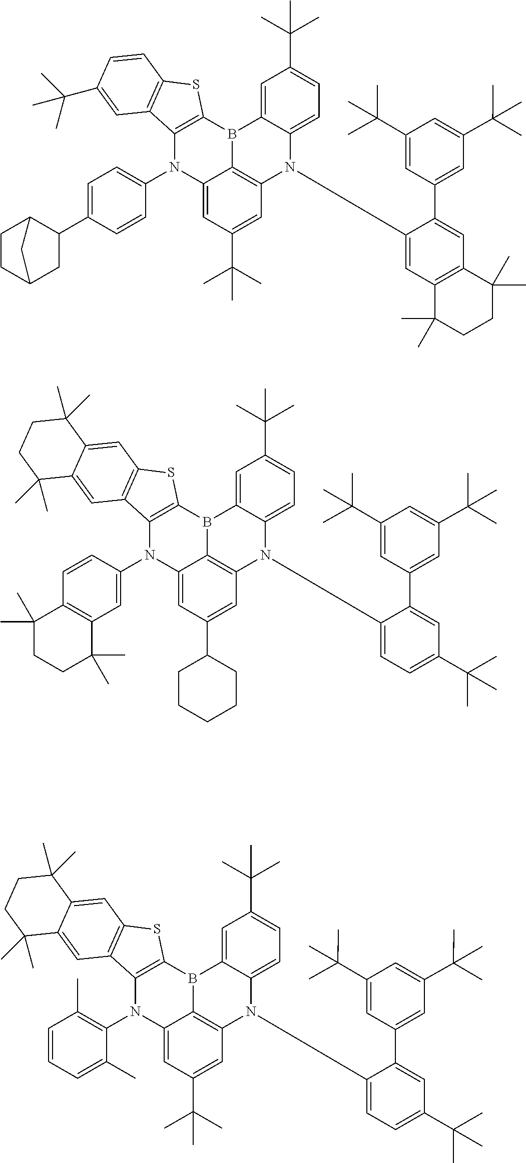

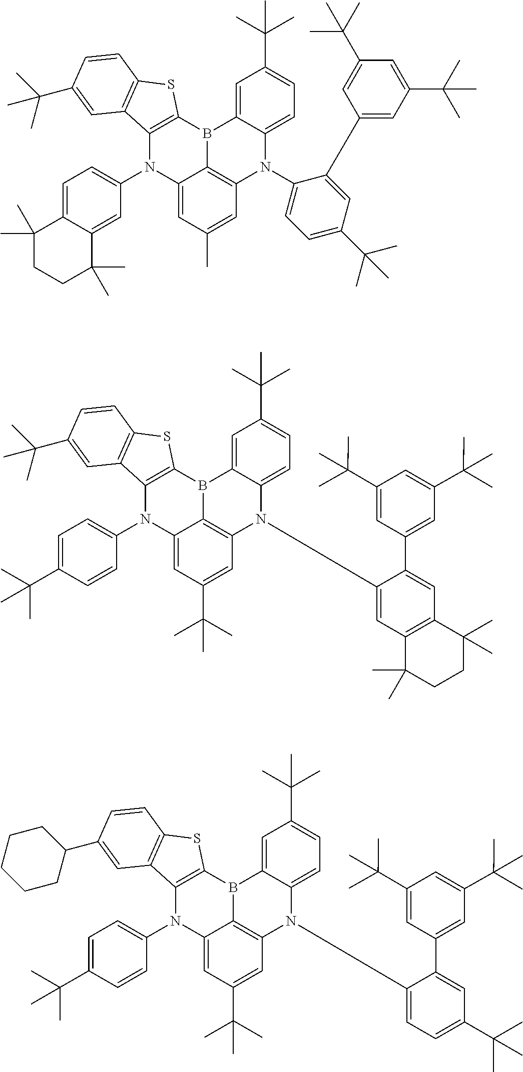

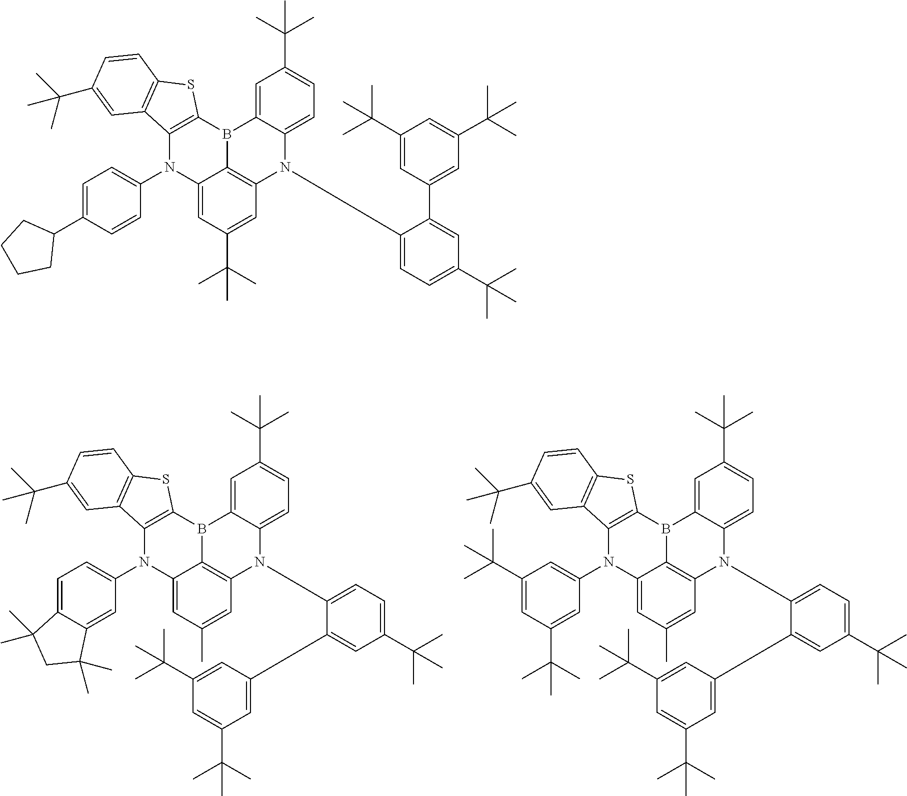 [SMILES: CC(C)(C)c1cc(-c2cc(C(C)(C)C)ccc2N2c3ccc(C(C)(C)C)cc3B3c4sc5ccc(C(C)(C)C)cc5c4N(c4ccc(C5CCCC5)cc4)c4cc(C(C)(C)C)cc2c43)cc(C(C)(C)C)c1 ; Cc1cc2c3c(c1)N(c1ccc4c(c1)C(C)(C)CC4(C)C)c1c(sc4ccc(C(C)(C)C)cc14)B3c1cc(C(C)(C)C)ccc1N2c1ccc(C(C)(C)C)cc1-c1cc(C(C)(C)C)cc(C(C)(C)C)c1 ; Cc1cc2c3c(c1)N(c1cc(C(C)(C)C)cc(C(C)(C)C)c1)c1c(sc4ccc(C(C)(C)C)cc14)B3c1cc(C(C)(C)C)ccc1N2c1ccc(C(C)(C)C)cc1-c1cc(C(C)(C)C)cc(C(C)(C)C)c1]

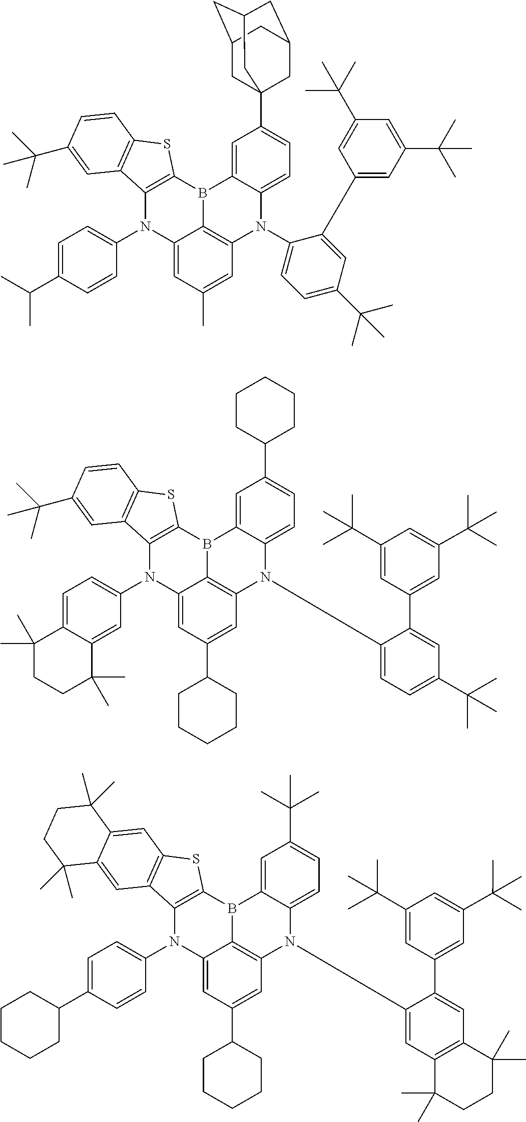

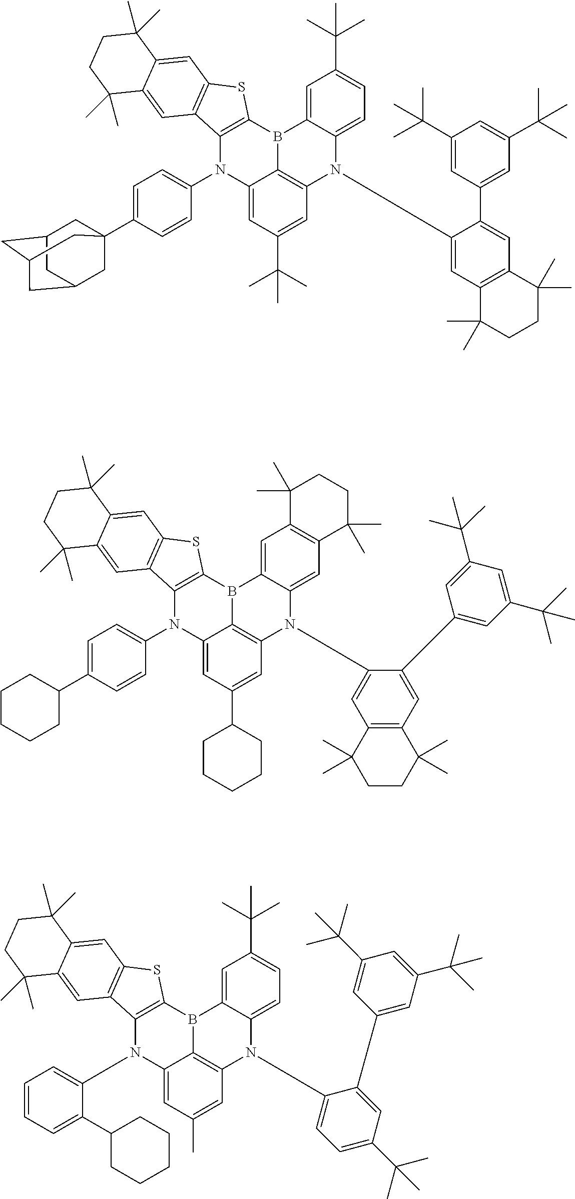

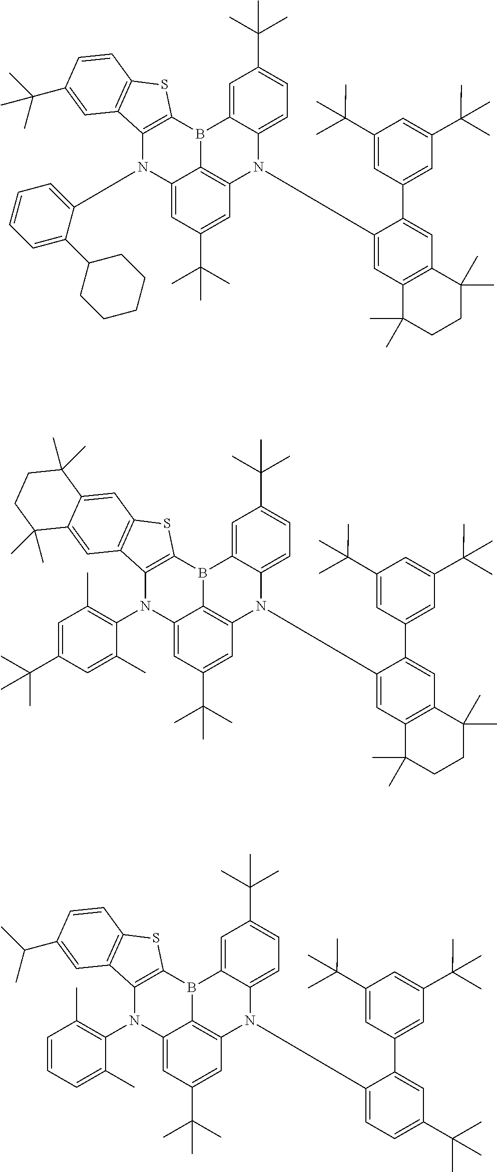

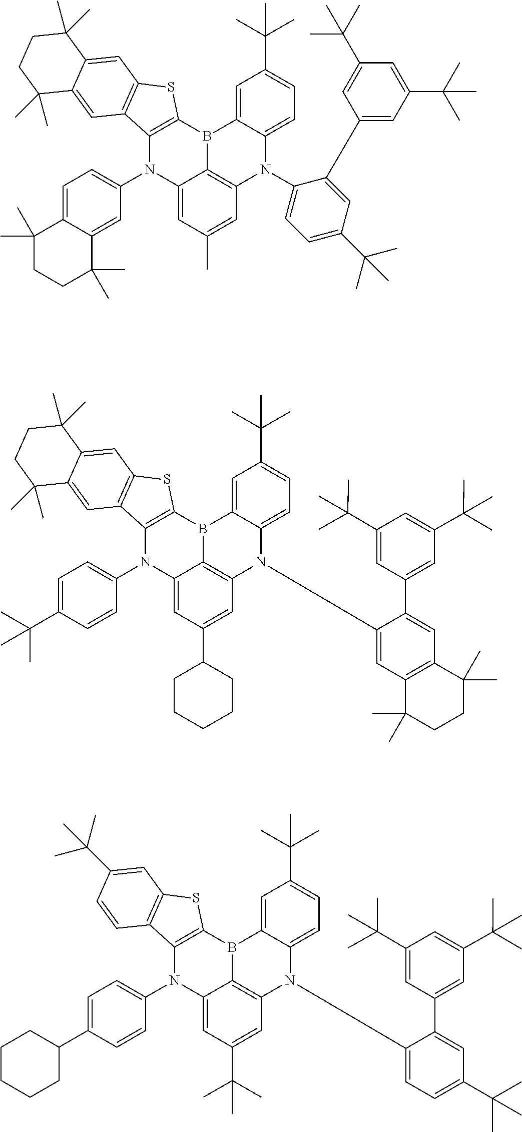

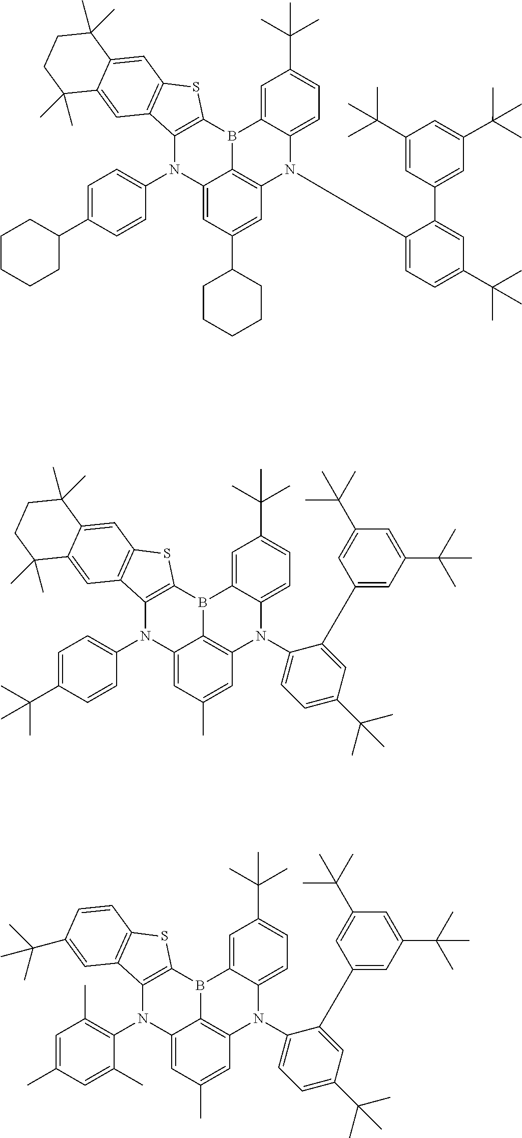

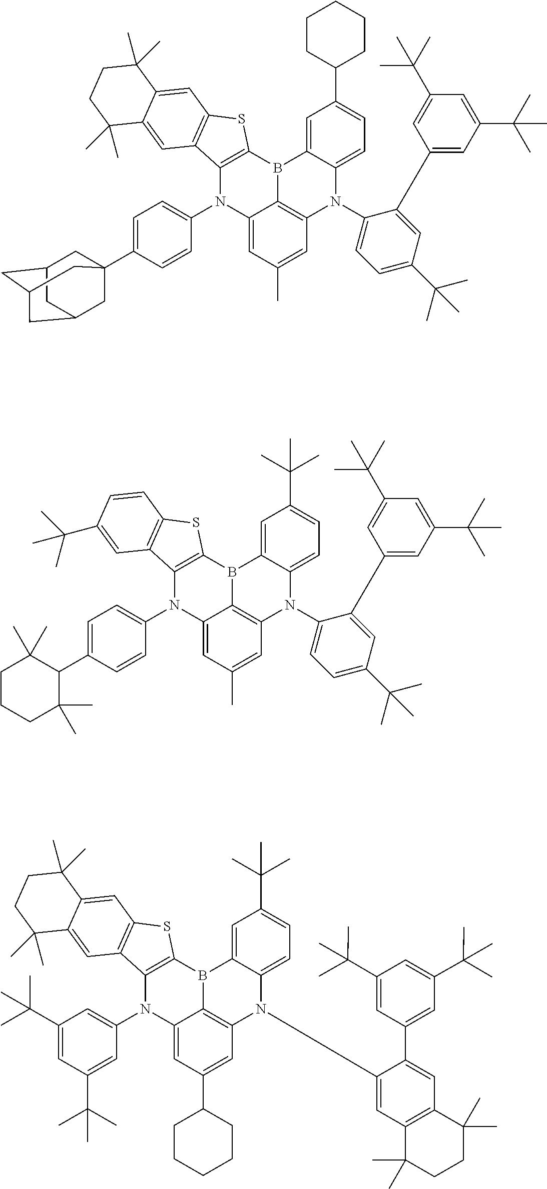

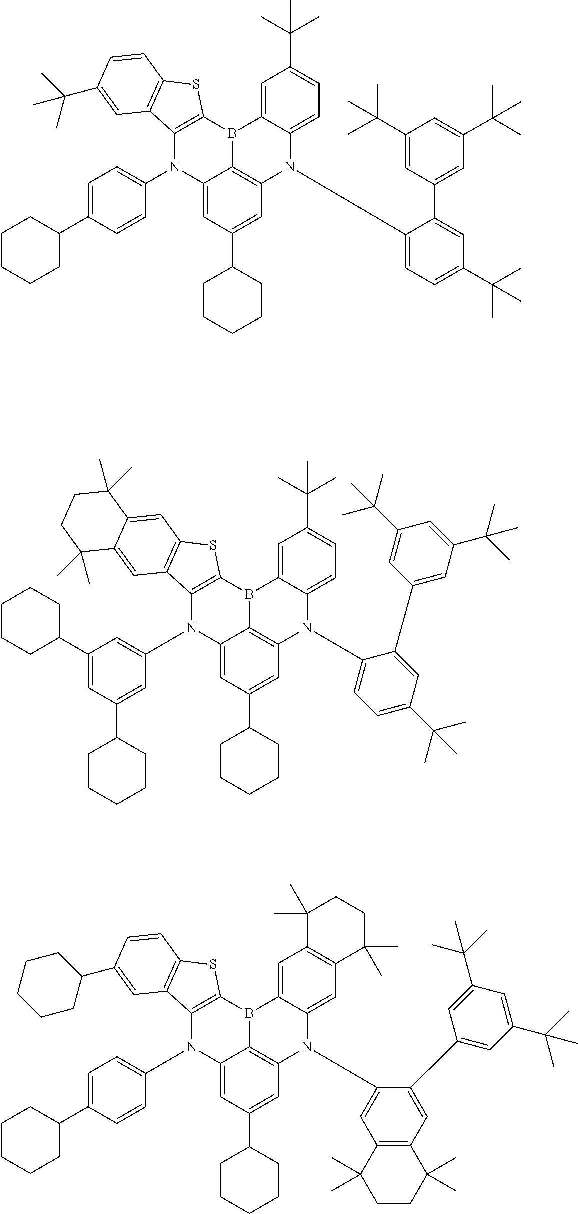 [SMILES: CC(C)(C)c1cc(-c2cc(C(C)(C)C)ccc2N2c3ccc(C(C)(C)C)cc3B3c4sc5ccc(C(C)(C)C)cc5c4N(c4ccc(C5CCCCC5)cc4)c4cc(C5CCCCC5)cc2c43)cc(C(C)(C)C)c1 ; CC(C)(C)c1cc(-c2cc(C(C)(C)C)ccc2N2c3ccc(C(C)(C)C)cc3B3c4sc5cc6c(cc5c4N(c4cc(C5CCCCC5)cc(C5CCCCC5)c4)c4cc(C5CCCCC5)cc2c43)C(C)(C)CCC6(C)C)cc(C(C)(C)C)c1 ; CC(C)(C)c1cc(-c2cc3c(cc2N2c4cc5c(cc4B4c6sc7ccc(C8CCCCC8)cc7c6N(c6ccc(C7CCCCC7)cc6)c6cc(C7CCCCC7)cc2c64)C(C)(C)CCC5(C)C)C(C)(C)CCC3(C)C)cc(C(C)(C)C)c1]

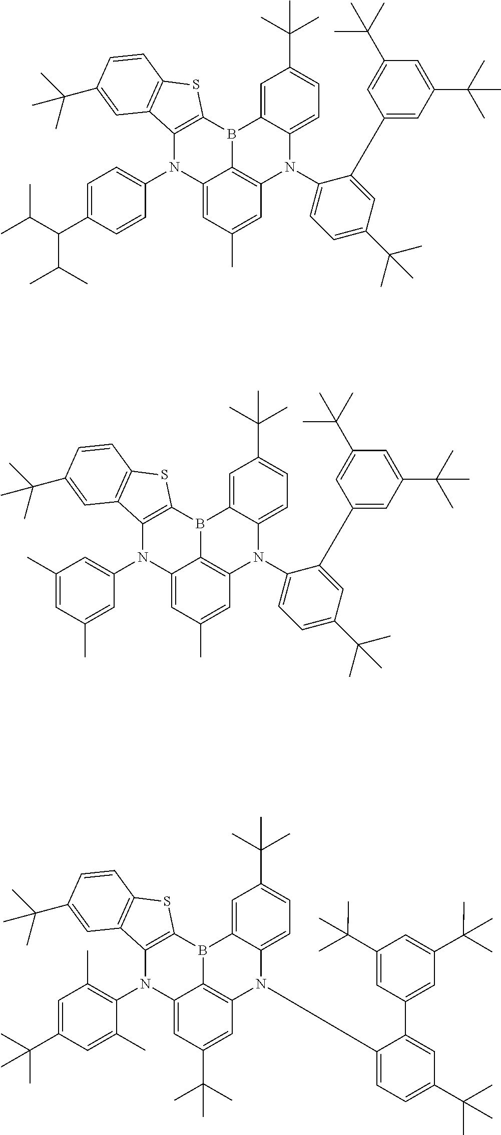

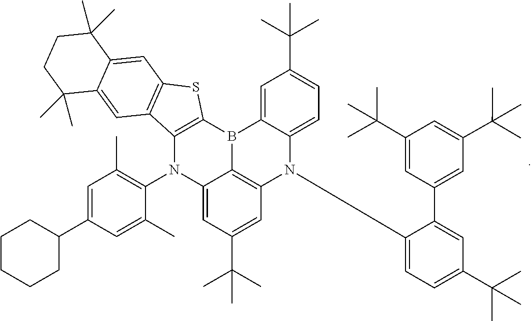 [SMILES: Cc1cc(C2CCCCC2)cc(C)c1N1c2cc(C(C)(C)C)cc3c2B(c2cc(C(C)(C)C)ccc2N3c2ccc(C(C)(C)C)cc2-c2cc(C(C)(C)C)cc(C(C)(C)C)c2)c2sc3cc4c(cc3c21)C(C)(C)CCC4(C)C]

A third aspect of the present invention provides the use of the composition as described above as a luminescent layer material.

A fourth aspect of the present invention provides an organic electroluminescent device, comprising sequentially a first electrode disposed on a substrate plate, a second electrode disposed opposite to the first electrode, and one or more organic functional layers disposed between the first electrode and the second electrode,
wherein the organic functional layer comprises a luminescent layer comprising the composition as described above.

In conjunction with the fourth aspect, the luminescent layer comprises a host material and a doping material, wherein the host material comprises one or more compounds represented by Chemical Formula I and one or more compounds represented by Chemical Formula II. In particular, the doping material comprises a first host material and a second host material, wherein the first host material comprises one or more compounds represented by Formula I, and the second host material comprises one or more compounds represented by Formula II.

In conjunction with the fourth aspect, the doping material comprises one or more compounds represented by Chemical Formula III.

### Beneficial Effects of the Invention

Comparing the compound represented by Formula I containing a 5,5-spirosilafluorene structure as provided by the first aspect of the present invention with a compound containing only carbon or aryl silane, the compound represented by Formula I containing the 5,5-spirosilafluorene structure as provided by the first aspect of the present invention has a better electron-donating ability, and the 5,5-spirosilafluorene structure has a larger steric hindrance, which can effectively avoid the aggregation between doping material molecules and avoid the problem of a decreased efficiency of the organic electroluminescent device caused by concentration quenching.

The composition provided according to the second aspect of the present invention comprises the compound represented by Formula I as described in the first aspect and further comprises a compound represented by Formula II containing a furan structure and a compound represented by Formula III containing a large steric hindrance and a thiophene structure. The compound represented by Formula I provided by the present invention contains a 5,5-spirosilafluorene structure, which has electron-pushing property and can adjust the electron cloud density on the anthracene ring so as to facilitate hole transport. The compound represented by Formula II provided by the present invention contains a furan structure, which has electron-pulling property and can adjust the electron cloud density on the anthracene ring so as to facilitate electron transport. In the present invention, the balance of carrier transport can be regulated by means of the interaction between the compound represented by Formula I and the compound represented by Formula II. The compound represented by Formula III provided by the present invention contains a large steric hindrance and a thiophene fragment, forming an asymmetric structure that has a relatively large dipole moment. There is a relatively strong dipole-dipole interaction between the compound represented by Formula II and the compound represented by Formula III, as provided by the present invention, which can enhance the FORSTER energy transmission process and contributes to reverse inter-system crossing.

The third aspect of the present invention provides the novel use of the composition described in the second aspect as a luminescent layer material. The interaction in the composition improves the comprehensive performance of the luminescent layer material and in turn facilitates the improvement of the comprehensive performance of the organic electroluminescent device prepared from this luminescent layer material as a raw material.

The fourth aspect of the present invention provides an organic electroluminescent device, in which a compound represented by Formula I is used as a first host compound, a compound represented by Formula II is used as a second host compound, and a compound represented by Formula III is used as a doping material to be applied in the luminescent layer of the organic electroluminescent device. In the present invention, by applying the compound represented by Formula I and the compound represented by Formula II to the luminescent layer of the organic electroluminescent device as double host materials, the transport of holes and electrons in the luminescent layer can be more balanced, so that the luminescence recombination region is located in the luminescent layer, and while reducing the driving voltage of the organic electroluminescent device, the efficiency of the organic electroluminescent device can be further improved. In addition, the compound represented by Formula I and the compound represented by Formula II as provided by the present invention both have anthracene-based structures, and the introduced organic fragments such as furan and spirosilafluorene all have a smaller degree of conjugation than the anthracene fragment and have less influence on the luminescence range of the host material. In the present invention, by means of the dipole-dipole interaction between the compound represented by Formula II and the compound represented by Formula III, the energy difference between the singlet state and the triplet state of the doping material can be reduced, and the FORSTER energy transfer in the luminescent layer can be enhanced, which is beneficial to the reverse inter-system crossing process in the doping material and in turn enables an improvement in the efficiency of the organic electroluminescent device. In the present invention, the energy transmission can be more sufficient by means of the interaction between the compound represented by Formula I, the compound represented by Formula II and the compound represented by Formula III, thereby effectively improving the efficiency of the organic electroluminescent device. In the present invention, by means of the rational combination of the double host materials and the doping material, the interaction of the first host compound, the second host compound, and the compound as a doping material imparts the organic electroluminescent device with the significant advantages of a high efficiency and a long lifetime. The use of the compound represented by Formula I, the compound represented by Formula II and the compound represented by Formula III provided by the present invention for use as the luminescent layer material can improve the luminous efficiency of the blue organic electroluminescent device, prolong the lifetime of the blue organic electroluminescent device and overcome the defects in the prior art.

### BRIEF DESCRIPTION OF THE DRAWINGS

The specific embodiments of the present invention will be described in further detail with reference to the accompanying drawings.

FIG. 1 is a schematic structural diagram of an organic electroluminescent device containing the compound and composition of the present invention.

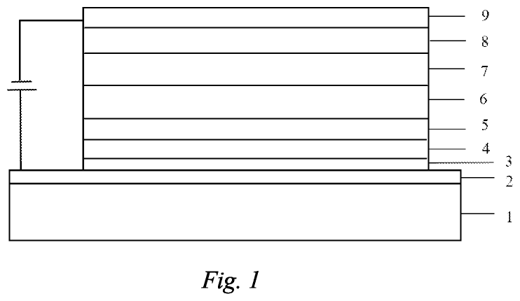

In the Brief Description of the Drawings: 1—substrate, 2—anode, 3—hole injection layer, 4—hole transport layer, 5—luminescent auxiliary layer, 6—luminescent layer, 7—electron transport layer, 8—electron injection layer, and 9—cathode.

### DETAILED DESCRIPTION OF EMBODIMENTS

In order to explain the present invention more clearly, the present invention will be further explained below in conjunction with preferred examples and the accompanying drawings. A person skilled in the art should understand that the following detailed description is illustrative rather than restrictive, and should not limit the scope of protection of the present invention. The examples and comparative examples in the present description are provided to explain the present description more completely to those skilled in the art. The examples and comparative examples according to the present description can be transformed into various forms, and the scope of protection of the present invention should not be limited to the examples and comparative examples detailed below.

The organic compound and composition of the present invention are suitable for light-emitting elements, display panels, and electronic devices, especially suitable for organic electroluminescent devices. The electronic device of the present invention is a device that comprises a layer of at least one organic compound, and the device may also comprise an inorganic material or a layer formed entirely of an inorganic material. The electronic device is preferably an organic electroluminescent device (OLED), an organic integrated circuit (O-IC), an organic field-effect transistor (O-FET), an organic thin film transistor (O-TFT), an organic light-emitting transistor (O-LET), an organic solar cell (O-SC), an organic dye-sensitized solar cell (O-DSSC), an organic optical detector, an organic photosensor, an organic field-quenching device (O-FQD), a luminescent electrochemical cell (LEC), an organic laser diode (O-laser), and an organic plasma emitting device. The electronic device is preferably an organic electroluminescent device (OLED).

In order to understand the content of the present invention more clearly, the organic compound, the preparation method for the compound, and the luminescent characteristics of the device will be explained in detail in conjunction with examples. Various chemical reactions can be applied to the synthesis method for a compound according to one embodiment of the present invention. However, it should be noted that the synthesis method for the compound according to one embodiment of the present invention is not limited to the synthesis method described below. Unless otherwise specified, the subsequent synthesis is carried out in an anhydrous solvent in a protective gas atmosphere. Solvents and reagents can be purchased from conventional reagent suppliers.

### Compound Synthesis Examples

### Synthesis of Intermediate of First Host Compound

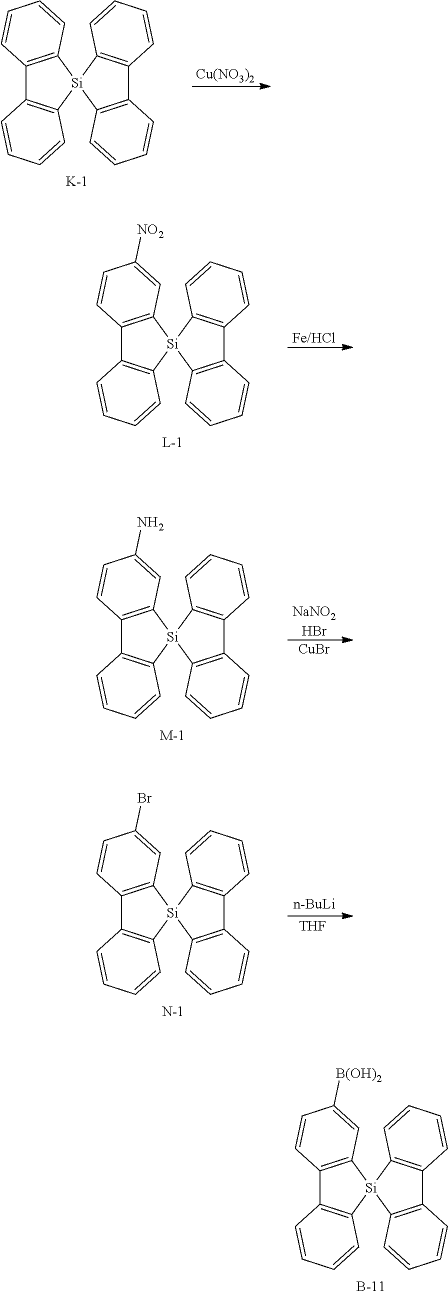

At room temperature, K-1 (10.00 g, 30 mmol) and copper nitrate trihydrate (7.90 g, 32.5 mmol) were added to 200 mL of acetic anhydride, stirred for 10 min, heated to 40° C., stirred for 4 h, and cooled to room temperature, the reaction was quenched with 1 L of water, extracted 3 times with 500 mL of dichloromethane, an organic phase is separated out, the organic phase was dried with anhydrous magnesium sulfate and subjected to rotary evaporation to remove the solvent to obtain a crude product. The crude product was recrystallized and purified by dichloromethane or n-heptane to obtain the product L-1:8.48 g, yield: 75%, MS (m/z) (M+): 377.

At room temperature, L-1 (10.00 g, 27 mmol) and iron powder (10.0 g, 0.18 mol) were added to 250 mL of ethanol, heated to 80° C. and refluxed, 40 mL of concentrated hydrochloric acid (1 mol/L) was slowly added dropwise, and the reflux reaction continued for 40 min, the reaction product was then cooled to room temperature, filtered to remove excess iron scraps, and subjected to rotary evaporation to remove the ethanol solvent to obtain a crude product. The crude product was dissolved in 500 mL of water, the pH was adjusted to neutrality (pH=7) by adding aqueous ammonia, and after filtration, a white precipitate was obtained. The white precipitate was recrystallized and purified by ethanol to obtain the product M-1:7.31 g, yield: 78%, MS (m/z) (M+): 347.

At room temperature, M-1 (20.00 g, 58 mmol) and 50 mL of concentrated hydrobromic acid (1.28 mol/L) were dissolved in 200 mL of water, the solution was cooled to 0° C., 50 mL of an aqueous sodium nitrite solution (0.16 g/mL) was slowly added dropwise at 0° C. or lower, and the mixture was maintained at 0° C. and stirred for 30 min. Cuprous bromide (10 g, 0.07 mol) in concentrated hydrobromic acid solution (100 mL, 1.28 mol/L) at 0° C. was added, and the solution was heated to 100° C., stirred for 30 min, cooled to room temperature, and filtered to obtain a white precipitate. The white precipitate was washed with a saturated sodium bicarbonate solution and water to obtain a crude product, and the crude product was recrystallized and purified by dichloromethane or n-heptane to obtain the product N-1:11.92 g, yield: 50%, MS (m/z) (M+): 411.

Under nitrogen protection, N-1 (10.00 g, 25 mmol) was dissolved in tetrahydrofuran (100 mL), and the solution was cooled to −78° C. While maintaining the temperature at −78° C., 48 mL of a hexane solution of n-butyl lithium (1.6 mol/L) was slowly added dropwise, and triisopropyl borate (7.05 g, 37.5 mmol) was then added dropwise. The reaction system was heated to −30° C., 30 mL of water was added, the reaction system was heated to 0° C., concentrated hydrochloric acid (1 mol/L) was added to adjusted the pH to 1-2, and the reaction system was heated to 20° C., stirred for 2 h, and cooled to room temperature. The reaction liquid was separated and extracted with ethyl acetate to obtain an organic phase. The organic phase was washed to neutrality with a saturated sodium chloride solution and subjected to rotary evaporation to remove the solvent to obtain a crude product. The crude product was recrystallized and purified by ethyl acetate or n-heptane to obtain the product B-11:6.11 g, yield: 65%, MS (m/z) (M+): 376.

After B-11 was obtained from the above process, another first host compound intermediate could be prepared by a method similar to that for B-11.

### Example 1

This example provided a first host compound C-11, and the synthesis route for this compound was as follows:

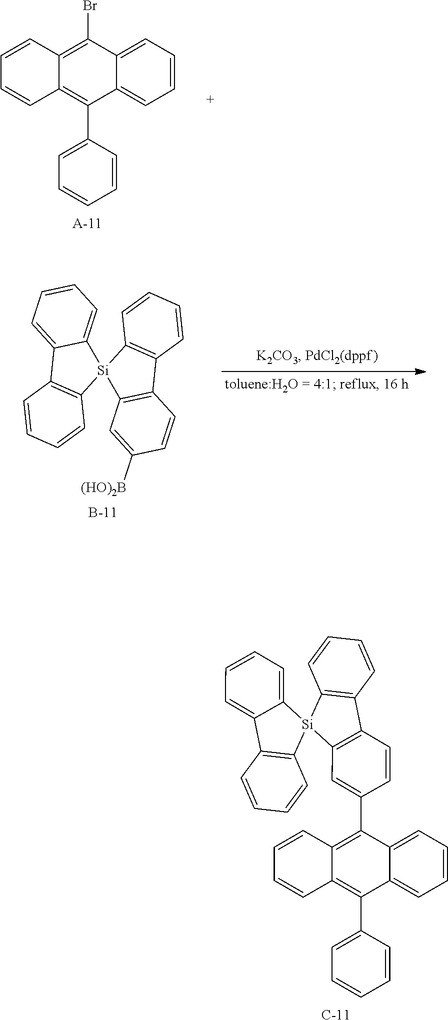

A-11 (3.33 g, 10 mmol) and B-11 (3.76 g, 10 mmol) were added to a mixture of toluene and water (in which the volume of toluene was 80 ml and the volume of water was 20 mL). Under nitrogen protection, potassium carbonate (1.65 g, 10 mmol) and [1,1′-bis(diphenylphosphino) ferrocene]dichloropalladium (II) (73 mg, 0.1 mmol) were added to the system. The reaction system was heated to 85° C. and refluxed for 16 hours. After cooling to room temperature, the reaction system was quenched with ice water and separated to obtain an organic phase. After filtration, the organic phase was dried with anhydrous magnesium sulfate and subjected to rotary evaporation to remove the solvent to obtain a crude product. The crude product was purified to finally obtain the product C-11:4.50 g (yield: 77%), MS (m/z) (M+): 585.

### Example 2

This example provided first host compound C-12, and the synthesis route for this compound was as follows:

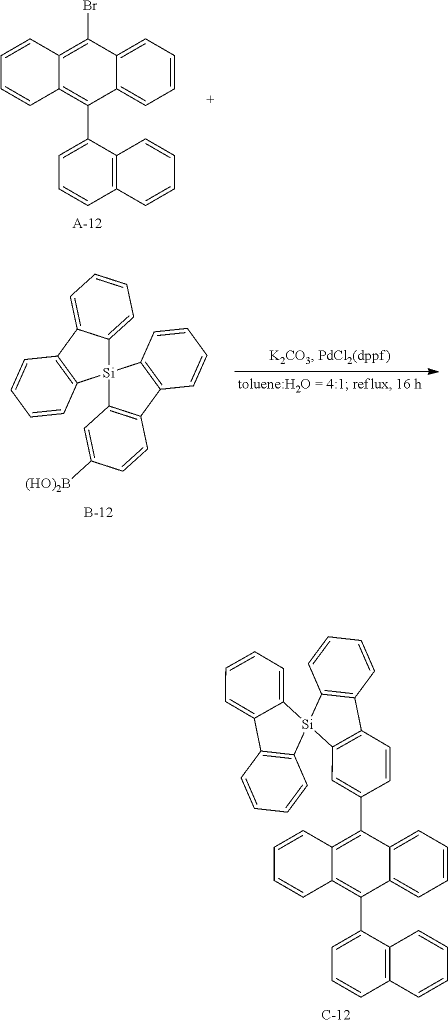

Using the same method as in Example 1, A-12 (3.83 g, 10 mmol) was substituted for A-11, and B-12 (3.76 g, 10 mmol) was substituted for B-11 to finally obtain the product C-12:4.76 g (yield: 75%), MS (m/z) (M+): 635.

### Example 3

This example provided first host compound C-13, and the synthesis route for this compound was as follows:

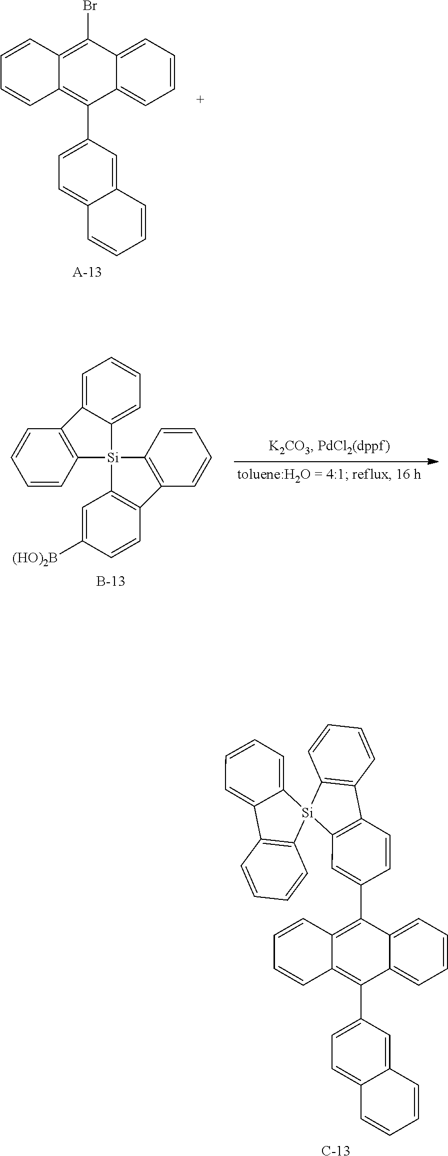

Using the same method as in Example 1, A-13 (3.83 g, 10 mmol) was substituted for A-11, and B-13 (3.76 g, 10 mmol) was substituted for B-11 to finally obtain the product C-13:4.70 g (yield: 74%), MS (m/z) (M+): 635.

### Example 4

This example provided first host compound C-14, and the synthesis route for this compound was as follows:

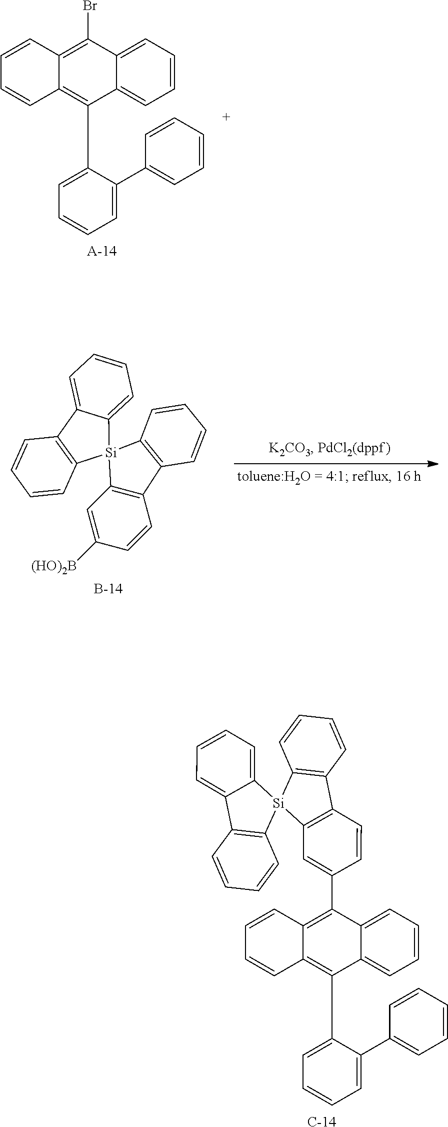

Using the same method as in Example 1, A-14 (4.09 g, 10 mmol) was substituted for A-11, and B-14 (3.76 g, 10 mmol) was substituted for B-11 to finally obtain the product C-14:5.35 g (yield: 81%), MS (m/z) (M+): 661.

### Example 5

This example provided first host compound C-15, and the synthesis route for this compound was as follows:

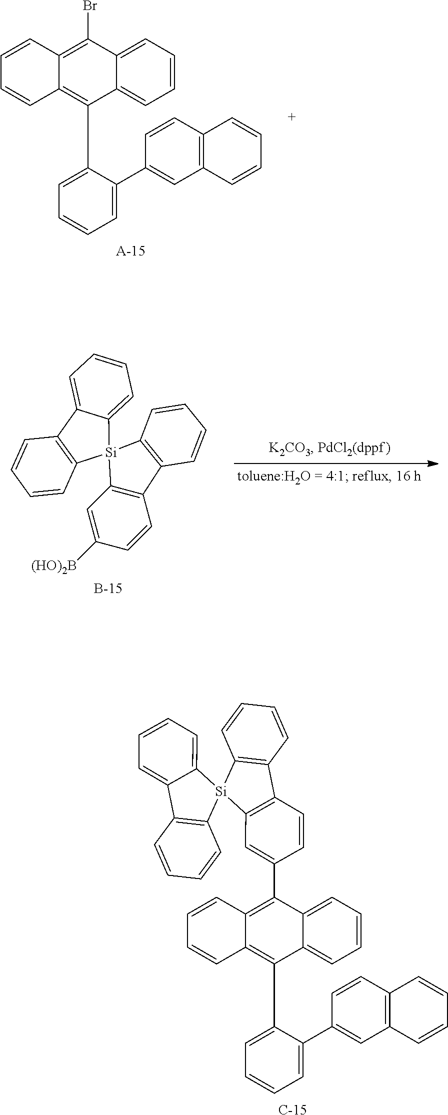

Using the same method as in Example 1, A-15 (4.59 g, 10 mmol) was substituted for A-11, and B-15 (3.76 g, 10 mmol) was substituted for B-11 to finally obtain the product C-15:5.19 g (yield: 73%), MS (m/z) (M+): 711.

### Example 6

This example provided first host compound C-16, and the synthesis route for this compound was as follows:

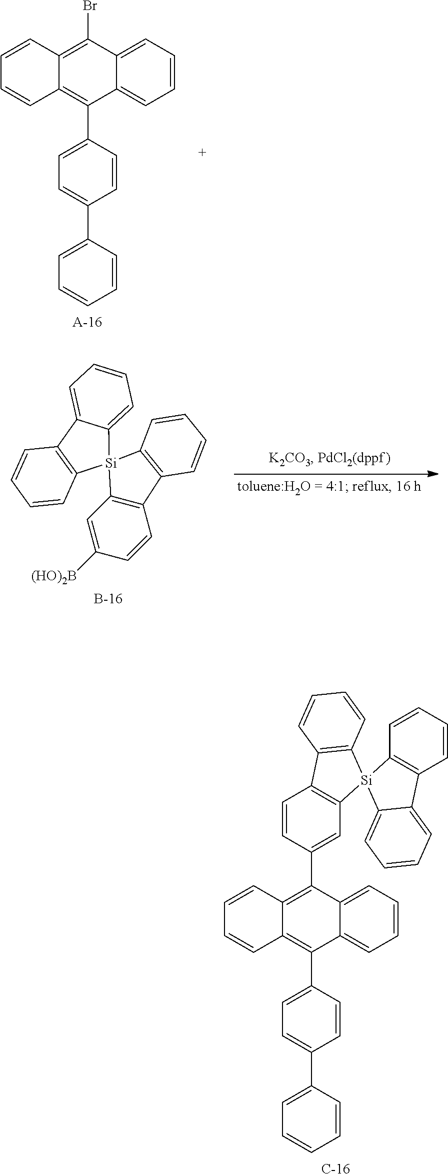

Using the same method as in Example 1, A-16 (4.09 g, 10 mmol) was substituted for A-11, and B-16 (3.76 g, 10 mmol) was substituted for B-11 to finally obtain the product C-16:5.35 g (yield: 81%), MS (m/z) (M+): 661.

### Example 7

This example provided first host compound C-17, and the synthesis route for this compound was as follows:

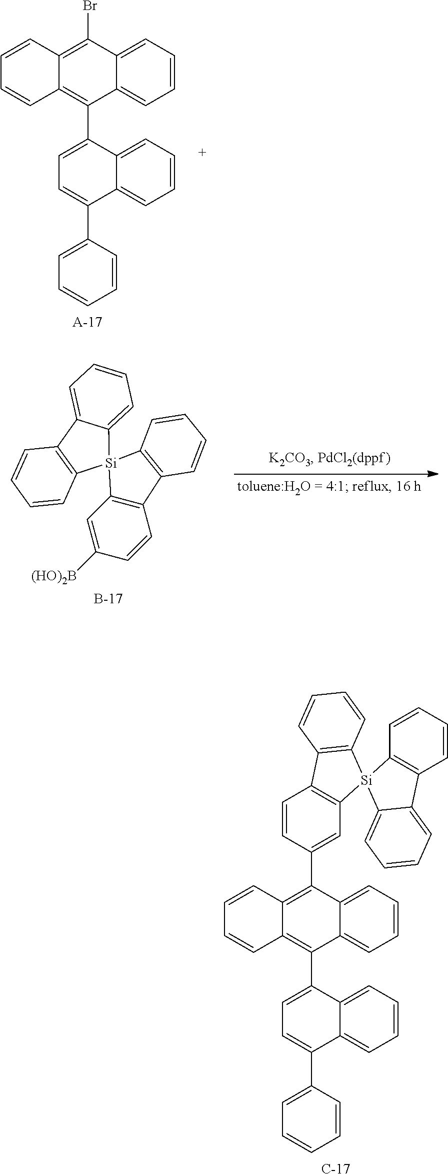

Using the same method as in Example 1, A-17 (4.59 g, 10 mmol) was substituted for A-11, and B-17 (3.76 g, 10 mmol) was substituted for B-11 to finally obtain the product C-17:5.55 g (yield: 78%), MS (m/z) (M+): 711.

### Example 8

This example provided first host compound C-18, and the synthesis route for this compound was as follows:

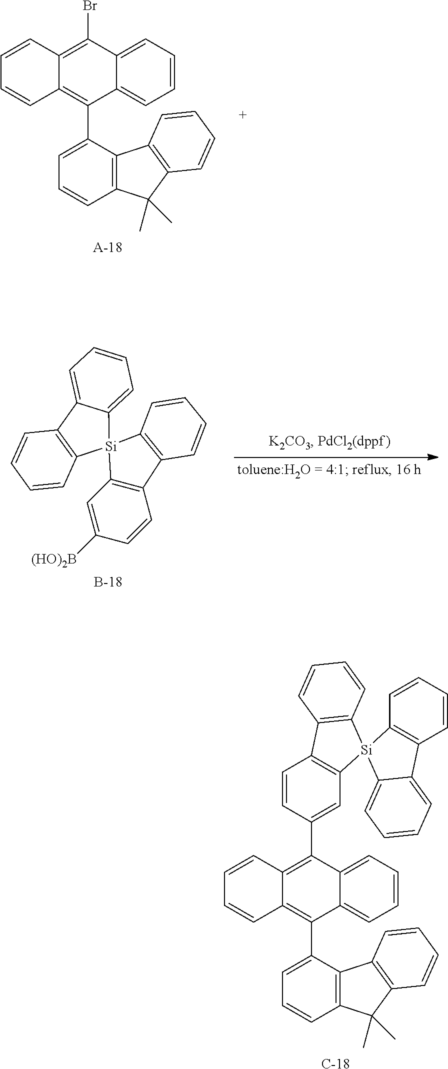

Using the same method as in Example 1, A-18 (4.49 g, 10 mmol) was substituted for A-11, and B-18 (3.76 g, 10 mmol) was substituted for B-11 to finally obtain the product C-18:5.54 g (yield: 79%), MS (m/z) (M+): 701.

### Example 9

This example provided first host compound C-19, and the synthesis route for this compound was as follows:

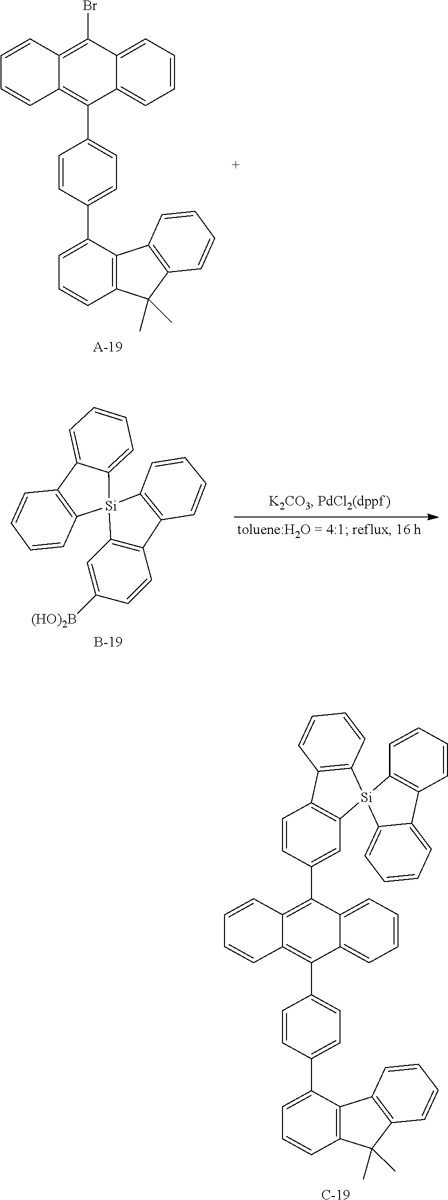

Using the same method as in Example 1, A-19 (5.25 g, 10 mmol) was substituted for A-11, and B-19 (3.76 g, 10 mmol) was substituted for B-11 to finally obtain the product C-19:6.29 g (yield: 81%), MS (m/z) (M+): 777.

### Example 10

This example provided second host compound C-2, and the synthesis route for this compound was as follows:

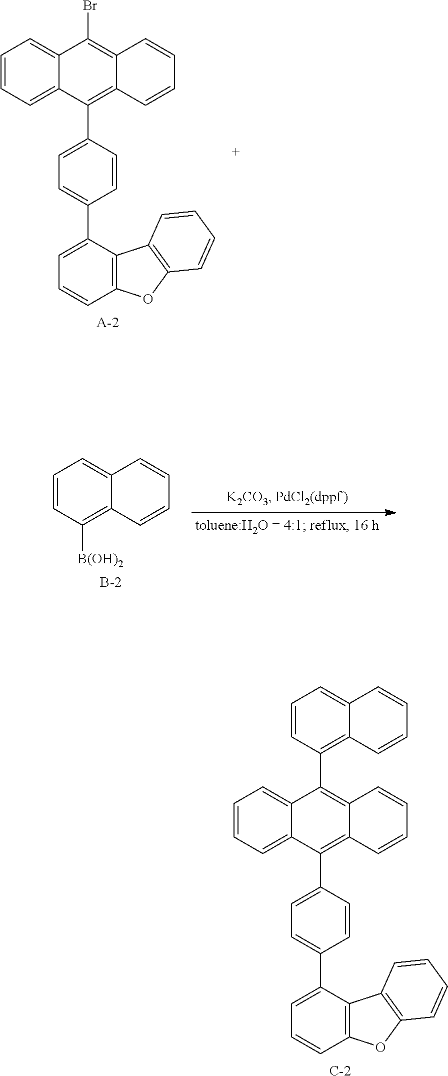

A-2 (4.99 g, 10 mmol) and B-2 (1.72 g, 10 mmol) were added to a mixture of toluene and water (in which the volumes of toluene and water were 80 mL and 20 mL, respectively). Under nitrogen protection, potassium carbonate (1.65 g, 10 mmol) was added to the system, and [1,1′-bis(diphenylphosphino) ferrocene]dichloropalladium (II) (73 mg, 0.1 mmol) was introduced. Subsequently, the reaction system was heated to reflux for 16 hours. After cooling to room temperature, the reaction was quenched with ice water and separated to obtain an organic phase. After filtration, the organic phase was dried with anhydrous magnesium sulfate and subjected to rotary evaporation to remove the solvent to obtain a crude product. The crude product was purified by column chromatography to finally obtain the product C-2:4.21 g (yield: 77%), MS (m/z) (M+): 547.

### Example 11

This example provided second host compound C-3, and the synthesis route for this compound was as follows:

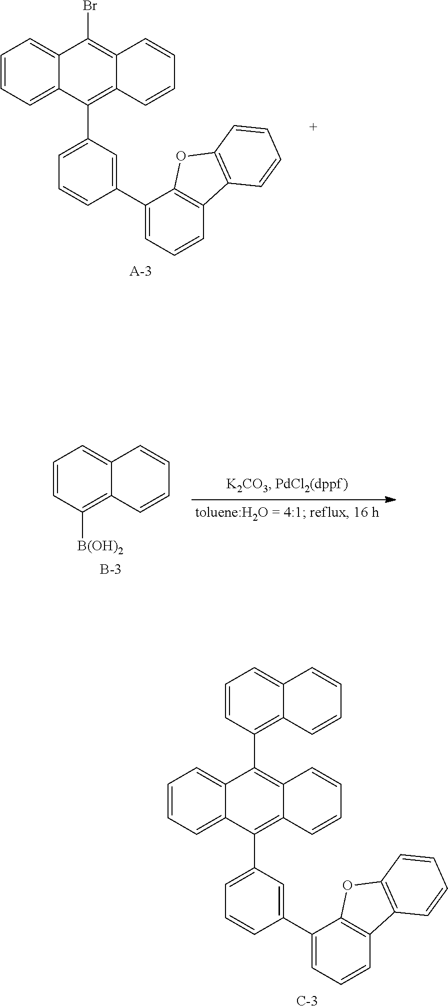

The same method as in Example 10 was used, except that A-3 (4.99 g, 10 mmol) was substituted for A-2, and B-3 (1.72 g, 10 mmol) was substituted for B-2 to finally obtain the product C-3:4.10 g (yield: 75%), MS (m/z) (M+): 547.

### Example 12

This example provided second host compound C-4, and the synthesis route for this compound was as follows:

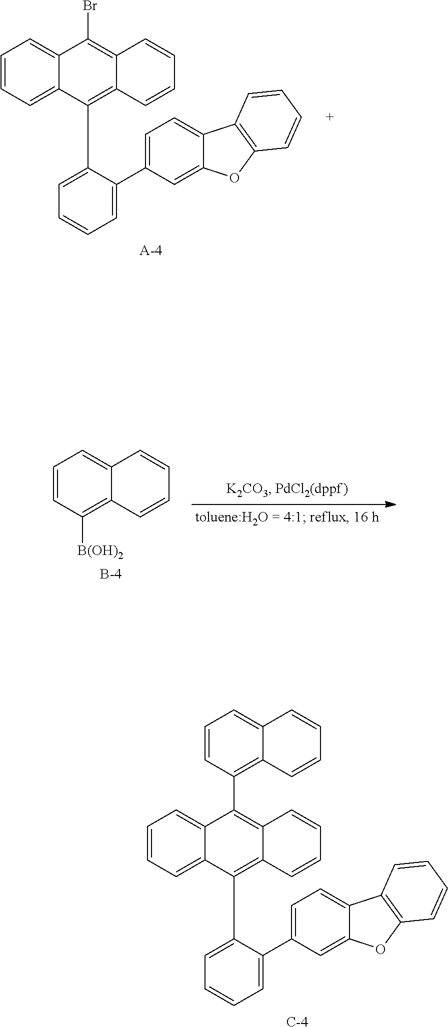

The same method as in Example 10 was used, except that A-4 (4.99 g, 10 mmol) was substituted for A-2, and B-4 (1.72 g, 10 mmol) was substituted for B-2 to finally obtain the product C-4:4.10 g (yield: 75%), MS (m/z) (M+): 547.

### Example 13

This example provided second host compound C-5, and the synthesis route for this compound was as follows:

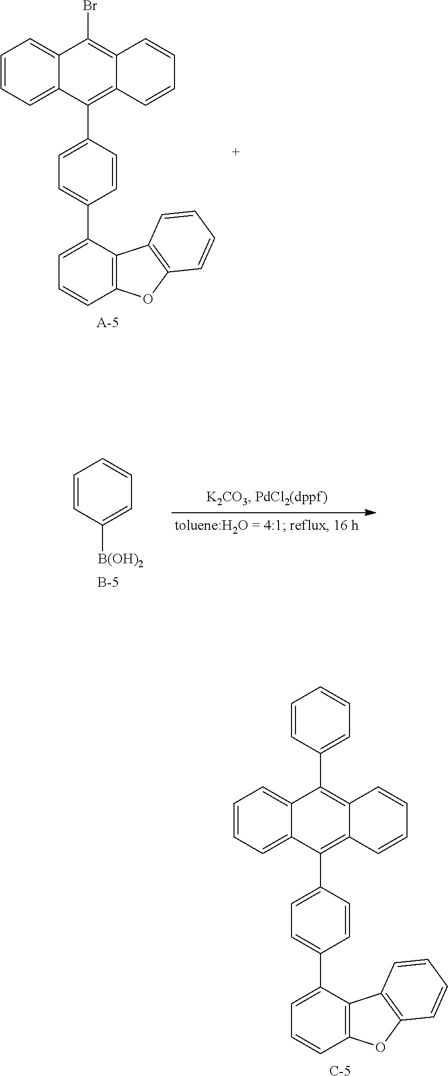

The same method as in Example 10 was used, except that A-5 (4.99 g, 10 mmol) was substituted for A-2, and B-5 (1.22 g, 10 mmol) was substituted for B-2 to finally obtain the product C-5:3.63 g (yield: 73%), MS (m/z) (M+): 497.

### Example 14

This example provided second host compound C-6, and the synthesis route for this compound was as follows:

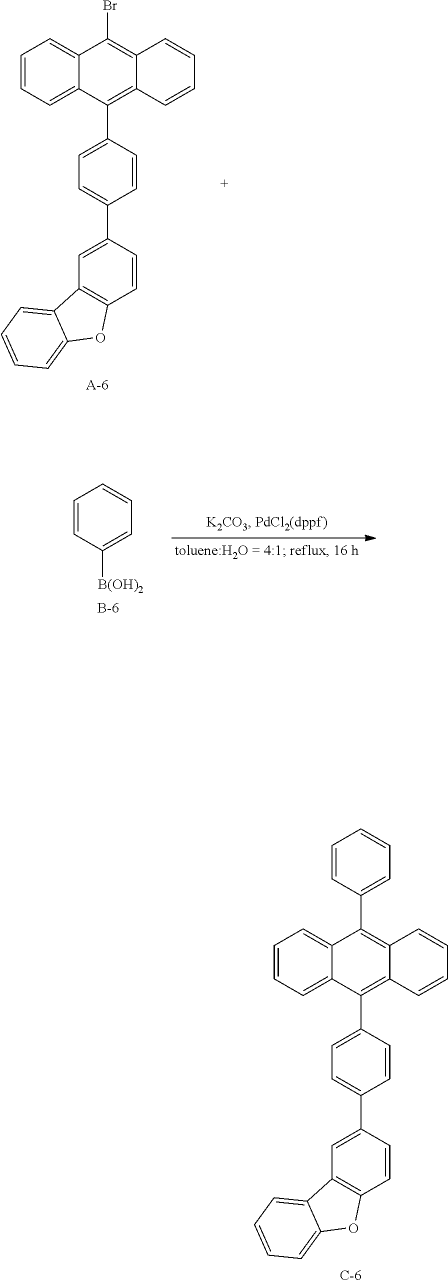

The same method as in Example 10 was used, except that A-6 (4.99 g, 10 mmol) was substituted for A-2, and B-6 (1.22 g, 10 mmol) was substituted for B-2 to finally obtain the product C-6:3.68 g (yield: 74%), MS (m/z) (M+): 497.

### Example 15

This example provided second host compound C-7, and the synthesis route for this compound was as follows:

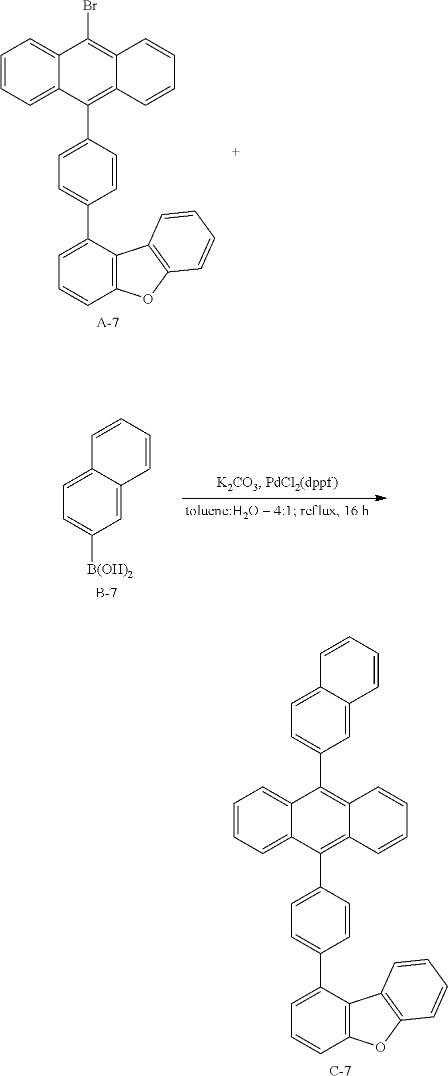

The same method as in Example 10 was used, except that A-7 (4.99 g, 10 mmol) was substituted for A-2, and B-7 (1.72 g, 10 mmol) was substituted for B-2 to finally obtain the product C-7:4.27 g (yield: 78%), MS (m/z) (M+): 547.

### Example 16

This example provided second host compound C-8, and the synthesis route for this compound was as follows:

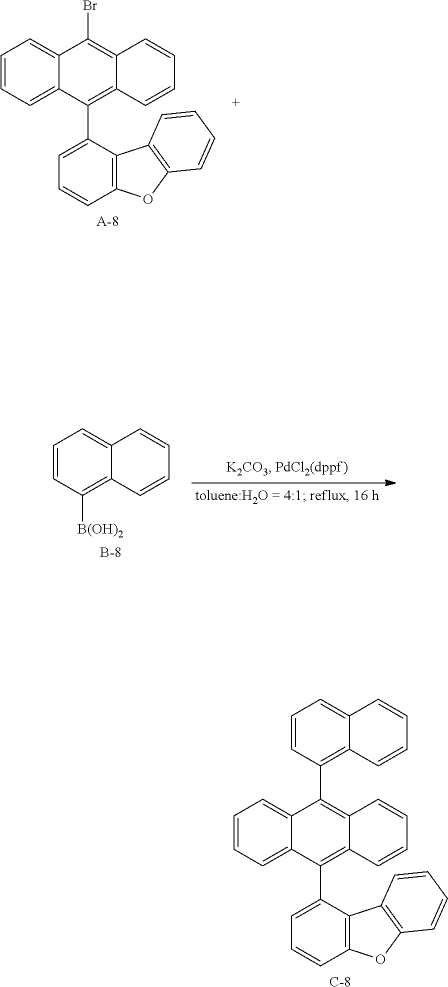

The same method as in Example 10 was used, except that A-8 (4.23 g, 10 mmol) was substituted for A-2, and B-8 (1.72 g, 10 mmol) was substituted for B-2 to finally obtain the product C-8:3.96 g (yield: 84%), MS (m/z) (M+): 471.

### Example 17

This example provided second host compound C-9, and the synthesis route for this compound was as follows:

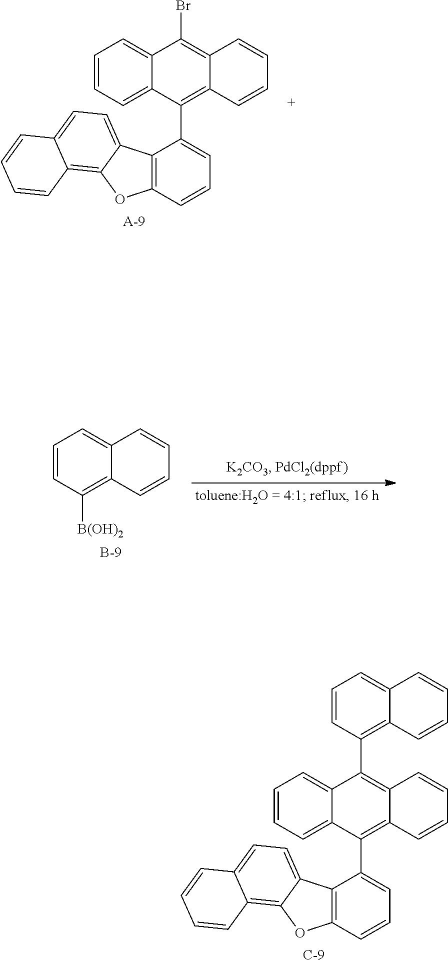

The same method as in Example 10 was used, except that A-9 (4.73 g, 10 mmol) was substituted for A-2, and B-9 (1.72 g, 10 mmol) was substituted for B-2 to finally obtain the product C-9:4.32 g (yield: 83%), MS (m/z) (M+): 521.

### Example 18

This example provided second host compound C-10, and the synthesis route for this compound was as follows:

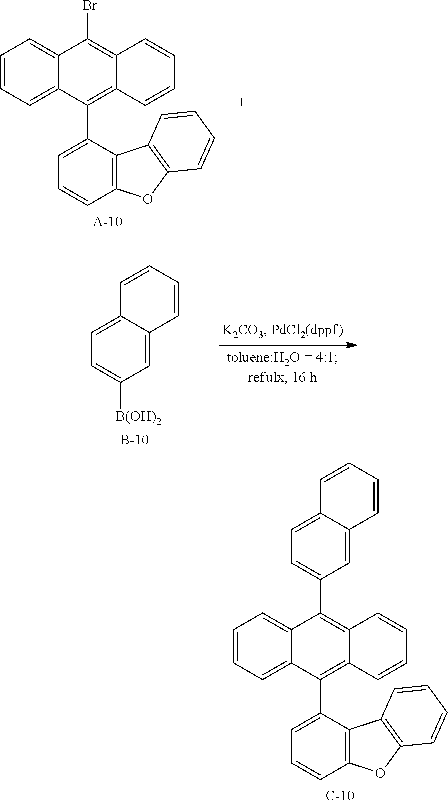

The same method as in Example 10 was used, except that A-10 (4.23 g, 10 mmol) was substituted for A-2, and B-10 (1.72 g, 10 mmol) was substituted for B-2 to finally obtain the product C-10:4.00 g (yield: 85%), MS (m/z) (M+): 471.

### Synthesis of Intermediate of Doping Material

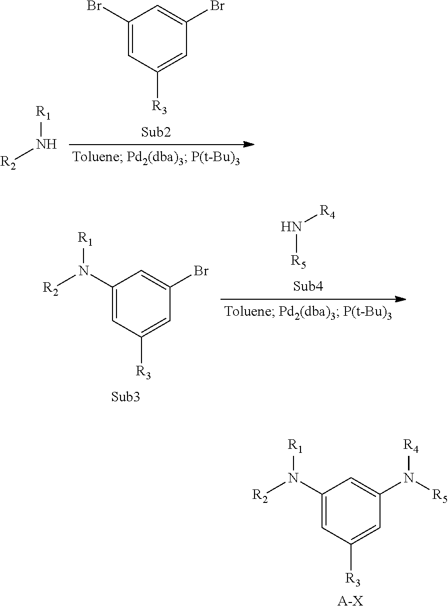

The general reaction formula of the intermediate synthesis was as above. The target intermediate could be obtained by means of a common two-step Buchwald-Hartwig coupling synthesis method.

A specific example was as follows:

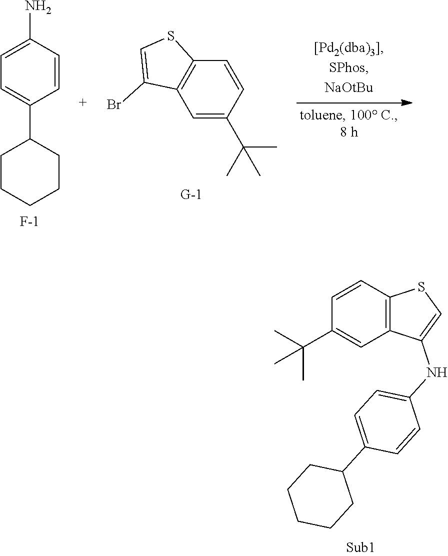

F-1 (8.75 g, 0.05 mol), G-1 (12.11 g, 0.045 mol), and sodium tert-butoxide (5.28 g, 0.055 mol) were added to toluene (200 mL). Subsequently, under nitrogen protection, bis(dibenzylideneacetone) palladium (0.46 g, 0.5 mmol) and SPhos (0.41 g, 1 mmol) were introduced. Subsequently, the reaction system was heated to 110° C., refluxed for 8 hours, and cooled to room temperature, the reaction was then quenched by adding water and separated to obtain an organic phase, the organic phase was filtered, then dried with anhydrous magnesium sulfate, and subjected to rotary evaporation to remove the solvent to obtain a crude product, and the crude product was purified by column chromatography to obtain the product Sub1: 11.47 g, yield: 70%, MS (m/z) (M+): 364.

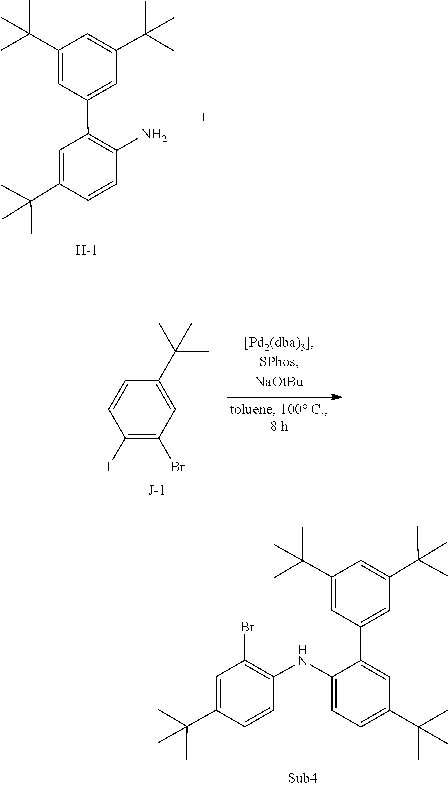

H-1 (16.9 g, 0.05 mol), J-1 (15.26 g, 0.045 mol), and sodium tert-butoxide (5.28 g, 0.055 mol) were added to toluene (500 mL). Under nitrogen protection, bis(dibenzylideneacetone) palladium (0.46 g, 0.5 mmol) and SPhos (0.41 g, 1 mmol) were introduced. Subsequently, the reaction system was heated to 110° C. and refluxed for 8 hours, and cooled to room temperature, and the reaction was then quenched by adding water and separated to obtain an organic phase. The organic phase was filtered, then dried with anhydrous sodium sulfate, and subjected to rotary evaporation to remove the solvent to obtain a crude product, and the crude product was purified by column chromatography to obtain the product Sub4: 20.01 g, yield: 81%, MS (m/z) (M+): 549.

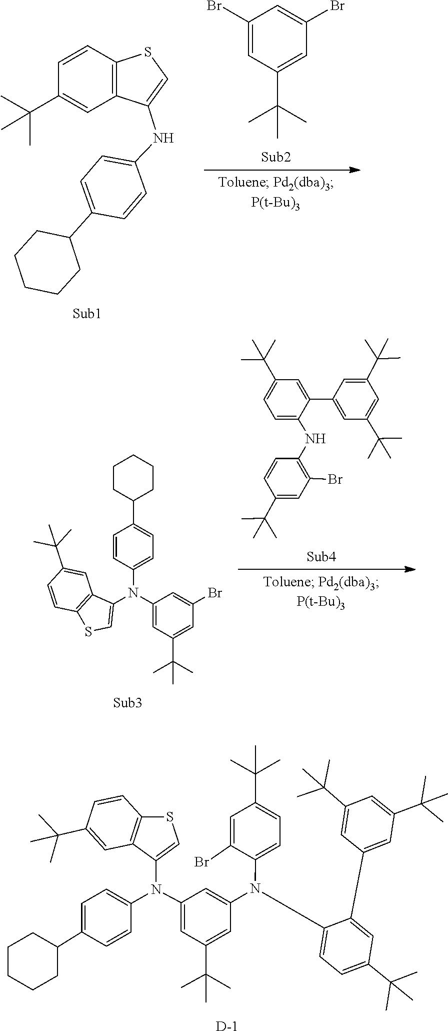

Sub1 (3.64 g, 10 mmol), Sub2 (2.63, 9 mmol), and sodium tert-butoxide (1.05 g, 11 mmol) were added to toluene (50 ml). Under nitrogen protection, bis(dibenzylideneacetone) palladium (274.28 mg, 0.30 mmol) and tri-tert-butylphosphine (121.2 mg, 0.6 mmol) were then introduced. Subsequently, the reaction system was heated to reflux for 10 hours and cooled to room temperature, the reaction was then quenched by adding water and separated to obtain an organic phase, the organic phase was filtered, then dried with anhydrous sodium sulfate, and subjected to rotary evaporation to remove the solvent to obtain a crude product, and the crude product was purified by column chromatography to finally obtain the product Sub3: 4.14 g (yield: 80%), MS (m/z) (M+): 575.

Sub3 (5.75 g, 10 mmol), Sub4 (5.49 g, 10 mmol), and sodium tert-butoxide (1.05 g, 11 mmol) were added to toluene (100 ml). Under nitrogen protection, bis(dibenzylideneacetone) palladium (274.28 mg, 0.30 mmol) and tri-tert-butylphosphine (121.2 mg, 0.6 mmol) were introduced. Subsequently, the reaction system was heated to reflux for 10 hours and cooled to room temperature, the reaction was then quenched by adding water and separated to obtain an organic phase, the organic phase was filtered, then dried with anhydrous sodium sulfate, and subjected to rotary evaporation to remove the solvent to obtain a crude product, and the crude product was purified by column chromatography to finally obtain the product D-1:6.77 g (yield: 65%), MS (m/z) (M+): 1042.

After D-1 was obtained from the above process, another doping material intermediate could be prepared by a method similar to that for D-1.

### Example 19

This example provided Compound E-1 as a doping material, and the synthesis route for this compound was as follows:

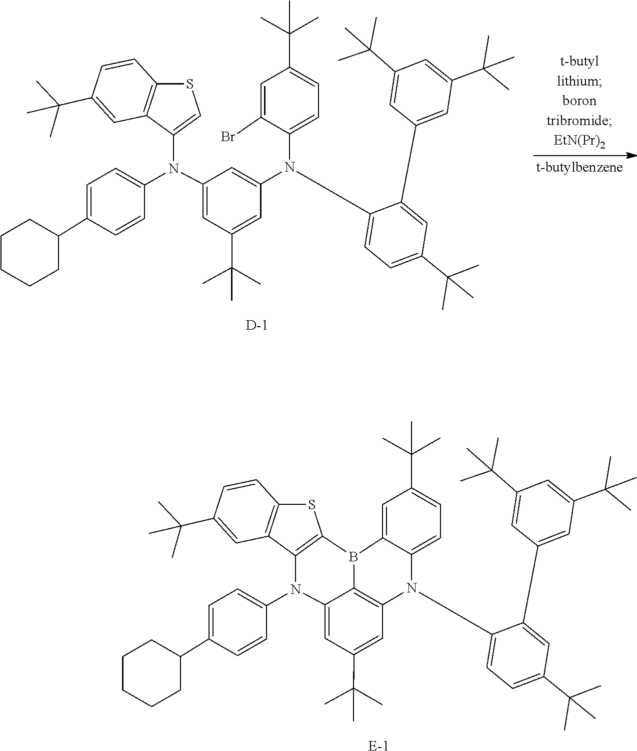

D-1 (10.42 g, 10 mmol) was added to tert-butyl benzene (125 ml), the mixture was then cooled to 0° C. under nitrogen protection, and 12.4 ml of a solution of 1.7 M tert-butyl lithium (21 mmol) in pentane was added. The mixture was heated to 60° C., stirred for 2 hours, and then cooled to 0° C., and 2.0 ml of boron tribromide (21 mmol) was added and stirred for 0.5 h. At 0° C., 3.65 ml of N,N-diisopropylethylamine (21 mmol) was added. The mixture was heated to 60° C., stirred for 2 h, and cooled to room temperature, and the reaction was then quenched by adding ice water and separated to obtain an organic phase. The organic phase was filtered, then dehydrated with anhydrous magnesium sulfate, and subjected to rotary evaporation to remove the organic solvent to obtain a crude product, and the crude product was recrystallized and purified from dichloromethane and n-heptane to finally obtain the product E-1:1.46 g (yield: 15%), MS (m/z) (M+): 971.

### Example 20

This example provided Compound E-2 as a doping material, and the synthesis route for this compound was as follows:

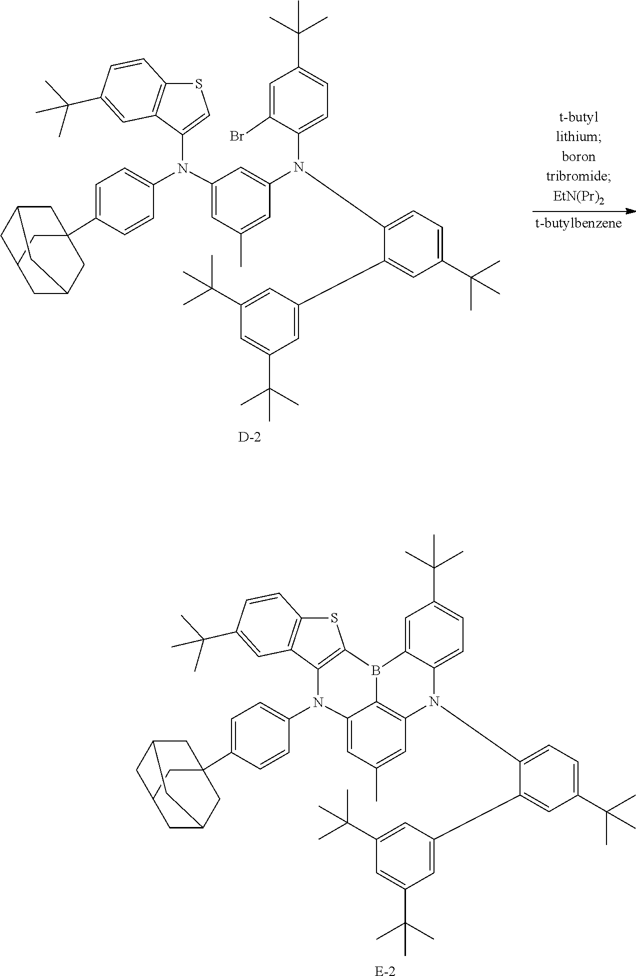

The same method as in Example 19 was used, except that D-2 (10.52 g, 10 mmol) was substituted for D-1 to finally obtain the product E-2:1.18 g (yield: 12%), MS (m/z) (M+): 981.

### Example 21

This example provided Compound E-3 as a doping material, and the synthesis route for this compound was as follows:

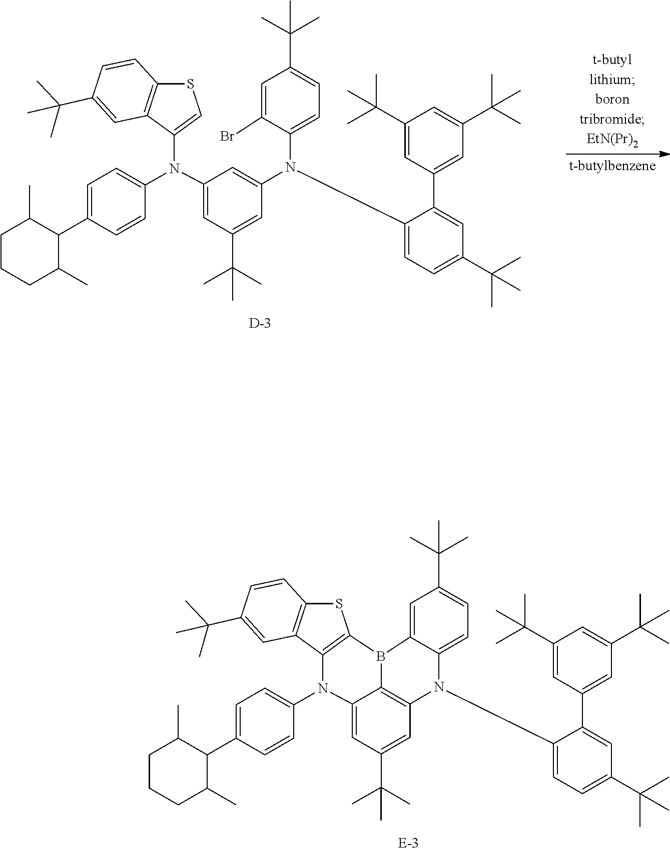

The same method as in Example 19 was used, except that D-3 (10.7 g, 10 mmol) was substituted for D-1 to finally obtain the product E-3:1 g (yield: 10%), MS (m/z) (M+): 999.

### Example 22

This example provided Compound E-4 as a doping material, and the synthesis route for this compound was as follows:

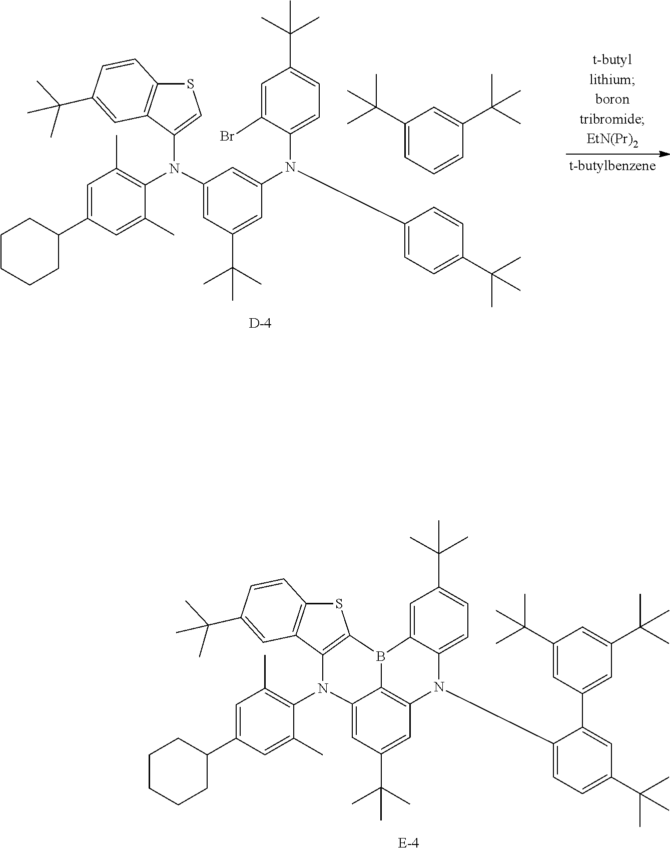

The same method as in Example 19 was used, except that D-4 (10.7 g, 10 mmol) was substituted for D-1 to finally obtain the product E-4:1.4 g (yield: 14%), MS (m/z) (M+): 999.

### Example 23

This example provided Compound E-5 as a doping material, and the synthesis route for this compound was as follows:

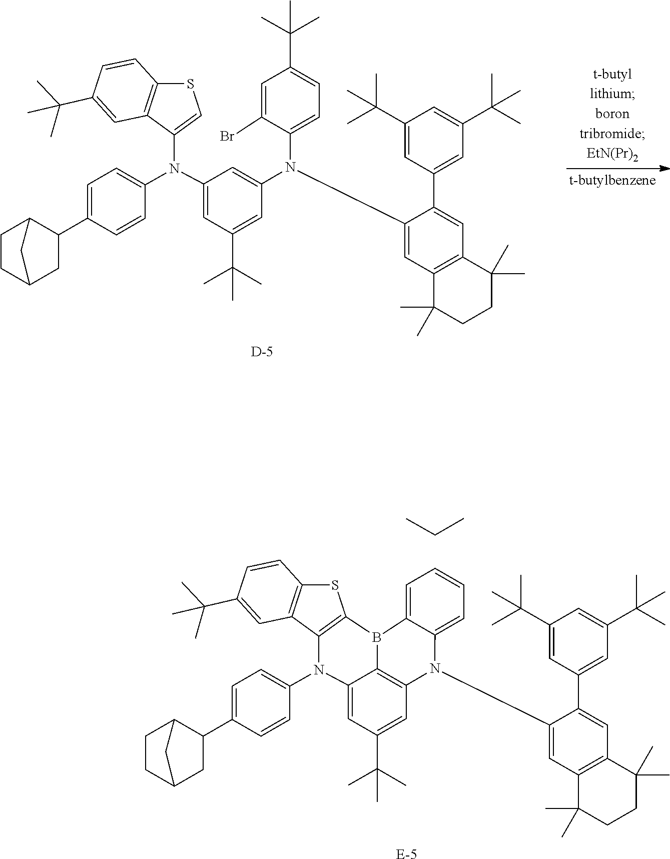

The same method as in Example 19 was used, except that D-5 (11.09 g, 10 mmol) was substituted for D-1 to finally obtain the product E-5:1.35 g (yield: 13%), MS (m/z) (M+): 1037.

### Example 24

This example provided Compound E-6 as a doping material, and the synthesis route for this compound was as follows:

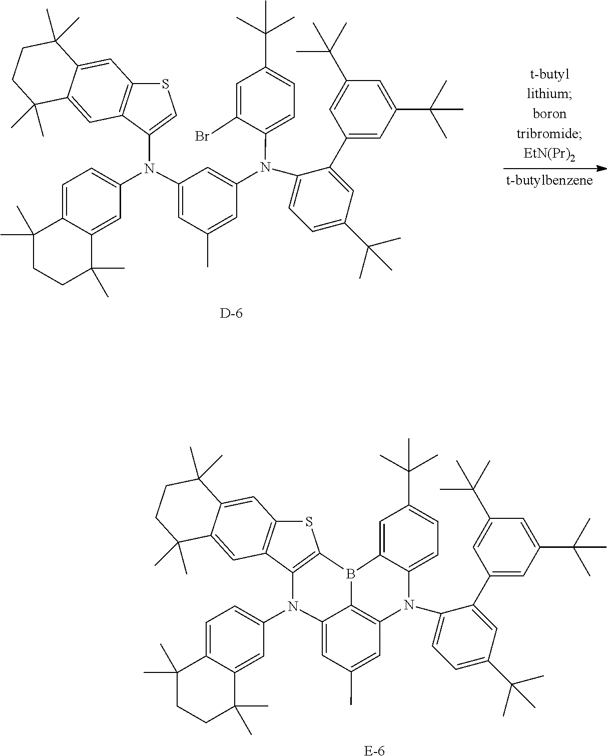

The same method as in Example 19 was used, except that D-6 (10.82 g, 10 mmol) was substituted for D-1 to finally obtain the product E-6:0.81 g (yield: 8%), MS (m/z) (M+): 1011.

### Example 25

This example provided Compound E-7 as a doping material, and the synthesis route for this compound was as follows:

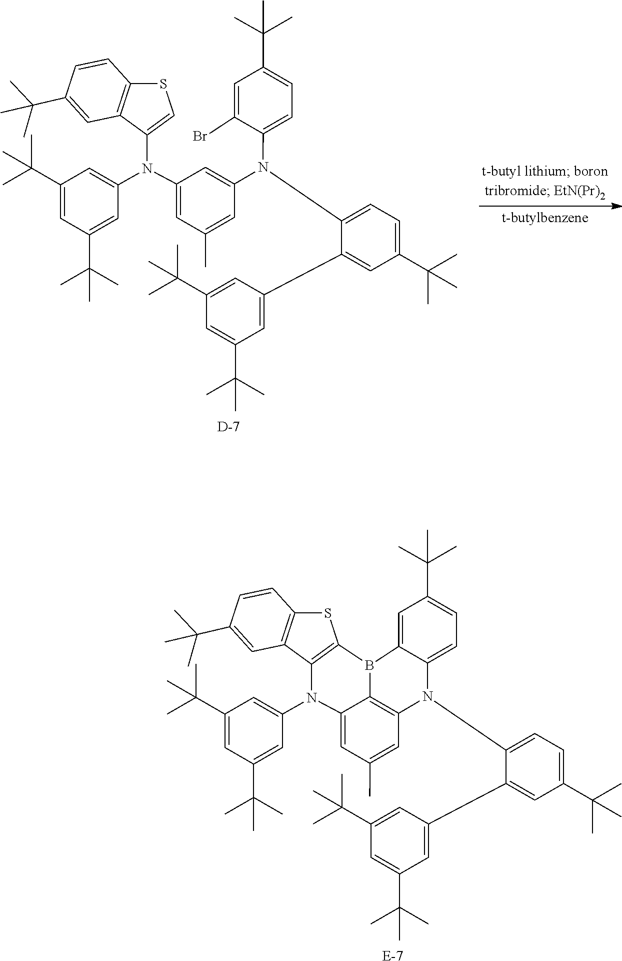

The same method as in Example 19 was used, except that D-7 (10.3 g, 10 mmol) was substituted for D-1 to finally obtain the product E-7:1.25 g (yield: 13%), MS (m/z) (M+): 959.

### Example 26

This example provided Compound E-8 as a doping material, and the synthesis route for this compound was as follows:

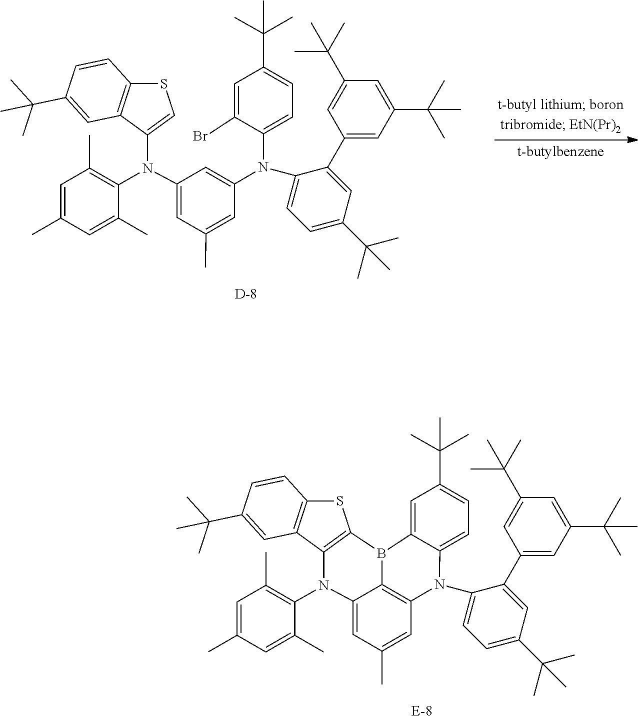

The same method as in Example 19 was used, except that D-8 (9.6 g, 10 mmol) was substituted for D-1 to finally obtain the product E-8:0.71 g (yield: 8%), MS (m/z) (M+): 889.

### Example 27

This example provided Compound E-9 as a doping material, and the synthesis route for this compound was as follows:

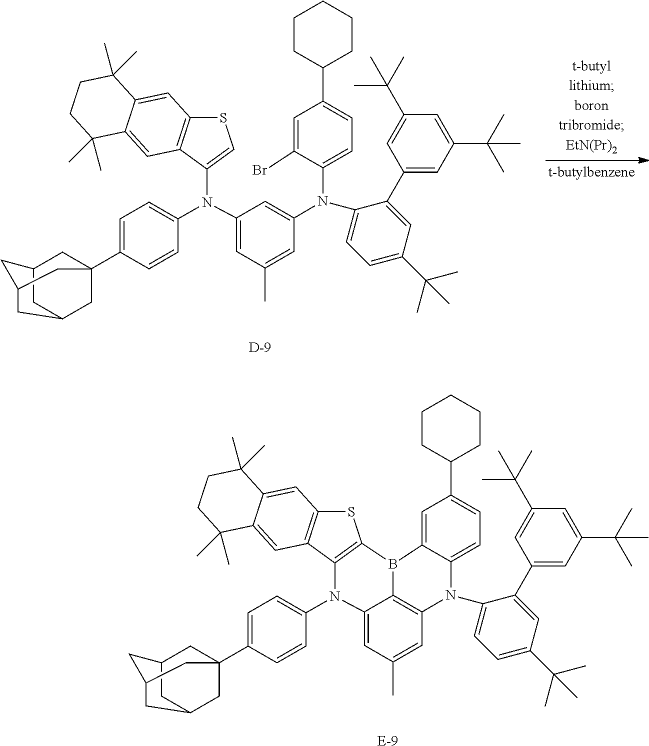

The same method as in Example 19 was used, except that D-9 (11.33 g, 10 mmol) was substituted for D-1 to finally obtain the product E-9:0.95 g (yield: 9%), MS (m/z) (M+): 1061.

### Example 28

This example provided Compound E-10 as a doping material, and the synthesis route for this compound was as follows:

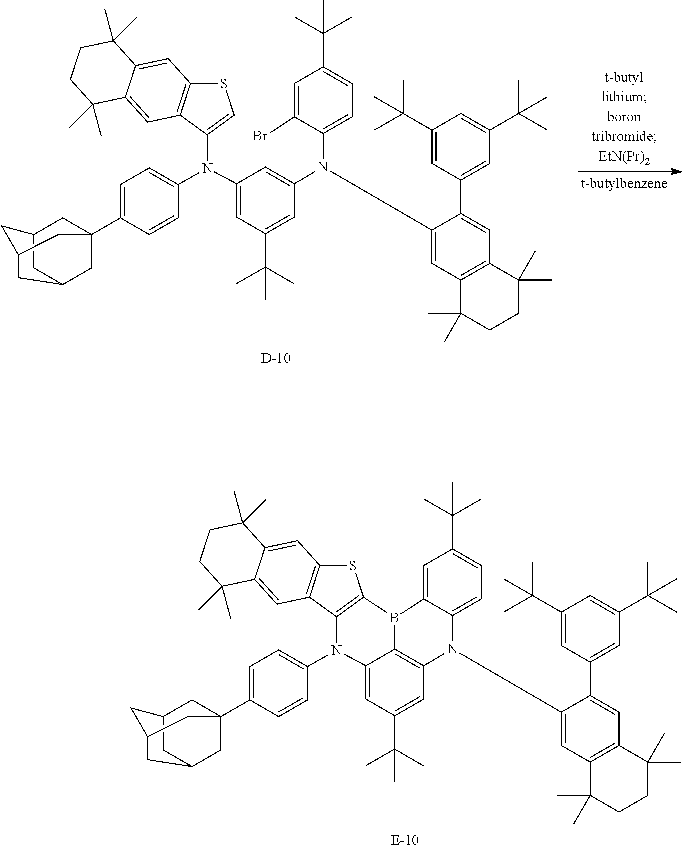

The same method as in Example 19 was used, except that D-10 (12.03 g, 10 mmol) was substituted for D-1 to finally obtain the product E-10:1.25 g (yield: 11%), MS (m/z) (M+): 1132.

### Composition Examples

### Examples 29 to 168

This example provided Compositions Z1 to Z140. Compositions Z1 to Z140 were obtained by combining the first host compound, the second host compound and the doping material according to Table 1 and uniformly mixing these materials, wherein the mass ratio of the first host compound to the second host compound to the doping material was 49:49:2.

TABLE 1

| | | Doping | First host | Second host |
|---|---|---|---|---|
| Example | Composition | material | compound | compound |
| 29 | Z1 | E-1 | C-11 | C-2 |
| 30 | Z2 | E-1 | C-12 | C-3 |
| 31 | Z3 | E-1 | C-13 | C-4 |
| 32 | Z4 | E-1 | C-14 | C-5 |
| 33 | Z5 | E-1 | C-15 | C-8 |
| 34 | Z6 | E-1 | C-16 | C-7 |
| 35 | Z7 | E-1 | C-17 | C-6 |
| 36 | Z8 | E-1 | C-18 | C-9 |
| 37 | Z9 | E-1 | C-19 | C-10 |
| 38 | Z10 | E-1 | C-12 | C-2 |
| 39 | Z11 | E-1 | C-13 | C-2 |
| 40 | Z12 | E-1 | C-17 | C-2 |
| 41 | Z13 | E-1 | C-12 | C-5 |
| 42 | Z14 | E-1 | C-13 | C-5 |
| 43 | Z15 | E-1 | C-17 | C-5 |
| 44 | Z16 | E-1 | C-12 | C-8 |
| 45 | Z17 | E-1 | C-13 | C-8 |
| 46 | Z18 | E-1 | C-17 | C-8 |
| 47 | Z19 | E-1 | C-12 | C-7 |
| 48 | Z20 | E-1 | C-13 | C-7 |
| 49 | Z21 | E-1 | C-17 | C-7 |
| 50 | Z22 | E-1 | C-12 | C-9 |
| 51 | Z23 | E-1 | C-13 | C-9 |
| 52 | Z24 | E-1 | C-17 | C-9 |
| 53 | Z25 | E-1 | C-12 | C-10 |
| 54 | Z26 | E-1 | C-13 | C-10 |
| 55 | Z27 | E-1 | C-17 | C-10 |
| 56 | Z28 | E-3 | C-11 | C-2 |
| 57 | Z29 | E-3 | C-12 | C-3 |
| 58 | Z30 | E-3 | C-13 | C-4 |
| 59 | Z31 | E-3 | C-14 | C-5 |
| 60 | Z32 | E-3 | C-15 | C-8 |
| 61 | Z33 | E-3 | C-16 | C-7 |
| 62 | Z34 | E-3 | C-17 | C-6 |
| 63 | Z35 | E-3 | C-18 | C-9 |
| 64 | Z36 | E-3 | C-19 | C-10 |
| 65 | Z37 | E-3 | C-12 | C-2 |
| 66 | Z38 | E-3 | C-13 | C-2 |
| 67 | Z39 | E-3 | C-17 | C-2 |
| 68 | Z40 | E-3 | C-12 | C-5 |
| 69 | Z41 | E-3 | C-13 | C-5 |
| 70 | Z42 | E-3 | C-17 | C-5 |
| 71 | Z43 | E-3 | C-12 | C-8 |
| 72 | Z44 | E-3 | C-13 | C-8 |
| 73 | Z45 | E-3 | C-17 | C-8 |
| 74 | Z46 | E-3 | C-12 | C-7 |
| 75 | Z47 | E-3 | C-13 | C-7 |
| 76 | Z48 | E-3 | C-17 | C-7 |
| 77 | Z49 | E-3 | C-12 | C-9 |
| 78 | Z50 | E-3 | C-13 | C-9 |
| 79 | Z51 | E-3 | C-17 | C-9 |
| 80 | Z52 | E-3 | C-12 | C-10 |
| 81 | Z53 | E-3 | C-13 | C-10 |
| 82 | Z54 | E-3 | C-17 | C-10 |
| 83 | Z55 | E-4 | C-11 | C-2 |
| 84 | Z56 | E-4 | C-12 | C-3 |
| 85 | Z57 | E-4 | C-13 | C-4 |
| 86 | Z58 | E-4 | C-14 | C-5 |
| 87 | Z59 | E-4 | C-15 | C-8 |
| 88 | Z60 | E-4 | C-16 | C-7 |
| 89 | Z61 | E-4 | C-17 | C-6 |
| 90 | Z62 | E-4 | C-18 | C-9 |
| 91 | Z63 | E-4 | C-19 | C-10 |
| 92 | Z64 | E-4 | C-12 | C-2 |
| 93 | Z65 | E-4 | C-13 | C-2 |
| 94 | Z66 | E-4 | C-17 | C-2 |
| 95 | Z67 | E-4 | C-12 | C-5 |
| 96 | Z68 | E-4 | C-13 | C-5 |
| 97 | Z69 | E-4 | C-17 | C-5 |
| 98 | Z70 | E-4 | C-12 | C-8 |
| 99 | Z71 | E-4 | C-13 | C-8 |
| 100 | Z72 | E-4 | C-17 | C-8 |
| 101 | Z73 | E-4 | C-12 | C-7 |
| 102 | Z74 | E-4 | C-13 | C-7 |
| 103 | Z75 | E-4 | C-17 | C-7 |
| 104 | Z76 | E-4 | C-12 | C-9 |
| 105 | Z77 | E-4 | C-13 | C-9 |
| 106 | Z78 | E-4 | C-17 | C-9 |
| 107 | Z79 | E-4 | C-12 | C-10 |
| 108 | Z80 | E-4 | C-13 | C-10 |
| 109 | Z81 | E-4 | C-17 | C-10 |
| 110 | Z82 | E-5 | C-11 | C-2 |
| 111 | Z83 | E-5 | C-12 | C-3 |
| 112 | Z84 | E-5 | C-13 | C-4 |
| 113 | Z85 | E-5 | C-14 | C-5 |
| 114 | Z86 | E-5 | C-15 | C-8 |
| 115 | Z87 | E-5 | C-16 | C-7 |
| 116 | Z88 | E-5 | C-17 | C-6 |
| 117 | Z89 | E-5 | C-18 | C-9 |
| 118 | Z90 | E-5 | C-19 | C-10 |
| 119 | Z91 | E-5 | C-12 | C-2 |
| 120 | Z92 | E-5 | C-13 | C-2 |
| 121 | Z93 | E-5 | C-17 | C-2 |
| 122 | Z94 | E-5 | C-12 | C-5 |
| 123 | Z95 | E-5 | C-13 | C-5 |
| 124 | Z96 | E-5 | C-17 | C-5 |
| 125 | Z97 | E-5 | C-12 | C-8 |
| 126 | Z98 | E-5 | C-13 | C-8 |
| 127 | Z99 | E-5 | C-17 | C-8 |
| 128 | Z100 | E-5 | C-12 | C-7 |
| 129 | Z101 | E-5 | C-13 | C-7 |
| 130 | Z102 | E-5 | C-17 | C-7 |
| 131 | Z103 | E-5 | C-12 | C-9 |
| 132 | Z104 | E-5 | C-13 | C-9 |
| 133 | Z105 | E-5 | C-17 | C-9 |
| 134 | Z106 | E-5 | C-12 | C-10 |
| 135 | Z107 | E-5 | C-13 | C-10 |
| 136 | Z108 | E-5 | C-17 | C-10 |
| 137 | Z109 | E-10 | C-11 | C-2 |
| 138 | Z110 | E-10 | C-12 | C-3 |
| 139 | Z111 | E-10 | C-13 | C-4 |
| 140 | Z112 | E-10 | C-14 | C-5 |
| 141 | Z113 | E-10 | C-15 | C-8 |
| 142 | Z114 | E-10 | C-16 | C-7 |
| 143 | Z115 | E-10 | C-17 | C-6 |
| 144 | Z116 | E-10 | C-18 | C-9 |
| 145 | Z117 | E-10 | C-19 | C-10 |
| 146 | Z118 | E-10 | C-12 | C-2 |
| 147 | Z119 | E-10 | C-13 | C-2 |
| 148 | Z120 | E-10 | C-17 | C-2 |
| 149 | Z121 | E-10 | C-12 | C-5 |
| 150 | Z122 | E-10 | C-13 | C-5 |
| 151 | Z123 | E-10 | C-17 | C-5 |
| 152 | Z124 | E-10 | C-12 | C-8 |
| 153 | Z125 | E-10 | C-13 | C-8 |
| 154 | Z126 | E-10 | C-17 | C-8 |
| 155 | Z127 | E-10 | C-12 | C-7 |
| 156 | Z128 | E-10 | C-13 | C-7 |
| 157 | Z129 | E-10 | C-17 | C-7 |
| 158 | Z130 | E-10 | C-12 | C-9 |
| 159 | Z131 | E-10 | C-13 | C-9 |
| 160 | Z132 | E-10 | C-17 | C-9 |
| 161 | Z133 | E-10 | C-12 | C-10 |
| 162 | Z134 | E-10 | C-13 | C-10 |
| 163 | Z135 | E-10 | C-17 | C-10 |
| 164 | Z136 | E-2 | C-12 | C-2 |
| 165 | Z137 | E-6 | C-13 | C-5 |
| 166 | Z138 | E-7 | C-17 | C-8 |
| 167 | Z139 | E-8 | C-12 | C-7 |
| 168 | Z140 | E-9 | C-13 | C-9 |

### Comparative Example 1

This comparative example provided Compound BH-1 that had been experimented during research, and the specific structural formula thereof was:

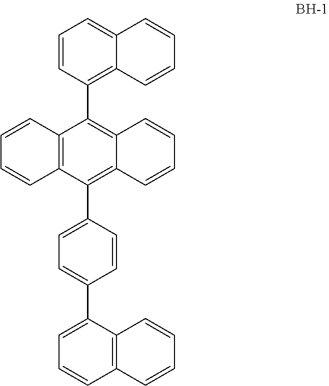 [SMILES: c1ccc2c(-c3ccc(-c4c5ccccc5c(-c5cccc6ccccc56)c5ccccc45)cc3)cccc2c1]

### Comparative Example 2

This comparative example provided Compound BH-2 that had been experimented during research, and the specific structural formula thereof was:

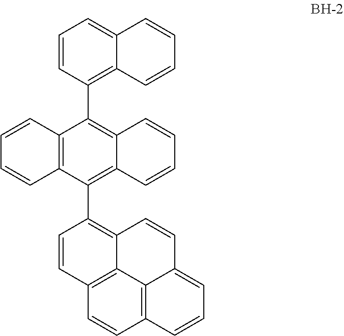 [SMILES: c1ccc2c(-c3c4ccccc4c(-c4ccc5ccc6cccc7ccc4c5c67)c4ccccc34)cccc2c1]

### Comparative Example 3

This comparative example provided Compound BD-1 that had been experimented during research, and the specific structural formula thereof was:

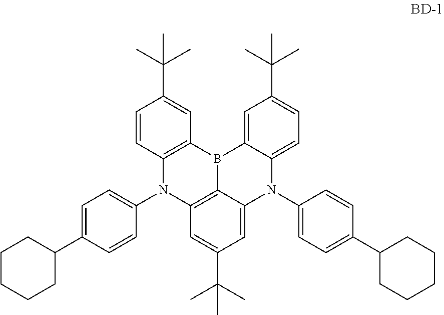 [SMILES: CC(C)(C)c1ccc2c(c1)B1c3cc(C(C)(C)C)ccc3N(c3ccc(C4CCCCC4)cc3)c3cc(C(C)(C)C)cc(c31)N2c1ccc(C2CCCCC2)cc1]

### Comparative Example 4

This comparative example provided Compound BD-2 that had been experimented during research, and the specific structural formula thereof was:

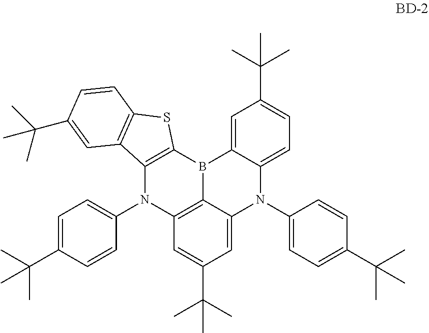 [SMILES: CC(C)(C)c1ccc(N2c3ccc(C(C)(C)C)cc3B3c4sc5ccc(C(C)(C)C)cc5c4N(c4ccc(C(C)(C)C)cc4)c4cc(C(C)(C)C)cc2c43)cc1]

### Comparative Composition Examples

### Comparative Examples 5 to 10

This comparative example provided Compositions DB1 to DB6 that had been experimented during research. Compositions DB1 to DB6 were obtained by combining the first host compound, the second host compound and the doping material according to Table 2 and uniformly mixing these materials, wherein in DB1 to DB4, the mass ratio of the first host compound to the second host compound to the doping material was 49:49:2, and in DB5 to DB6, the mass ratio of the host compound to the doping material was 98:2.

TABLE 2

| Comparative | | Doping | First host | Second host |
|---|---|---|---|---|
| Example | Composition | material | compound | compound |
| 5 | DB1 | BD-1 | C-17 | C-5 |
| 6 | DB2 | BD-2 | C-17 | C-5 |
| 7 | DB3 | E-1 | C-17 | BH-1 |
| 8 | DB4 | E-1 | BH-2 | C-5 |
| 9 | DB5 | E-1 | — | C-5 |
| 10 | DB6 | E-1 | C-17 | — |

### Evaluation of Performance of Composition

In order to explain that the composition provided by the present invention had unique advantages, the following tests were conducted:

1. In order to explain the unique advantages of the composition material provided by the present invention in terms of the interaction between the host material and the doping material, the molecular structure characteristics of the first host compound, the second host compound and the doping material in the compositions provided by Examples 29 to 168 and Comparative Examples 5 to 10 were calculated respectively. By means of Gaussian 09 W software, based on the calculation method of density functional theory (DFT) (the basis set level was set to b31yp/6-31g (d), and the charge number was 0), molecular structure geometry optimization was performed to obtain the dipole moments of the first host compound, the second host compound and the doping material in the ground state. Since the dipole moment of the second host compound was much larger than that of the first host compound, it was mainly the second host compound that produced an inducing effect on the compound structure of the doping material in the ground state. Therefore, the ratio of the dipole moments of the two, X=D_{BD}/D_{BH2}, was taken as a parameter to measure the intensity of the interaction between the host material and the doping material in the ground state. The larger this value, the smaller the dipole moment of the host compound, indicating that the interaction became weaker when the dipole moment of the doping material was constant. On this basis, the recombination energies of the first host compound and the second host compound in the compositions provided in Examples 29 to 168 and Comparative Examples 5 to 10 under positive charge and negative charge conditions were further calculated. Generally, the smaller the recombination energy, the faster the mobility. The ratio of the hole recombination energy of the first host compound obtained by calculation to the electron recombination energy of the second host compound, i.e., the value Y, was taken as a parameter to measure the host material in terms of balancing carriers, i.e., Y=λh_{BH1}/λe_{BH2}. If the value Y was less than 1, it would be biased towards holes; and if the value Y was greater than 1, it would be biased towards electrons. The closer to 1 the value Y, the more balanced the carrier transport.

2. The energy transmission between the host material and the doping material was related to the degree of overlapping between the luminescent spectrum of the host material and the absorption spectrum of the doping material. The greater the overlap integral, the greater the energy transmission between the host material and the doping material. In order to explain the relatively high energy transmission between the host material and the doping material in the composition material provided by the present invention, the fluorescence emission spectrum of the host material and the ultraviolet-visible absorption spectrum of the doping material in the compositions provided by Examples 29 to 168 and Comparative Examples 5 to 10 were tested, and the overlapping integral thereof was calculated after the spectra thereof were normalized. The ultraviolet-visible absorption spectrum of the doping material was measured by means of ultraviolet-visible spectrophotometer Model LAMBDA35 from PerkinELmer, and the fluorescence spectrum of the host material was measured by means of Fluoro Max (HORIBA) fluorescence spectrophotometer. The specific method involved separately preparing the first host compound, the second host compound and the doping material in the compositions provided in Examples 29 to 168 and Comparative Examples 5 to 10 into toluene solutions with a molar concentration of 5*10-5 mol/L for the above spectral test, processing the test results by means of Origin software, and denoting the overlap integral area between the compound as the doping material and the second host compound as S1 and the overlap integral area between the compound as the doping material and the first host compound as S2. The calculated values of X, Y, S1, and S2 were as shown in Table 3.

TABLE 3
Performance Test Results of Compositions

| Composition | X | Y | S1 | S2 |
|---|---|---|---|---|
| Z1 | 2.84 | 0.83 | 24.18 | 23.21 |
| Z2 | 5.50 | 0.80 | 22.08 | 25.36 |
| Z3 | 5.81 | 0.84 | 22.48 | 25.64 |
| Z4 | 2.08 | 0.86 | 24.81 | 24.02 |
| Z5 | 2.59 | 0.86 | 24.32 | 24.66 |
| Z6 | 2.70 | 0.81 | 24.96 | 23.56 |
| Z7 | 5.71 | 0.83 | 22.25 | 25.02 |
| Z8 | 2.34 | 0.86 | 24.49 | 24.39 |
| Z9 | 2.97 | 0.87 | 24.20 | 24.68 |
| Z10 | 2.84 | 0.98 | 24.18 | 25.36 |
| Z11 | 2.84 | 0.97 | 24.18 | 25.64 |
| Z12 | 2.84 | 0.92 | 24.18 | 25.02 |
| Z13 | 2.08 | 0.96 | 24.81 | 25.36 |
| Z14 | 2.08 | 0.95 | 24.81 | 25.64 |
| Z15 | 2.08 | 0.97 | 24.81 | 25.02 |
| Z16 | 2.59 | 0.95 | 24.32 | 25.36 |
| Z17 | 2.59 | 0.91 | 24.32 | 25.64 |
| Z18 | 2.59 | 0.96 | 24.32 | 25.02 |
| Z19 | 2.70 | 0.91 | 24.96 | 25.36 |
| Z20 | 2.70 | 0.94 | 24.96 | 25.64 |
| Z21 | 2.70 | 0.95 | 24.96 | 25.02 |
| Z22 | 2.34 | 0.97 | 24.49 | 25.36 |
| Z23 | 2.34 | 0.97 | 24.49 | 25.64 |
| Z24 | 2.34 | 0.90 | 24.49 | 25.02 |
| Z25 | 2.97 | 0.95 | 24.20 | 25.36 |
| Z26 | 2.97 | 0.93 | 24.20 | 25.64 |
| Z27 | 2.97 | 0.99 | 24.20 | 25.02 |
| Z28 | 2.89 | 0.83 | 24.64 | 23.12 |
| Z29 | 5.63 | 0.80 | 22.79 | 25.77 |
| Z30 | 5.69 | 0.84 | 22.63 | 25.98 |
| Z31 | 2.98 | 0.86 | 24.90 | 24.30 |
| Z32 | 2.78 | 0.86 | 24.59 | 24.76 |
| Z33 | 2.91 | 0.81 | 24.09 | 23.82 |
| Z34 | 5.99 | 0.83 | 22.07 | 25.23 |
| Z35 | 2.84 | 0.86 | 24.61 | 24.67 |
| Z36 | 2.05 | 0.87 | 24.14 | 24.15 |
| Z37 | 2.89 | 0.98 | 24.64 | 25.77 |
| Z38 | 2.89 | 0.97 | 24.64 | 25.98 |
| Z39 | 2.89 | 0.92 | 24.64 | 25.23 |
| Z40 | 2.98 | 0.96 | 24.90 | 25.77 |
| Z41 | 2.98 | 0.95 | 24.90 | 25.98 |
| Z42 | 2.98 | 0.97 | 24.90 | 25.23 |
| Z43 | 2.78 | 0.95 | 24.59 | 25.77 |
| Z44 | 2.78 | 0.91 | 24.59 | 25.98 |
| Z45 | 2.78 | 0.96 | 24.59 | 25.23 |
| Z46 | 2.91 | 0.91 | 24.09 | 25.77 |
| Z47 | 2.91 | 0.94 | 24.09 | 25.98 |
| Z48 | 2.91 | 0.95 | 24.09 | 25.23 |
| Z49 | 2.84 | 0.97 | 24.61 | 25.77 |
| Z50 | 2.84 | 0.97 | 24.61 | 25.98 |
| Z51 | 2.84 | 0.90 | 24.61 | 25.23 |
| Z52 | 2.05 | 0.95 | 24.14 | 25.77 |
| Z53 | 2.05 | 0.93 | 24.14 | 25.98 |
| Z54 | 2.05 | 0.99 | 24.14 | 25.23 |
| Z55 | 2.90 | 0.83 | 24.42 | 23.44 |
| Z56 | 5.59 | 0.80 | 22.18 | 25.04 |
| Z57 | 5.43 | 0.84 | 22.59 | 25.34 |
| Z58 | 2.05 | 0.86 | 24.51 | 24.97 |
| Z59 | 2.19 | 0.86 | 24.98 | 24.83 |
| Z60 | 2.40 | 0.81 | 24.40 | 23.79 |
| Z61 | 5.80 | 0.83 | 22.24 | 25.75 |
| Z62 | 2.95 | 0.86 | 24.61 | 24.35 |
| Z63 | 2.36 | 0.87 | 24.75 | 24.59 |
| Z64 | 2.90 | 0.98 | 24.42 | 25.04 |
| Z65 | 2.90 | 0.97 | 24.42 | 25.34 |
| Z66 | 2.90 | 0.92 | 24.42 | 25.75 |
| Z67 | 2.05 | 0.96 | 24.51 | 25.04 |
| Z68 | 2.05 | 0.95 | 24.51 | 25.34 |
| Z69 | 2.05 | 0.97 | 24.51 | 25.75 |
| Z70 | 2.19 | 0.95 | 24.98 | 25.04 |
| Z71 | 2.19 | 0.91 | 24.98 | 25.34 |
| Z72 | 2.19 | 0.96 | 24.98 | 25.75 |
| Z73 | 2.40 | 0.91 | 24.40 | 25.04 |
| Z74 | 2.40 | 0.94 | 24.40 | 25.34 |
| Z75 | 2.40 | 0.95 | 24.40 | 25.75 |
| Z76 | 2.95 | 0.97 | 24.61 | 25.04 |
| Z77 | 2.95 | 0.97 | 24.61 | 25.34 |
| Z78 | 2.95 | 0.90 | 24.61 | 25.75 |
| Z79 | 2.36 | 0.95 | 24.75 | 25.04 |
| Z80 | 2.36 | 0.93 | 24.75 | 25.34 |
| Z81 | 2.36 | 0.99 | 24.75 | 25.75 |
| Z82 | 2.61 | 0.83 | 24.87 | 23.40 |
| Z83 | 5.74 | 0.80 | 22.63 | 25.65 |
| Z84 | 5.29 | 0.84 | 22.53 | 25.63 |
| Z85 | 2.50 | 0.86 | 24.82 | 24.95 |
| Z86 | 2.07 | 0.86 | 24.97 | 24.54 |
| Z87 | 2.85 | 0.81 | 24.15 | 23.08 |
| Z88 | 5.79 | 0.83 | 22.23 | 25.73 |
| Z89 | 2.38 | 0.86 | 24.20 | 24.65 |
| Z90 | 2.06 | 0.87 | 24.25 | 24.75 |
| Z91 | 2.61 | 0.98 | 24.87 | 25.65 |
| Z92 | 2.61 | 0.97 | 24.87 | 25.63 |
| Z93 | 2.61 | 0.92 | 24.87 | 25.73 |
| Z94 | 2.50 | 0.96 | 24.82 | 25.65 |
| Z95 | 2.50 | 0.95 | 24.82 | 25.63 |
| Z96 | 2.50 | 0.97 | 24.82 | 25.73 |
| Z97 | 2.07 | 0.95 | 24.97 | 25.65 |
| Z98 | 2.07 | 0.91 | 24.97 | 25.63 |
| Z99 | 2.07 | 0.96 | 24.97 | 25.73 |
| Z100 | 2.85 | 0.91 | 24.15 | 25.65 |
| Z101 | 2.85 | 0.94 | 24.15 | 25.63 |
| Z102 | 2.85 | 0.95 | 24.15 | 25.73 |
| Z103 | 2.38 | 0.97 | 24.20 | 25.65 |
| Z104 | 2.38 | 0.97 | 24.20 | 25.63 |
| Z105 | 2.38 | 0.90 | 24.20 | 25.73 |
| Z106 | 2.06 | 0.95 | 24.25 | 25.65 |
| Z107 | 2.06 | 0.93 | 24.25 | 25.63 |
| Z108 | 2.06 | 0.99 | 24.25 | 25.73 |
| Z109 | 2.99 | 0.83 | 24.27 | 23.22 |
| Z110 | 5.60 | 0.80 | 22.57 | 25.74 |
| Z111 | 5.20 | 0.84 | 22.24 | 25.30 |
| Z112 | 2.43 | 0.86 | 24.37 | 24.26 |
| Z113 | 2.96 | 0.86 | 24.00 | 24.51 |
| Z114 | 2.80 | 0.81 | 24.46 | 23.67 |
| Z115 | 5.67 | 0.83 | 22.06 | 25.81 |
| Z116 | 2.51 | 0.86 | 24.46 | 24.43 |
| Z117 | 2.42 | 0.87 | 24.40 | 24.79 |
| Z118 | 2.99 | 0.98 | 24.27 | 25.74 |
| Z119 | 2.99 | 0.97 | 24.27 | 25.30 |
| Z120 | 2.99 | 0.92 | 24.27 | 25.81 |
| Z121 | 2.43 | 0.96 | 24.37 | 25.74 |
| Z122 | 2.43 | 0.95 | 24.37 | 25.30 |
| Z123 | 2.43 | 0.97 | 24.37 | 25.81 |
| Z124 | 2.96 | 0.95 | 24.00 | 25.74 |
| Z125 | 2.96 | 0.91 | 24.00 | 25.30 |
| Z126 | 2.96 | 0.96 | 24.00 | 25.81 |
| Z127 | 2.80 | 0.91 | 24.46 | 25.74 |
| Z128 | 2.80 | 0.94 | 24.46 | 25.30 |
| Z129 | 2.80 | 0.95 | 24.46 | 25.81 |
| Z130 | 2.51 | 0.97 | 24.46 | 25.74 |
| Z131 | 2.51 | 0.97 | 24.46 | 25.30 |
| Z132 | 2.51 | 0.90 | 24.46 | 25.81 |
| Z133 | 2.42 | 0.95 | 24.40 | 25.74 |
| Z134 | 2.42 | 0.93 | 24.40 | 25.30 |
| Z135 | 2.42 | 0.99 | 24.40 | 25.81 |
| Z136 | 3.75 | 0.98 | 23.79 | 24.18 |
| Z137 | 4.55 | 0.95 | 23.71 | 24.82 |
| Z138 | 4.84 | 0.96 | 23.59 | 24.76 |
| Z139 | 3.92 | 0.91 | 23.79 | 24.99 |
| Z140 | 3.22 | 0.97 | 23.98 | 24.92 |
| DB1 | 18.27 | 0.98 | 20.33 | 21.92 |
| DB2 | 18.19 | 0.97 | 20.52 | 21.87 |
| DB3 | 19.42 | 0.58 | 20.75 | 25.02 |
| DB4 | 20.08 | 0.60 | 24.81 | 21.21 |
| DB5 | 20.11 | 0.52 | 24.46 | 0 |
| DB6 | 20.12 | 0.53 | 0 | 24.98 |

As could be seen from the data in Table 3, the composition provided by the present invention had a lower value of X. If any one of the dopant, the first host compound, or the second host compound in Composition Z15 provided by the present invention was replaced with another commonly used compound of the same type or removed, the value X would significantly increase, indicating that there was a relatively strong interaction between the first host compound, the second host compound, and the doping material in the composition provided by the present invention. Since the second host compound provided by the present invention contained a benzofuran structure and the compound as the doping material contained a thiophene structure, the composition provided by the present invention could provide an enhanced dipole-dipole interaction between the host material and the doping material by means of the interaction of the above two structures and thus enhanced FORSTER energy transmission of the luminescent material. From the data in Table 3, it could be seen that the value Y of the composition provided by the present invention was closer to 1. If either the first host compound or the second host compound in Composition Z15 provided by the present invention was replaced with another commonly used compound of the same type or removed, the value Y would significantly deviate from 1, indicating that the hole and electron transport between the first host compound and the second host compound in the composition provided by the present invention was more balanced. As could be seen from the data in Table 3, compared with the compositions of the comparative examples, the overlap integral area between the luminescent spectrum of the host material and the absorption spectrum of the doping material in the composition provided by the present invention was larger, indicating that the energy transmission between the host material and the doping material in the composition provided by the present invention was more sufficient.

### Device Example 1

This example provided a blue-light organic electroluminescent device, the preparation method of which was as follows: firstly, on an ITO layer (anode) formed on a substrate, HTL and p-dopant (at a mass ratio of HTL to p-dopant of 97:3) were deposited in vacuo to a thickness of 10 nm to form a hole injection layer; secondly, on the above hole injection layer, HTL was deposited in vacuo to a thickness of 120 nm to form a hole transport layer; thirdly, on the above hole transport layer, B prime was deposited in vacuo to a thickness of 5 nm to form a luminescent auxiliary layer; again, on the above luminescent auxiliary layer, a mixture of a host material and a doping material was vacuum-deposited with a thickness of 20 nm to form a luminescent layer, wherein C-11 was the first host compound, C-2 was the second host compound, and E-1 was the doping material, and the mass ratio of the first host compound to the second host compound to the doping material was 49:49:2; next, on the above luminescent layer, HBL was deposited in vacuo to a thickness of 5 nm to form a hole barrier layer; a mixture of ET and Liq (the mass ratio of ET to Liq was 1:1) was deposited in vacuo to a thickness of 30 nm to form an electron transport layer; then, on the above electron transport layer, LiF was deposited to a thickness of 0.2 nm to form an electron injection layer; and finally, on the above electron injection layer, aluminum (Al) was deposited to a thickness of 150 nm to form a cathode, thereby preparing a blue-light organic electroluminescent device.

The molecular structural formulas of the materials of the layers other than the host materials and the doping material in the luminescent layer were as follows:

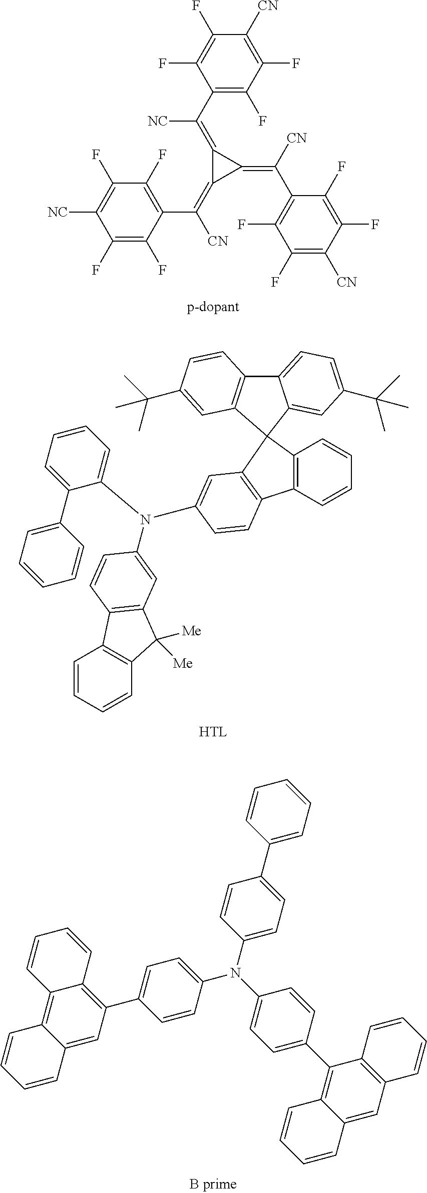 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; c1ccc(-c2ccc(N(c3ccc(-c4c5ccccc5cc5ccccc45)cc3)c3ccc(-c4cc5ccccc5c5ccccc45)cc3)cc2)cc1]

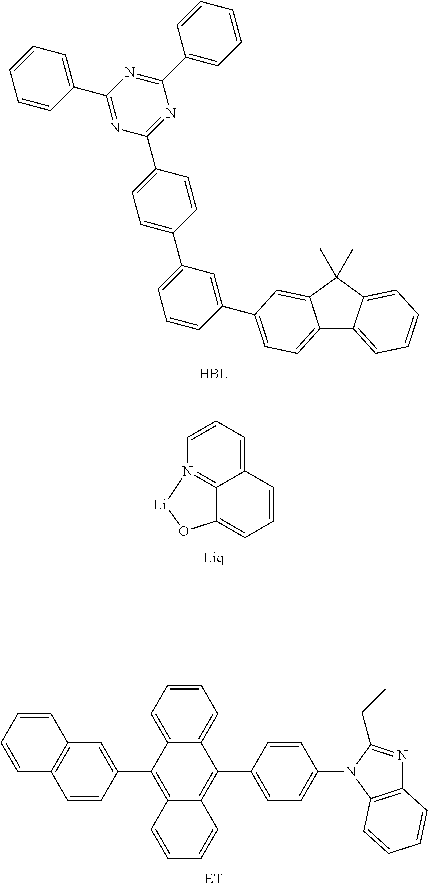

The electrode preparation method and the deposition method for each functional layer in this implementation were both conventional methods in the art, such as vacuum thermal evaporation or ink-jet printing. No more unnecessary repetition would be given here.

### Device Examples 2-140

The method was the same as that in Device Example 1, except that the luminescent layer material was replaced with the compositions of Examples 30 to 168, respectively. The host materials and doping materials in the device examples were found in Table 4.

TABLE 4
Comparison table of host materials and
doping materials in device examples

| | Doping | First host | Second host |
|---|---|---|---|
| Device Example | material | compound | compound |
| Device Example 1 | E-1 | C-11 | C-2 |
| Device Example 2 | E-1 | C-12 | C-3 |
| Device Example 3 | E-1 | C-13 | C-4 |
| Device Example 4 | E-1 | C-14 | C-5 |
| Device Example 5 | E-1 | C-15 | C-8 |
| Device Example 6 | E-1 | C-16 | C-7 |
| Device Example 7 | E-1 | C-17 | C-6 |
| Device Example 8 | E-1 | C-18 | C-9 |
| Device Example 9 | E-1 | C-19 | C-10 |
| Device Example 10 | E-1 | C-12 | C-2 |
| Device Example 11 | E-1 | C-13 | C-2 |
| Device Example 12 | E-1 | C-17 | C-2 |
| Device Example 13 | E-1 | C-12 | C-5 |
| Device Example 14 | E-1 | C-13 | C-5 |
| Device Example 15 | E-1 | C-17 | C-5 |
| Device Example 16 | E-1 | C-12 | C-8 |
| Device Example 17 | E-1 | C-13 | C-8 |
| Device Example 18 | E-1 | C-17 | C-8 |
| Device Example 19 | E-1 | C-12 | C-7 |
| Device Example 20 | E-1 | C-13 | C-7 |
| Device Example 21 | E-1 | C-17 | C-7 |
| Device Example 22 | E-1 | C-12 | C-9 |
| Device Example 23 | E-1 | C-13 | C-9 |
| Device Example 24 | E-1 | C-17 | C-9 |
| Device Example 25 | E-1 | C-12 | C-10 |
| Device Example 26 | E-1 | C-13 | C-10 |
| Device Example 27 | E-1 | C-17 | C-10 |
| Device Example 28 | E-3 | C-11 | C-2 |
| Device Example 29 | E-3 | C-12 | C-3 |
| Device Example 30 | E-3 | C-13 | C-4 |
| Device Example 31 | E-3 | C-14 | C-5 |
| Device Example 32 | E-3 | C-15 | C-8 |
| Device Example 33 | E-3 | C-16 | C-7 |
| Device Example 34 | E-3 | C-17 | C-6 |
| Device Example 35 | E-3 | C-18 | C-9 |
| Device Example 36 | E-3 | C-19 | C-10 |
| Device Example 37 | E-3 | C-12 | C-2 |
| Device Example 38 | E-3 | C-13 | C-2 |
| Device Example 39 | E-3 | C-17 | C-2 |
| Device Example 40 | E-3 | C-12 | C-5 |
| Device Example 41 | E-3 | C-13 | C-5 |
| Device Example 42 | E-3 | C-17 | C-5 |
| Device Example 43 | E-3 | C-12 | C-8 |
| Device Example 44 | E-3 | C-13 | C-8 |
| Device Example 45 | E-3 | C-17 | C-8 |
| Device Example 46 | E-3 | C-12 | C-7 |
| Device Example 47 | E-3 | C-13 | C-7 |
| Device Example 48 | E-3 | C-17 | C-7 |
| Device Example 49 | E-3 | C-12 | C-9 |
| Device Example 50 | E-3 | C-13 | C-9 |
| Device Example 51 | E-3 | C-17 | C-9 |
| Device Example 52 | E-3 | C-12 | C-10 |
| Device Example 53 | E-3 | C-13 | C-10 |
| Device Example 54 | E-3 | C-17 | C-10 |
| Device Example 55 | E-4 | C-11 | C-2 |
| Device Example 56 | E-4 | C-12 | C-3 |
| Device Example 57 | E-4 | C-13 | C-4 |
| Device Example 58 | E-4 | C-14 | C-5 |
| Device Example 59 | E-4 | C-15 | C-8 |
| Device Example 60 | E-4 | C-16 | C-7 |
| Device Example 61 | E-4 | C-17 | C-6 |
| Device Example 62 | E-4 | C-18 | C-9 |
| Device Example 63 | E-4 | C-19 | C-10 |
| Device Example 64 | E-4 | C-12 | C-2 |
| Device Example 65 | E-4 | C-13 | C-2 |
| Device Example 66 | E-4 | C-17 | C-2 |
| Device Example 67 | E-4 | C-12 | C-5 |
| Device Example 68 | E-4 | C-13 | C-5 |
| Device Example 69 | E-4 | C-17 | C-5 |
| Device Example 70 | E-4 | C-12 | C-8 |
| Device Example 71 | E-4 | C-13 | C-8 |
| Device Example 72 | E-4 | C-17 | C-8 |
| Device Example 73 | E-4 | C-12 | C-7 |
| Device Example 74 | E-4 | C-13 | C-7 |
| Device Example 75 | E-4 | C-17 | C-7 |
| Device Example 76 | E-4 | C-12 | C-9 |
| Device Example 77 | E-4 | C-13 | C-9 |
| Device Example 78 | E-4 | C-17 | C-9 |
| Device Example 79 | E-4 | C-12 | C-10 |
| Device Example 80 | E-4 | C-13 | C-10 |
| Device Example 81 | E-4 | C-17 | C-10 |
| Device Example 82 | E-5 | C-11 | C-2 |
| Device Example 83 | E-5 | C-12 | C-3 |
| Device Example 84 | E-5 | C-13 | C-4 |
| Device Example 85 | E-5 | C-14 | C-5 |
| Device Example 86 | E-5 | C-15 | C-8 |
| Device Example 87 | E-5 | C-16 | C-7 |
| Device Example 88 | E-5 | C-17 | C-6 |
| Device Example 89 | E-5 | C-18 | C-9 |
| Device Example 90 | E-5 | C-19 | C-10 |
| Device Example 91 | E-5 | C-12 | C-2 |
| Device Example 92 | E-5 | C-13 | C-2 |
| Device Example 93 | E-5 | C-17 | C-2 |
| Device Example 94 | E-5 | C-12 | C-5 |
| Device Example 95 | E-5 | C-13 | C-5 |
| Device Example 96 | E-5 | C-17 | C-5 |
| Device Example 97 | E-5 | C-12 | C-8 |
| Device Example 98 | E-5 | C-13 | C-8 |
| Device Example 99 | E-5 | C-17 | C-8 |
| Device Example 100 | E-5 | C-12 | C-7 |
| Device Example 101 | E-5 | C-13 | C-7 |
| Device Example 102 | E-5 | C-17 | C-7 |
| Device Example 103 | E-5 | C-12 | C-9 |
| Device Example 104 | E-5 | C-13 | C-9 |
| Device Example 105 | E-5 | C-17 | C-9 |
| Device Example 106 | E-5 | C-12 | C-10 |
| Device Example 107 | E-5 | C-13 | C-10 |
| Device Example 108 | E-5 | C-17 | C-10 |
| Device Example 109 | E-10 | C-11 | C-2 |
| Device Example 110 | E-10 | C-12 | C-3 |
| Device Example 111 | E-10 | C-13 | C-4 |
| Device Example 112 | E-10 | C-14 | C-5 |
| Device Example 113 | E-10 | C-15 | C-8 |
| Device Example 114 | E-10 | C-16 | C-7 |
| Device Example 115 | E-10 | C-17 | C-6 |
| Device Example 116 | E-10 | C-18 | C-9 |
| Device Example 117 | E-10 | C-19 | C-10 |
| Device Example 118 | E-10 | C-12 | C-2 |
| Device Example 119 | E-10 | C-13 | C-2 |
| Device Example 120 | E-10 | C-17 | C-2 |
| Device Example 121 | E-10 | C-12 | C-5 |
| Device Example 122 | E-10 | C-13 | C-5 |
| Device Example 123 | E-10 | C-17 | C-5 |
| Device Example 124 | E-10 | C-12 | C-8 |
| Device Example 125 | E-10 | C-13 | C-8 |
| Device Example 126 | E-10 | C-17 | C-8 |
| Device Example 127 | E-10 | C-12 | C-7 |
| Device Example 128 | E-10 | C-13 | C-7 |
| Device Example 129 | E-10 | C-17 | C-7 |
| Device Example 130 | E-10 | C-12 | C-9 |
| Device Example 131 | E-10 | C-13 | C-9 |
| Device Example 132 | E-10 | C-17 | C-9 |
| Device Example 133 | E-10 | C-12 | C-10 |
| Device Example 134 | E-10 | C-13 | C-10 |
| Device Example 135 | E-10 | C-17 | C-10 |
| Device Example 136 | E-2 | C-12 | C-2 |
| Device Example 137 | E-6 | C-13 | C-5 |
| Device Example 138 | E-7 | C-17 | C-8 |
| Device Example 139 | E-8 | C-12 | C-7 |
| Device Example 140 | E-9 | C-13 | C-9 |

### Comparative Device Examples 1-6

The method was the same as that in Device Example 1, except that the luminescent layer material was replaced with the compositions of Comparative Examples 5 to 10. The host materials and doping materials in the comparative device examples were found in Table 5.

TABLE 5
Comparison table of host materials and doping
materials in comparative device examples

| Comparative Device | Doping | First host | Second host |
|---|---|---|---|
| Example | material | compound | compound |
| Comparative Device | BD-1 | C-17 | C-5 |
| Example 1 | | | |
| Comparative Device | BD-2 | C-17 | C-5 |
| Example 2 | | | |
| Comparative Device | E-1 | C-17 | BH-1 |
| Example 3 | | | |
| Comparative Device | E-1 | BH-2 | C-5 |
| Example 4 | | | |
| Comparative Device | E-1 | — | C-5 |
| Example 5 | | | |
| Comparative Device | E-1 | C-17 | — |
| Example 6 | | | |

### Device Performance Effect Example

The organic electroluminescent devices provided by Device Examples 1-140 and Comparative Device Examples 1-6 were tested by standard methods. In this regard, the organic electroluminescent devices were measured at a current density of J=20 mA/cm² for the driving voltage, brightness, electroluminescent current efficiency (measured as cd/A), and external quantum efficiency (EQE, measured by percentage), calculated, as a function of luminous density, from the current/voltage/luminous density characteristic curves (IVL characteristic curves) showing Lambertian emission characteristics, luminous spectrum. The lifetime LT was defined as the time for the brightness to decrease from the initial luminous brightness L₀ to a specific proportion L₁, during working at a constant current J; The expressions J=50 mA/cm² and L₁=90% meant that during working at 50 mA/cm², the luminous brightness decreased to 90% of the initial value L₀ thereof after the time LT. Similarly, the expressions J=20 mA/cm² and L₁=80% meant that during working at 20 mA/cm², the luminous brightness decreased to 80% of the initial value L₀ thereof after the time LT.

The test instruments and methods for testing the performance of the above OLED devices were as follows:
the brightness was tested by means of spectrum scanner PhotoResearch PR-635;
the current density and turn-on voltage were tested by digital SourceMeter Keithley 2400; and
lifetime test: LT-96ch lifetime test device was used.

The performance test results of the above devices were listed in Table 6.

TABLE 6
Performance test results of blue-light devices

| | | | @J = 20 mA/cm² | |
|---|---|---|---|---|
| | Vop (V) | EQE (%) | LT95 (h) | Color |
| Device Example 1 | 3.97 | 6.59 | 122.00 | Blue |
| Device Example 2 | 3.97 | 6.5 | 115.00 | Blue |
| Device Example 3 | 3.98 | 6.81 | 124.00 | Blue |
| Device Example 4 | 3.80 | 7.15 | 132.00 | Blue |
| Device Example 5 | 3.85 | 7.33 | 132.00 | Blue |
| Device Example 6 | 3.92 | 6.78 | 117.00 | Blue |
| Device Example 7 | 3.97 | 6.8 | 116.00 | Blue |
| Device Example 8 | 3.86 | 7.19 | 148.00 | Blue |
| Device Example 9 | 3.83 | 7.4 | 131.00 | Blue |
| Device Example 10 | 3.72 | 8.38 | 152.00 | Blue |
| Device Example 11 | 3.76 | 8.48 | 160.00 | Blue |
| Device Example 12 | 3.71 | 7.75 | 165.00 | Blue |
| Device Example 13 | 3.73 | 7.81 | 170.00 | Blue |
| Device Example 14 | 3.78 | 8.18 | 156.00 | Blue |
| Device Example 15 | 3.74 | 7.61 | 163.00 | Blue |
| Device Example 16 | 3.76 | 8.34 | 157.00 | Blue |
| Device Example 17 | 3.72 | 7.89 | 167.00 | Blue |
| Device Example 18 | 3.70 | 7.88 | 169.00 | Blue |
| Device Example 19 | 3.71 | 7.85 | 155.00 | Blue |
| Device Example 20 | 3.70 | 8.18 | 152.00 | Blue |
| Device Example 21 | 3.77 | 8.48 | 163.00 | Blue |
| Device Example 22 | 3.71 | 7.83 | 169.00 | Blue |
| Device Example 23 | 3.76 | 8.46 | 159.00 | Blue |
| Device Example 24 | 3.72 | 7.99 | 154.00 | Blue |
| Device Example 25 | 3.72 | 7.55 | 163.00 | Blue |
| Device Example 26 | 3.73 | 7.56 | 170.00 | Blue |
| Device Example 27 | 3.77 | 8.45 | 155.00 | Blue |
| Device Example 28 | 3.96 | 6.55 | 118.00 | Blue |
| Device Example 29 | 3.93 | 6.7 | 124.00 | Blue |
| Device Example 30 | 4.00 | 6.61 | 119.00 | Blue |
| Device Example 31 | 3.81 | 7.05 | 131.00 | Blue |
| Device Example 32 | 3.86 | 7.17 | 137.00 | Blue |
| Device Example 33 | 3.91 | 6.96 | 120.00 | Blue |
| Device Example 34 | 3.92 | 6.72 | 122.00 | Blue |
| Device Example 35 | 3.85 | 7.23 | 133.00 | Blue |
| Device Example 36 | 3.88 | 7.09 | 131.00 | Blue |
| Device Example 37 | 3.75 | 8.37 | 163.00 | Blue |
| Device Example 38 | 3.72 | 8.29 | 166.00 | Blue |
| Device Example 39 | 3.76 | 8.4 | 155.00 | Blue |
| Device Example 40 | 3.71 | 7.84 | 162.00 | Blue |
| Device Example 41 | 3.77 | 7.68 | 163.00 | Blue |
| Device Example 42 | 3.73 | 8.17 | 160.00 | Blue |
| Device Example 43 | 3.76 | 8.32 | 154.00 | Blue |
| Device Example 44 | 3.76 | 7.64 | 150.00 | Blue |
| Device Example 45 | 3.70 | 8.33 | 164.00 | Blue |
| Device Example 46 | 3.70 | 8.23 | 153.00 | Blue |
| Device Example 47 | 3.75 | 8.02 | 169.00 | Blue |
| Device Example 48 | 3.74 | 8.02 | 159.00 | Blue |
| Device Example 49 | 3.72 | 8.43 | 170.00 | Blue |
| Device Example 50 | 3.73 | 7.79 | 163.00 | Blue |
| Device Example 51 | 3.73 | 8.29 | 166.00 | Blue |
| Device Example 52 | 3.72 | 7.99 | 160.00 | Blue |
| Device Example 53 | 3.70 | 8.32 | 153.00 | Blue |
| Device Example 54 | 3.71 | 8.29 | 151.00 | Blue |
| Device Example 55 | 3.90 | 6.75 | 113.00 | Blue |
| Device Example 56 | 3.95 | 6.93 | 120.00 | Blue |
| Device Example 57 | 3.98 | 6.57 | 121.00 | Blue |
| Device Example 58 | 3.85 | 7.29 | 149.00 | Blue |
| Device Example 59 | 3.85 | 7.41 | 133.00 | Blue |
| Device Example 60 | 3.99 | 6.97 | 111.00 | Blue |
| Device Example 61 | 3.99 | 6.95 | 119.00 | Blue |
| Device Example 62 | 3.87 | 7.3 | 133.00 | Blue |
| Device Example 63 | 3.85 | 7.43 | 137.00 | Blue |
| Device Example 64 | 3.77 | 8.31 | 168.00 | Blue |
| Device Example 65 | 3.72 | 7.71 | 155.00 | Blue |
| Device Example 66 | 3.78 | 7.82 | 150.00 | Blue |
| Device Example 67 | 3.79 | 8.06 | 166.00 | Blue |
| Device Example 68 | 3.79 | 7.68 | 169.00 | Blue |
| Device Example 69 | 3.76 | 7.53 | 167.00 | Blue |
| Device Example 70 | 3.79 | 7.91 | 151.00 | Blue |
| Device Example 71 | 3.70 | 7.63 | 167.00 | Blue |
| Device Example 72 | 3.79 | 8.24 | 163.00 | Blue |
| Device Example 73 | 3.73 | 7.52 | 162.00 | Blue |
| Device Example 74 | 3.77 | 8.05 | 167.00 | Blue |
| Device Example 75 | 3.79 | 7.5 | 168.00 | Blue |
| Device Example 76 | 3.79 | 8.23 | 165.00 | Blue |
| Device Example 77 | 3.78 | 8.07 | 151.00 | Blue |
| Device Example 78 | 3.72 | 8.29 | 168.00 | Blue |
| Device Example 79 | 3.74 | 8.19 | 166.00 | Blue |
| Device Example 80 | 3.73 | 7.64 | 164.00 | Blue |
| Device Example 81 | 3.74 | 7.7 | 152.00 | Blue |
| Device Example 82 | 3.95 | 6.75 | 120.00 | Blue |
| Device Example 83 | 3.92 | 6.81 | 122.00 | Blue |
| Device Example 84 | 3.97 | 6.98 | 117.00 | Blue |
| Device Example 85 | 3.86 | 7.46 | 144.00 | Blue |
| Device Example 86 | 3.80 | 7.08 | 135.00 | Blue |
| Device Example 87 | 3.91 | 6.53 | 126.00 | Blue |
| Device Example 88 | 3.95 | 6.68 | 128.00 | Blue |
| Device Example 89 | 3.85 | 7.39 | 138.00 | Blue |
| Device Example 90 | 3.85 | 7.17 | 136.00 | Blue |
| Device Example 91 | 3.79 | 7.75 | 170.00 | Blue |
| Device Example 92 | 3.75 | 7.95 | 168.00 | Blue |
| Device Example 93 | 3.76 | 8.23 | 168.00 | Blue |
| Device Example 94 | 3.78 | 7.63 | 156.00 | Blue |
| Device Example 95 | 3.76 | 8.32 | 168.00 | Blue |
| Device Example 96 | 3.73 | 7.98 | 162.00 | Blue |
| Device Example 97 | 3.71 | 7.71 | 165.00 | Blue |
| Device Example 98 | 3.78 | 7.68 | 160.00 | Blue |
| Device Example 99 | 3.75 | 8.36 | 164.00 | Blue |
| Device Example 100 | 3.77 | 7.95 | 161.00 | Blue |
| Device Example 101 | 3.74 | 8.38 | 150.00 | Blue |
| Device Example 102 | 3.78 | 7.72 | 167.00 | Blue |
| Device Example 103 | 3.72 | 8.11 | 166.00 | Blue |
| Device Example 104 | 3.74 | 8.37 | 153.00 | Blue |
| Device Example 105 | 3.75 | 7.99 | 163.00 | Blue |
| Device Example 106 | 3.74 | 8.36 | 150.00 | Blue |
| Device Example 107 | 3.77 | 7.84 | 169.00 | Blue |
| Device Example 108 | 3.71 | 8.3 | 155.00 | Blue |
| Device Example 109 | 3.91 | 6.92 | 126.00 | Blue |
| Device Example 110 | 3.91 | 6.83 | 113.00 | Blue |
| Device Example 111 | 3.96 | 6.64 | 127.00 | Blue |
| Device Example 112 | 3.83 | 7.05 | 132.00 | Blue |
| Device Example 113 | 3.88 | 7.36 | 145.00 | Blue |
| Device Example 114 | 3.99 | 6.84 | 124.00 | Blue |
| Device Example 115 | 3.91 | 6.5 | 111.00 | Blue |
| Device Example 116 | 3.89 | 7.43 | 134.00 | Blue |
| Device Example 117 | 3.81 | 7.37 | 148.00 | Blue |
| Device Example 118 | 3.79 | 7.93 | 165.00 | Blue |
| Device Example 119 | 3.71 | 7.51 | 165.00 | Blue |
| Device Example 120 | 3.72 | 7.51 | 156.00 | Blue |
| Device Example 121 | 3.76 | 7.99 | 154.00 | Blue |
| Device Example 122 | 3.72 | 8.37 | 164.00 | Blue |
| Device Example 123 | 3.71 | 7.71 | 168.00 | Blue |
| Device Example 124 | 3.75 | 8.41 | 152.00 | Blue |
| Device Example 125 | 3.75 | 8.25 | 163.00 | Blue |
| Device Example 126 | 3.74 | 8.31 | 160.00 | Blue |
| Device Example 127 | 3.78 | 8.47 | 153.00 | Blue |
| Device Example 128 | 3.74 | 7.71 | 157.00 | Blue |
| Device Example 129 | 3.72 | 7.73 | 166.00 | Blue |
| Device Example 130 | 3.70 | 7.96 | 163.00 | Blue |
| Device Example 131 | 3.78 | 8.03 | 162.00 | Blue |
| Device Example 132 | 3.73 | 8.42 | 167.00 | Blue |
| Device Example 133 | 3.73 | 7.68 | 160.00 | Blue |
| Device Example 134 | 3.72 | 8.15 | 152.00 | Blue |
| Device Example 135 | 3.75 | 8.13 | 152.00 | Blue |
| Device Example 136 | 3.80 | 7.46 | 144.00 | Blue |
| Device Example 137 | 3.84 | 7.29 | 131.00 | Blue |
| Device Example 138 | 3.88 | 7.36 | 142.00 | Blue |
| Device Example 139 | 3.88 | 7.02 | 142.00 | Blue |
| Device Example 140 | 3.86 | 7.02 | 145.00 | Blue |
| Comparative | 4.03 | 5.52 | 91.00 | Blue |
| Device Example 1 | | | | |
| Comparative | 4.06 | 5.86 | 91.00 | Blue |
| Device Example 2 | | | | |
| Comparative | 4.07 | 5.80 | 83.00 | Blue |
| Device Example 3 | | | | |
| Comparative | 4.03 | 5.83 | 92.00 | Blue |
| Device Example 4 | | | | |
| Comparative | 4.12 | 5.81 | 75.00 | Blue |
| Device Example 5 | | | | |
| Comparative | 4.13 | 5.82 | 76.00 | Blue |
| Device Example 6 | | | | |

From the device performance test results in Table 6 above, it could be seen that compared with the devices of the comparative examples, the efficiency and lifetime of the organic electroluminescent device provided by the present invention were significantly improved. If any one of the dopant, the first host compound, or the second host compound in Device Example 15 provided by the present invention was replaced with another commonly used compound of the same type or removed, the efficiency and lifetime thereof would both significantly increase. The reason lay in that there was a large steric hindrance between the first host compound and the compound as the doping material in the composition provided by the present invention, which could effectively avoid the aggregation of the compound as the doping material, avoid the problem of efficiency reduction caused by concentration quenching, and thus prolong the lifetime of the organic electroluminescent device. There was a relatively strong dipole-dipole interaction between the second host compound and the compound as the doping material in the composition provided by the present invention, which was beneficial to reducing the energy difference between the singlet state and the triplet state of the doping material, could enhance the FORSTER energy transfer of the luminescent layer, was beneficial to the reverse inter-system crossing process of the doping material, and could thus improve the efficiency of the organic electroluminescent device. The hole and electron transport between the first host compound and the second host compound in the composition provided by the present invention was more balanced, so that the luminescence recombination region was located in the luminescent layer, and while reducing the driving voltage of the organic electroluminescent device, the efficiency of the organic electroluminescent device could be further improved. The overlap integral area between the first host compound and the compound as the doping material and the overlap integral area between the second host compound and the compound as the doping material as provided by the present invention were both relatively large, and the energy transmission between the host material and the doping material was sufficient, so that the efficiency of the organic electroluminescent device could be effectively improved. In the present invention, by means of the rational combination of the double host materials and the doping material, the interaction of the first host compound, the second host compound, and the compound as a doping material imparts the organic electroluminescent device with the significant advantages of a high efficiency and a long lifetime. The use of the composition provided by the present invention as the luminescent layer material could improve the luminous efficiency of a blue organic electroluminescent device, prolong the lifetime of the blue organic electroluminescent device and overcome the defects in the prior art.

The above description is only preferred embodiments of the present invention, and the scope of protection of the present invention is not limited thereto. Any changes, substitutions, etc. readily conceivable to any of those familiar with the technical field within the technical scope of the disclosure of the present invention should be included in the scope of protection of the present invention. Therefore, for the scope of protection of the present invention, the scope of protection of the claims shall prevail.

1. An organic compound, characterized in that the organic compound has a general structural formula as shown in Formula I: 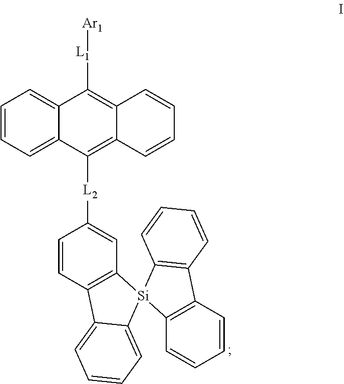
wherein Ar₁ is selected from a substituted or unsubstituted aryl group with a carbon atom number of 6 to 60 and a substituted or unsubstituted fused cyclic aryl group with a carbon atom number of 10 to 60;
L₁ and L₂ are each independently selected from a single bond and a substituted or unsubstituted arylene group with a carbon atom number of 6 to 30; and
when any one of Ar₁, L₁, and L₂ has substituents, Ar₁, L₁, or L₂ can have one or more substituents, and each of the substituents is independently selected from deuterium, an aryl group with a carbon atom number of 6 to 30, and a fused cyclic aryl group with a carbon atom number of 10 to 30.

2. The organic compound according to claim 1, characterized in that Ar₁ is selected from any one of or a combination of any two of phenyl, naphthyl, phenanthryl, pyrenyl, dimethylfluorenyl, and dimethylbenzofluorenyl.

3. The organic compound according to claim 1, characterized in that the organic compound is selected from any one of the following compounds:

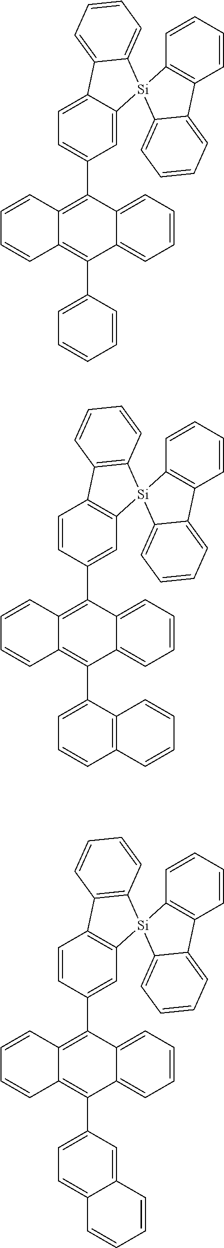 [SMILES: c1ccc(-c2c3ccccc3c(-c3ccc4c(c3)[Si]3(c5ccccc5-c5ccccc53)c3ccccc3-4)c3ccccc23)cc1 ; c1ccc2c(c1)-c1ccccc1[Si]21c2ccccc2-c2ccc(-c3c4ccccc4c(-c4cccc5ccccc45)c4ccccc34)cc21 ; c1ccc2c(c1)-c1ccccc1[Si]21c2ccccc2-c2ccc(-c3c4ccccc4c(-c4ccc5ccccc5c4)c4ccccc34)cc21]

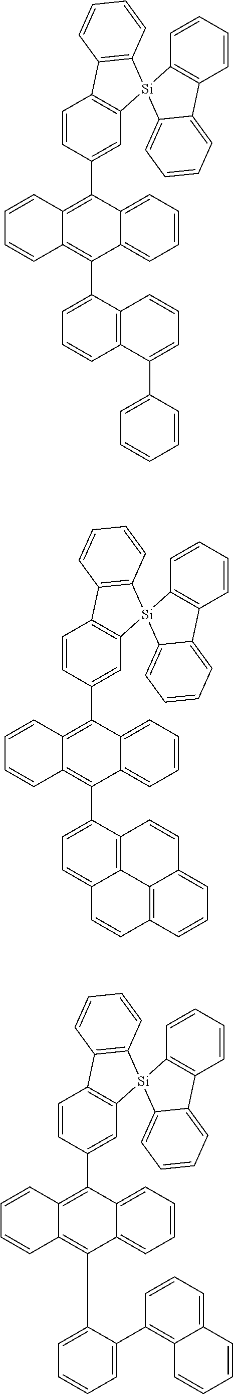 [SMILES: c1ccc(-c2cccc3c(-c4c5ccccc5c(-c5ccc6c(c5)[Si]5(c7ccccc7-c7ccccc75)c5ccccc5-6)c5ccccc45)cccc23)cc1 ; c1ccc2c(c1)-c1ccccc1[Si]21c2ccccc2-c2ccc(-c3c4ccccc4c(-c4ccc5ccc6cccc7ccc4c5c67)c4ccccc34)cc21 ; c1ccc(-c2c3ccccc3c(-c3ccc4c(c3)[Si]3(c5ccccc5-c5ccccc53)c3ccccc3-4)c3ccccc23)c(-c2cccc3ccccc23)c1]

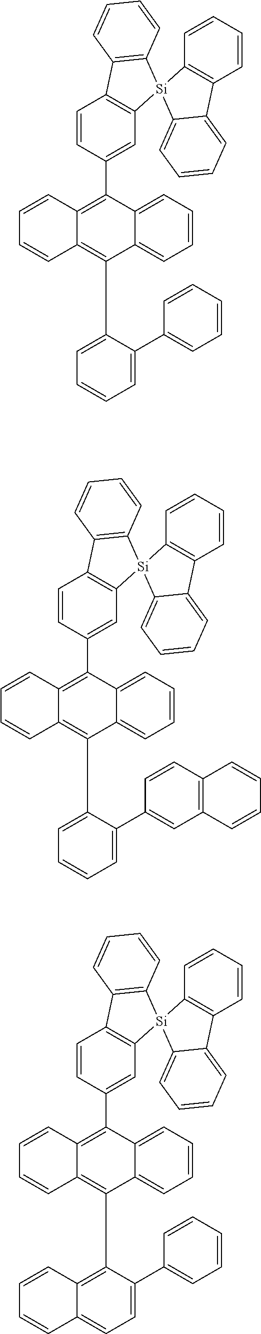 [SMILES: c1ccc(-c2ccccc2-c2c3ccccc3c(-c3ccc4c(c3)[Si]3(c5ccccc5-c5ccccc53)c3ccccc3-4)c3ccccc23)cc1 ; c1ccc(-c2c3ccccc3c(-c3ccc4c(c3)[Si]3(c5ccccc5-c5ccccc53)c3ccccc3-4)c3ccccc23)c(-c2ccc3ccccc3c2)c1 ; c1ccc(-c2ccc3ccccc3c2-c2c3ccccc3c(-c3ccc4c(c3)[Si]3(c5ccccc5-c5ccccc53)c3ccccc3-4)c3ccccc23)cc1]

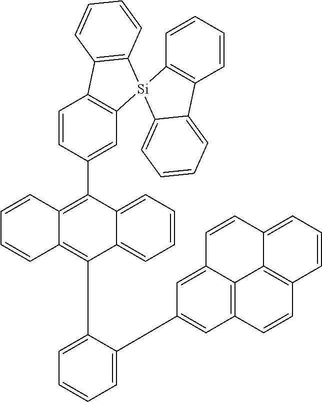 [SMILES: c1ccc(-c2c3ccccc3c(-c3ccc4c(c3)[Si]3(c5ccccc5-c5ccccc53)c3ccccc3-4)c3ccccc23)c(-c2cc3ccc4cccc5ccc(c2)c3c45)c1]

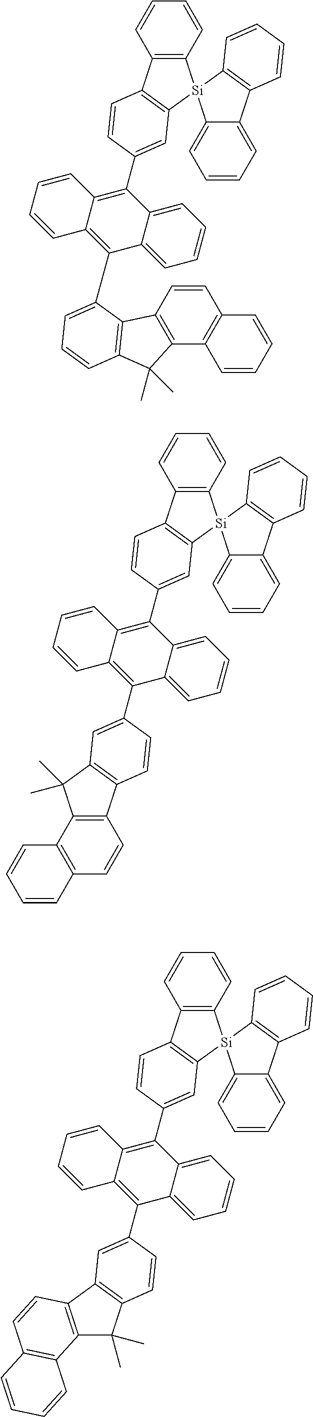

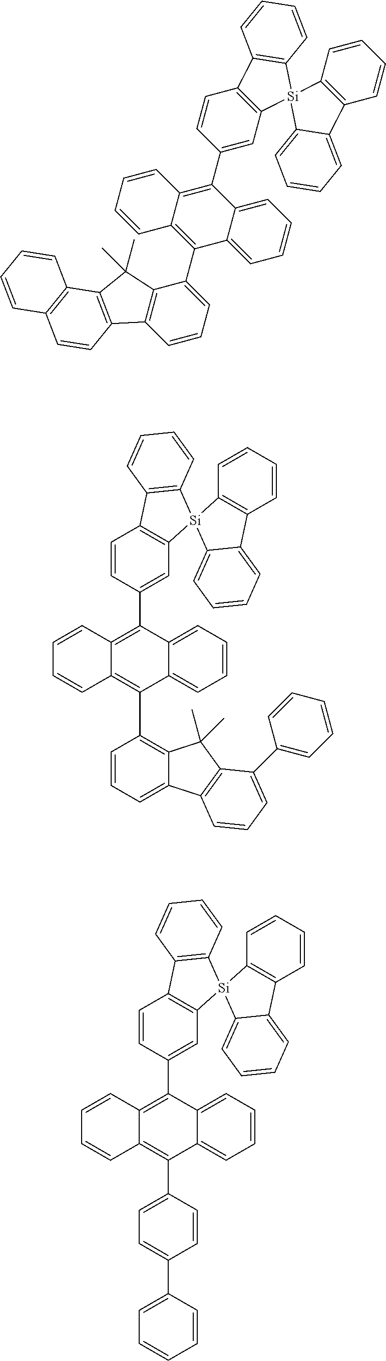 [SMILES: CC1(C)c2c(cccc2-c2c3ccccc3c(-c3ccc4c(c3)[Si]3(c5ccccc5-c5ccccc53)c3ccccc3-4)c3ccccc23)-c2ccc3ccccc3c21 ; CC1(C)c2c(-c3ccccc3)cccc2-c2cccc(-c3c4ccccc4c(-c4ccc5c(c4)[Si]4(c6ccccc6-c6ccccc64)c4ccccc4-5)c4ccccc34)c21 ; c1ccc(-c2ccc(-c3c4ccccc4c(-c4ccc5c(c4)[Si]4(c6ccccc6-c6ccccc64)c4ccccc4-5)c4ccccc34)cc2)cc1]

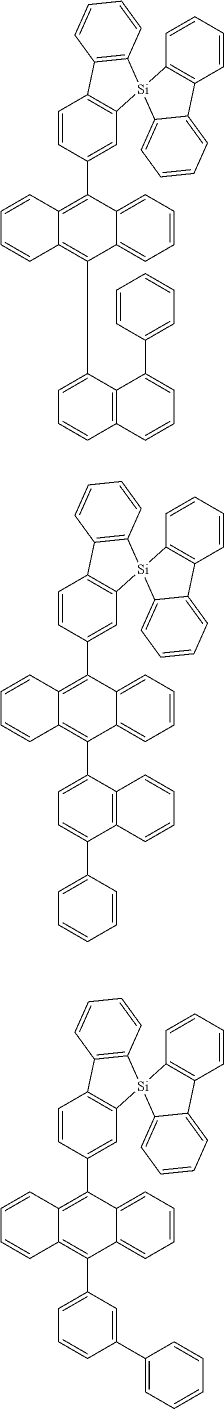

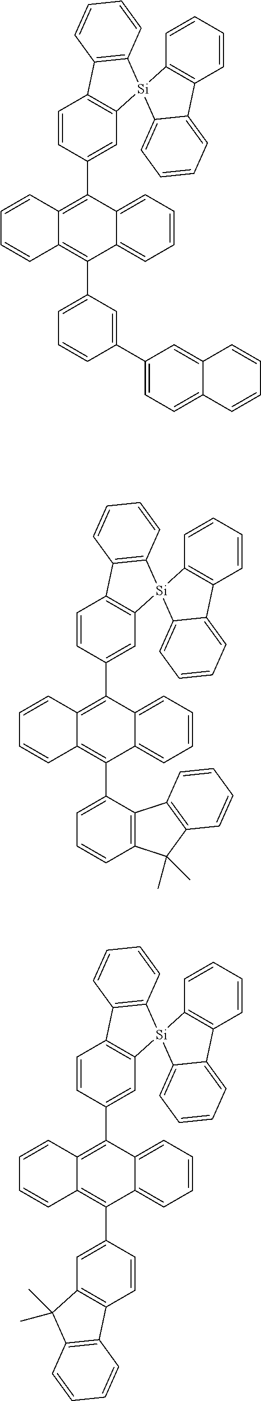 [SMILES: c1cc(-c2ccc3ccccc3c2)cc(-c2c3ccccc3c(-c3ccc4c(c3)[Si]3(c5ccccc5-c5ccccc53)c3ccccc3-4)c3ccccc23)c1 ; CC1(C)c2ccccc2-c2c(-c3c4ccccc4c(-c4ccc5c(c4)[Si]4(c6ccccc6-c6ccccc64)c4ccccc4-5)c4ccccc34)cccc21 ; CC1(C)c2ccccc2-c2ccc(-c3c4ccccc4c(-c4ccc5c(c4)[Si]4(c6ccccc6-c6ccccc64)c4ccccc4-5)c4ccccc34)cc21]

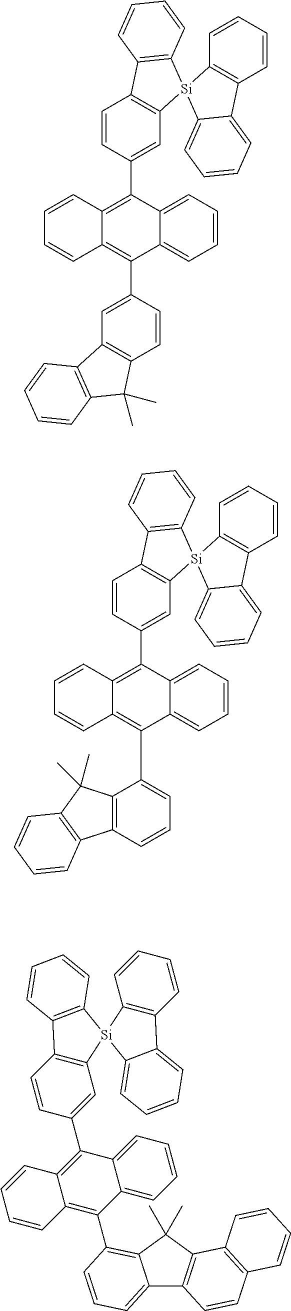 [SMILES: CC1(C)c2ccccc2-c2cc(-c3c4ccccc4c(-c4ccc5c(c4)[Si]4(c6ccccc6-c6ccccc64)c4ccccc4-5)c4ccccc34)ccc21 ; CC1(C)c2ccccc2-c2cccc(-c3c4ccccc4c(-c4ccc5c(c4)[Si]4(c6ccccc6-c6ccccc64)c4ccccc4-5)c4ccccc34)c21 ; CC1(C)c2c(cccc2-c2c3ccccc3c(-c3ccc4c(c3)[Si]3(c5ccccc5-c5ccccc53)c3ccccc3-4)c3ccccc23)-c2ccc3ccccc3c21]

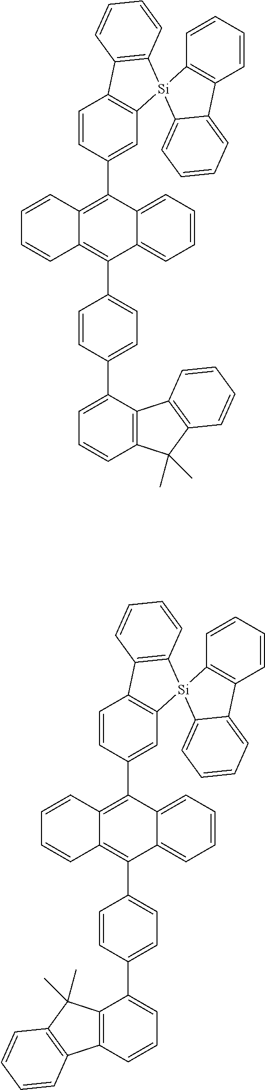 [SMILES: CC1(C)c2ccccc2-c2c(-c3ccc(-c4c5ccccc5c(-c5ccc6c(c5)[Si]5(c7ccccc7-c7ccccc75)c5ccccc5-6)c5ccccc45)cc3)cccc21 ; CC1(C)c2ccccc2-c2cccc(-c3ccc(-c4c5ccccc5c(-c5ccc6c(c5)[Si]5(c7ccccc7-c7ccccc75)c5ccccc5-6)c5ccccc45)cc3)c21]

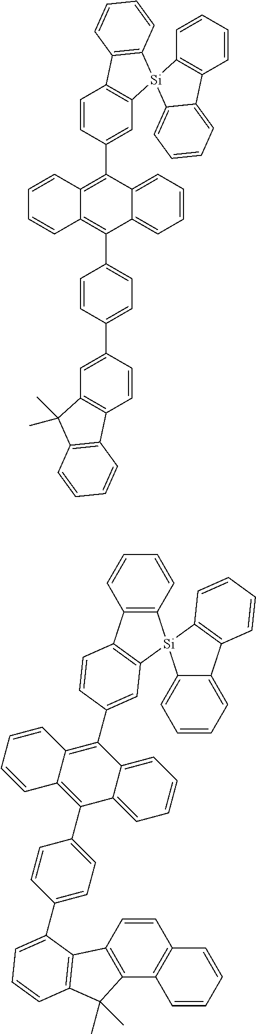 [SMILES: CC1(C)c2ccccc2-c2ccc(-c3ccc(-c4c5ccccc5c(-c5ccc6c(c5)[Si]5(c7ccccc7-c7ccccc75)c5ccccc5-6)c5ccccc45)cc3)cc21 ; CC1(C)c2cccc(-c3ccc(-c4c5ccccc5c(-c5ccc6c(c5)[Si]5(c7ccccc7-c7ccccc75)c5ccccc5-6)c5ccccc45)cc3)c2-c2ccc3ccccc3c21]

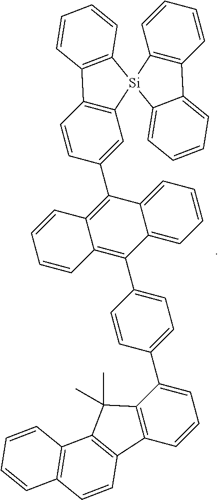 [SMILES: CC1(C)c2c(-c3ccc(-c4c5ccccc5c(-c5ccc6c(c5)[Si]5(c7ccccc7-c7ccccc75)c5ccccc5-6)c5ccccc45)cc3)cccc2-c2ccc3ccccc3c21]

4. A composition, characterized in that the composition comprises one or more organic compounds according to claim 1, and the composition further comprises one or more compounds represented by Formula II and one or more compounds represented by Formula III: 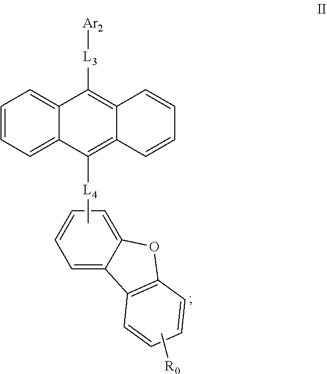
wherein Ar₂ is selected from a substituted or unsubstituted aryl group with a carbon atom number of 6 to 60 and a substituted or unsubstituted fused cyclic aryl group with a carbon atom number of 10 to 60;
R₀ represents a single substituent to the maximum allowable number of substituents, and each of the substituents is independently selected from hydrogen, deuterium, a substituted or unsubstituted alkyl group with a carbon atom number of 1 to 10, and a substituted or unsubstituted alkenyl group with a carbon atom number of 2 to 10, wherein two or more of the substituents can be bonded to each other via a linker group or a single bond to form a benzene ring or a fused ring;
L₃ and L₄ are each independently selected from a single bond and a substituted or unsubstituted arylene group with a carbon atom number of 6 to 30; and
when any one of Ar₂, R₀, L₃, and L₄ has substituents, Ar₂, R₀, L₃, or L₄ can have one or more substituents, and each of the substituents is independently selected from deuterium, an aryl group with a carbon atom number of 6 to 30, and a fused cyclic aryl group with a carbon atom number of 10 to 30; and 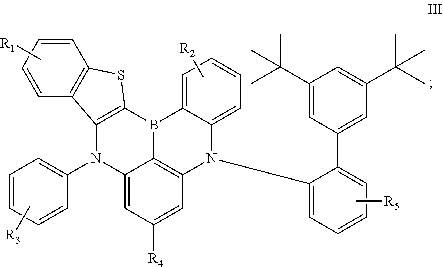
wherein R₁, R₂, R₃, and R₄ each independently represent a single substituent to the maximum allowable number of substituents, and each of the substituents is independently selected from any one of or a combination of any two or more of hydrogen, deuterium, a substituted or unsubstituted alkyl group with a carbon atom number of 1 to 10, a substituted or unsubstituted cycloalkyl group with a carbon atom number of 3 to 30, a substituted or unsubstituted aryl group with a carbon atom number of 6 to 30, and a substituted or unsubstituted arylamine group with a carbon atom number of 12 to 30, wherein two or more of the substituents can be bonded to each other via a linker group or a single bond to form an aliphatic ring, an aromatic ring, a heteroaromatic ring, a fused ring, or a fused heterocyclic ring;
R₅ represents a single substituent to the maximum allowable number of substituents, and each of the substituents is independently selected from hydrogen, deuterium, a substituted or unsubstituted alkyl group with a carbon atom number of 1 to 10, wherein two or more of the substituents can be bonded to each other via a linker group or a single bond to form an aliphatic ring, an aromatic ring, a heteroaromatic ring, a fused ring, or a fused heterocyclic ring; and
when any one of R₁, R₂, R₃, R₄, and R₅ has substituents, R₁, R₂, R₃, R₄, or R₅ can have one or more substituents, and each of the substituents is independently selected from any one of deuterium, an alkyl group with a carbon atom number of 1 to 10 and a cycloalkyl group with a carbon atom number of 3 to 30.

5. The composition according to claim 4, characterized in that the compound represented by Formula II is selected from any one of the following structures represented by Formulas II-1 to II-2: 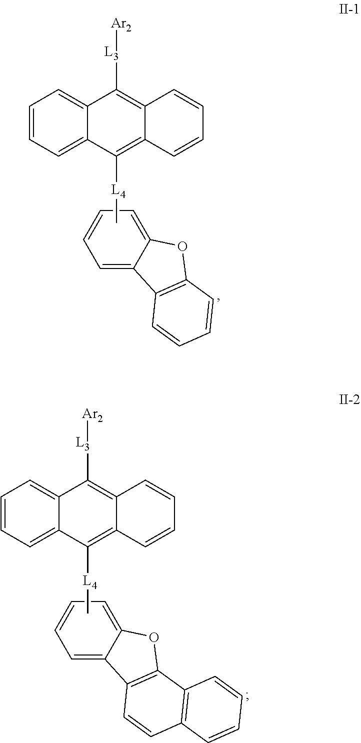
preferably, the compound represented by Formula II is selected from any one of the following compounds:

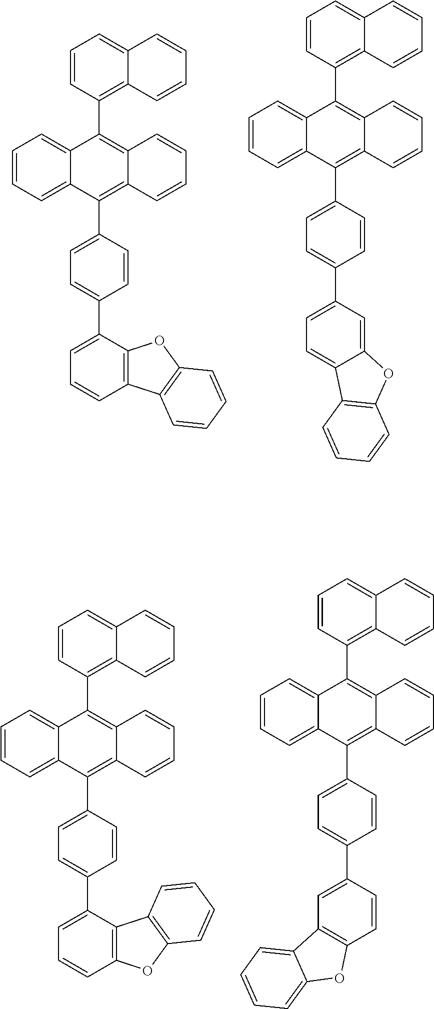 [SMILES: c1ccc2c(-c3c4ccccc4c(-c4ccc(-c5cccc6c5oc5ccccc56)cc4)c4ccccc34)cccc2c1 ; c1ccc2c(-c3c4ccccc4c(-c4ccc(-c5ccc6c(c5)oc5ccccc56)cc4)c4ccccc34)cccc2c1 ; c1ccc2c(-c3c4ccccc4c(-c4ccc(-c5cccc6oc7ccccc7c56)cc4)c4ccccc34)cccc2c1 ; c1ccc2c(-c3c4ccccc4c(-c4ccc(-c5ccc6oc7ccccc7c6c5)cc4)c4ccccc34)cccc2c1]

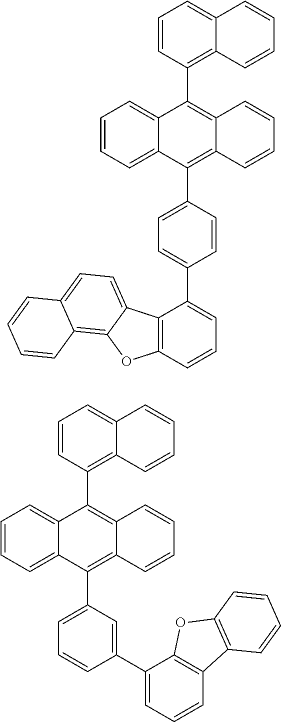 [SMILES: c1ccc2c(-c3c4ccccc4c(-c4ccc(-c5cccc6oc7c8ccccc8ccc7c56)cc4)c4ccccc34)cccc2c1 ; c1cc(-c2c3ccccc3c(-c3cccc4ccccc34)c3ccccc23)cc(-c2cccc3c2oc2ccccc23)c1]

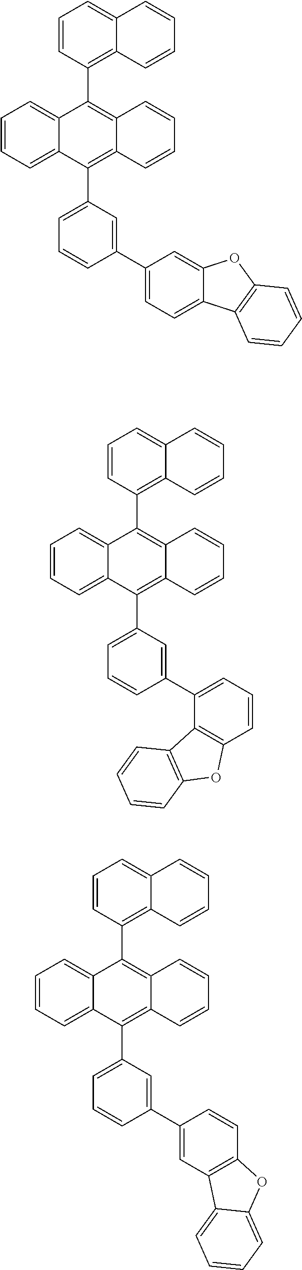 [SMILES: c1cc(-c2ccc3c(c2)oc2ccccc23)cc(-c2c3ccccc3c(-c3cccc4ccccc34)c3ccccc23)c1 ; c1cc(-c2c3ccccc3c(-c3cccc4ccccc34)c3ccccc23)cc(-c2cccc3oc4ccccc4c23)c1 ; c1cc(-c2ccc3oc4ccccc4c3c2)cc(-c2c3ccccc3c(-c3cccc4ccccc34)c3ccccc23)c1]

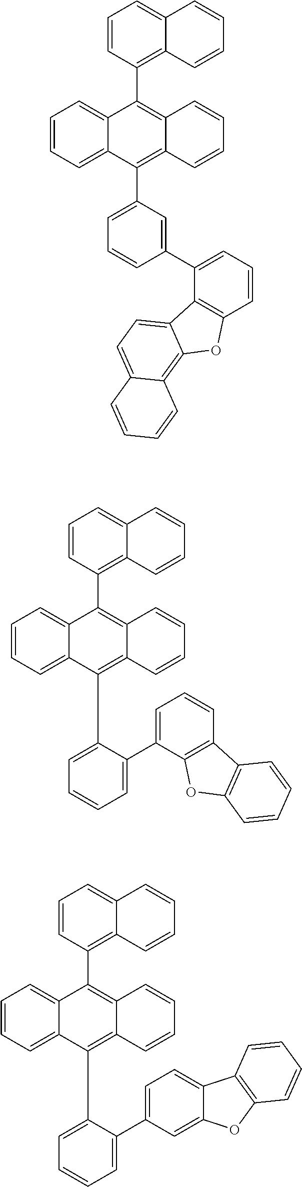 [SMILES: c1cc(-c2c3ccccc3c(-c3cccc4ccccc34)c3ccccc23)cc(-c2cccc3oc4c5ccccc5ccc4c23)c1 ; c1ccc(-c2cccc3c2oc2ccccc23)c(-c2c3ccccc3c(-c3cccc4ccccc34)c3ccccc23)c1 ; c1ccc(-c2c3ccccc3c(-c3cccc4ccccc34)c3ccccc23)c(-c2ccc3c(c2)oc2ccccc23)c1]

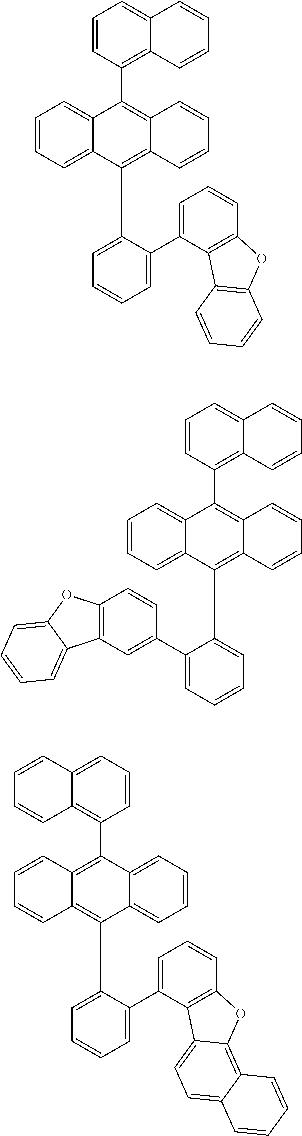 [SMILES: c1ccc(-c2cccc3oc4ccccc4c23)c(-c2c3ccccc3c(-c3cccc4ccccc34)c3ccccc23)c1 ; c1ccc(-c2c3ccccc3c(-c3cccc4ccccc34)c3ccccc23)c(-c2ccc3oc4ccccc4c3c2)c1 ; c1ccc(-c2cccc3oc4c5ccccc5ccc4c23)c(-c2c3ccccc3c(-c3cccc4ccccc34)c3ccccc23)c1]

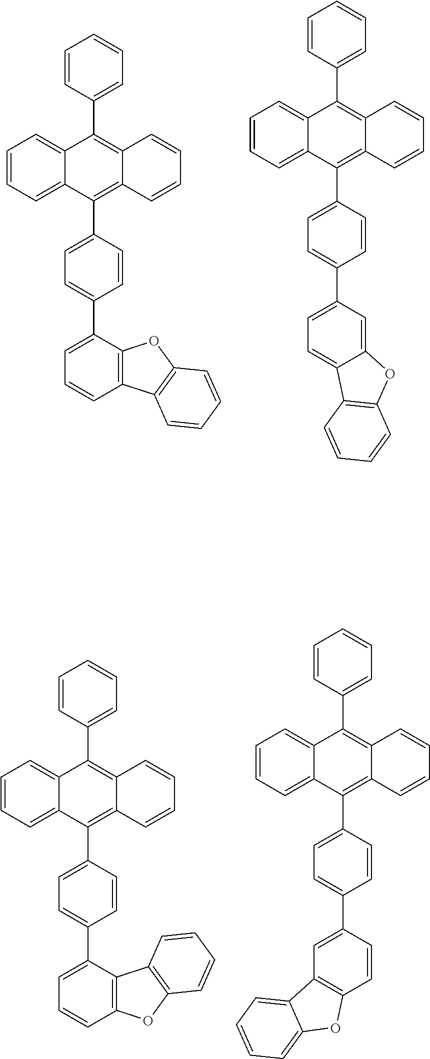 [SMILES: c1ccc(-c2c3ccccc3c(-c3ccc(-c4cccc5c4oc4ccccc45)cc3)c3ccccc23)cc1 ; c1ccc(-c2c3ccccc3c(-c3ccc(-c4ccc5c(c4)oc4ccccc45)cc3)c3ccccc23)cc1 ; c1ccc(-c2c3ccccc3c(-c3ccc(-c4cccc5oc6ccccc6c45)cc3)c3ccccc23)cc1 ; c1ccc(-c2c3ccccc3c(-c3ccc(-c4ccc5oc6ccccc6c5c4)cc3)c3ccccc23)cc1]

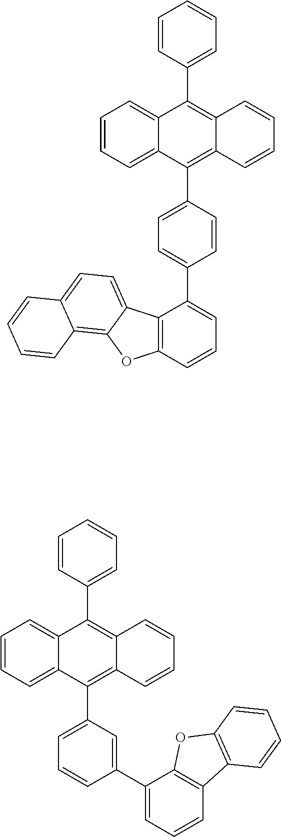 [SMILES: c1ccc(-c2c3ccccc3c(-c3ccc(-c4cccc5oc6c7ccccc7ccc6c45)cc3)c3ccccc23)cc1 ; c1ccc(-c2c3ccccc3c(-c3cccc(-c4cccc5c4oc4ccccc45)c3)c3ccccc23)cc1]

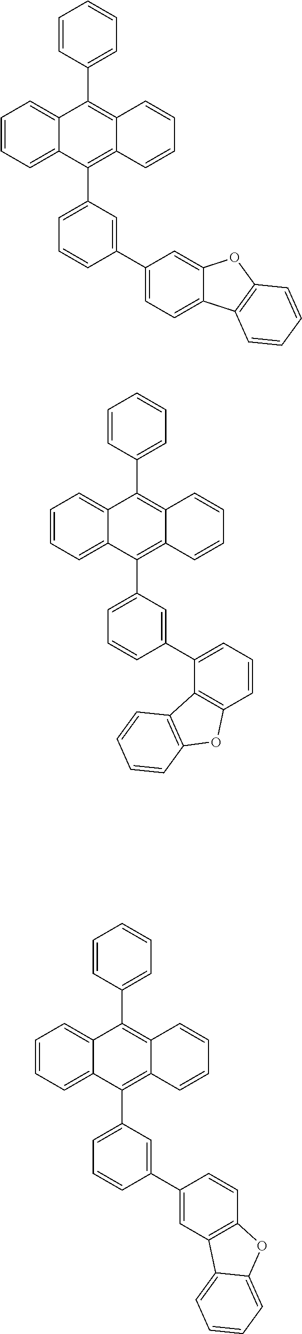 [SMILES: c1ccc(-c2c3ccccc3c(-c3cccc(-c4ccc5c(c4)oc4ccccc45)c3)c3ccccc23)cc1 ; c1ccc(-c2c3ccccc3c(-c3cccc(-c4cccc5oc6ccccc6c45)c3)c3ccccc23)cc1 ; c1ccc(-c2c3ccccc3c(-c3cccc(-c4ccc5oc6ccccc6c5c4)c3)c3ccccc23)cc1]

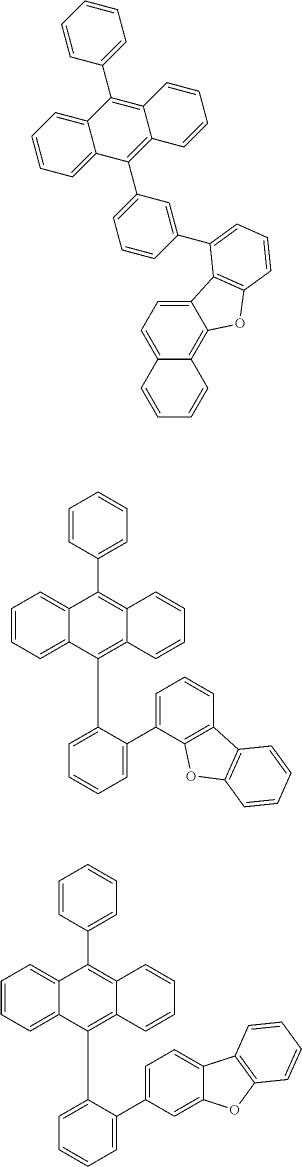 [SMILES: c1ccc(-c2c3ccccc3c(-c3cccc(-c4cccc5oc6c7ccccc7ccc6c45)c3)c3ccccc23)cc1 ; c1ccc(-c2c3ccccc3c(-c3ccccc3-c3cccc4c3oc3ccccc34)c3ccccc23)cc1 ; c1ccc(-c2c3ccccc3c(-c3ccccc3-c3ccc4c(c3)oc3ccccc34)c3ccccc23)cc1]

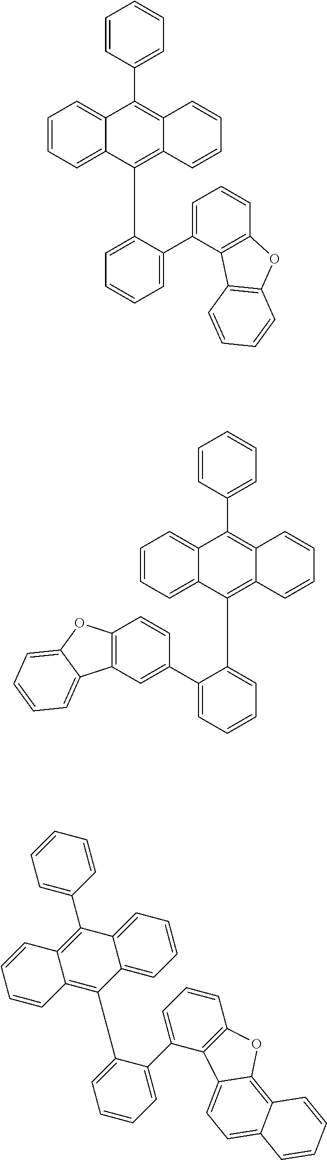 [SMILES: c1ccc(-c2c3ccccc3c(-c3ccccc3-c3cccc4oc5ccccc5c34)c3ccccc23)cc1 ; c1ccc(-c2c3ccccc3c(-c3ccccc3-c3ccc4oc5ccccc5c4c3)c3ccccc23)cc1 ; c1ccc(-c2c3ccccc3c(-c3ccccc3-c3cccc4oc5c6ccccc6ccc5c34)c3ccccc23)cc1]

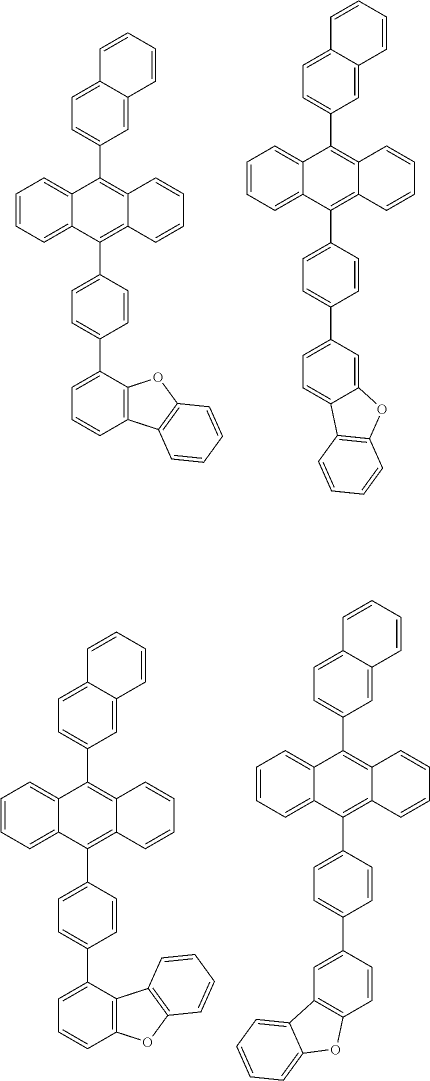 [SMILES: c1ccc2cc(-c3c4ccccc4c(-c4ccc(-c5cccc6c5oc5ccccc56)cc4)c4ccccc34)ccc2c1 ; c1ccc2cc(-c3c4ccccc4c(-c4ccc(-c5ccc6c(c5)oc5ccccc56)cc4)c4ccccc34)ccc2c1 ; c1ccc2cc(-c3c4ccccc4c(-c4ccc(-c5cccc6oc7ccccc7c56)cc4)c4ccccc34)ccc2c1 ; c1ccc2cc(-c3c4ccccc4c(-c4ccc(-c5ccc6oc7ccccc7c6c5)cc4)c4ccccc34)ccc2c1]

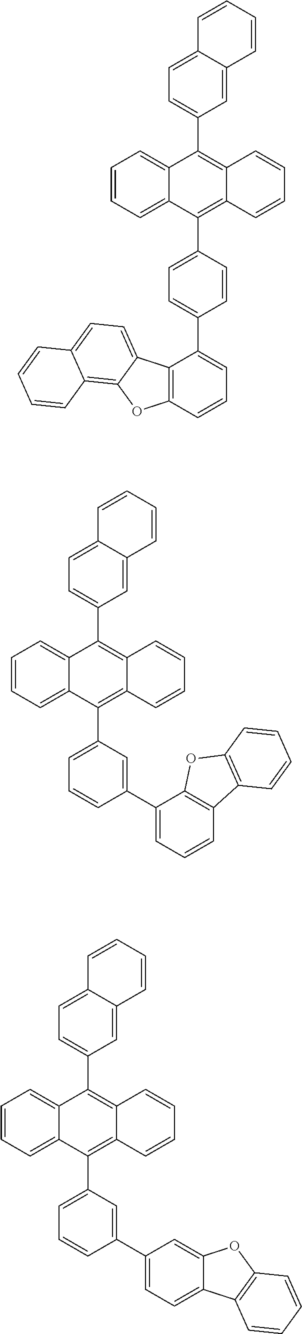 [SMILES: c1ccc2cc(-c3c4ccccc4c(-c4ccc(-c5cccc6oc7c8ccccc8ccc7c56)cc4)c4ccccc34)ccc2c1 ; c1cc(-c2c3ccccc3c(-c3ccc4ccccc4c3)c3ccccc23)cc(-c2cccc3c2oc2ccccc23)c1 ; c1cc(-c2ccc3c(c2)oc2ccccc23)cc(-c2c3ccccc3c(-c3ccc4ccccc4c3)c3ccccc23)c1]

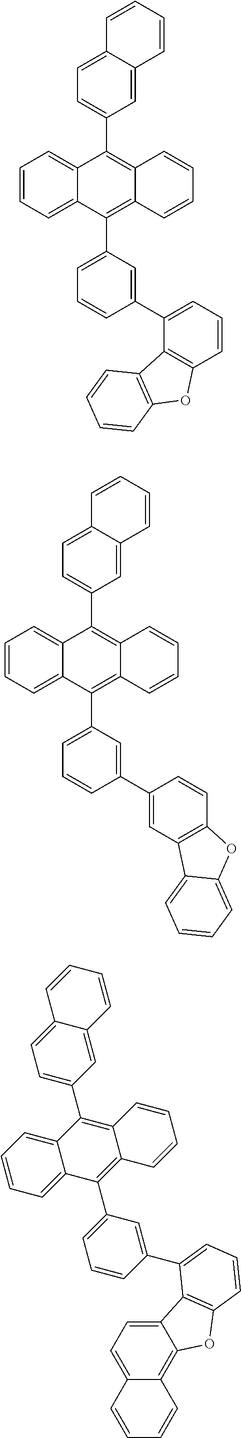 [SMILES: c1cc(-c2c3ccccc3c(-c3ccc4ccccc4c3)c3ccccc23)cc(-c2cccc3oc4ccccc4c23)c1 ; c1cc(-c2ccc3oc4ccccc4c3c2)cc(-c2c3ccccc3c(-c3ccc4ccccc4c3)c3ccccc23)c1 ; c1cc(-c2c3ccccc3c(-c3ccc4ccccc4c3)c3ccccc23)cc(-c2cccc3oc4c5ccccc5ccc4c23)c1]

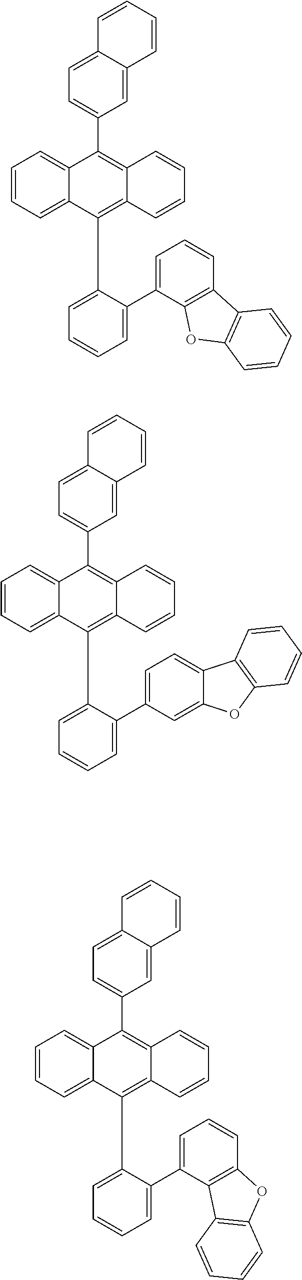 [SMILES: c1ccc(-c2cccc3c2oc2ccccc23)c(-c2c3ccccc3c(-c3ccc4ccccc4c3)c3ccccc23)c1 ; c1ccc(-c2c3ccccc3c(-c3ccc4ccccc4c3)c3ccccc23)c(-c2ccc3c(c2)oc2ccccc23)c1 ; c1ccc(-c2cccc3oc4ccccc4c23)c(-c2c3ccccc3c(-c3ccc4ccccc4c3)c3ccccc23)c1]

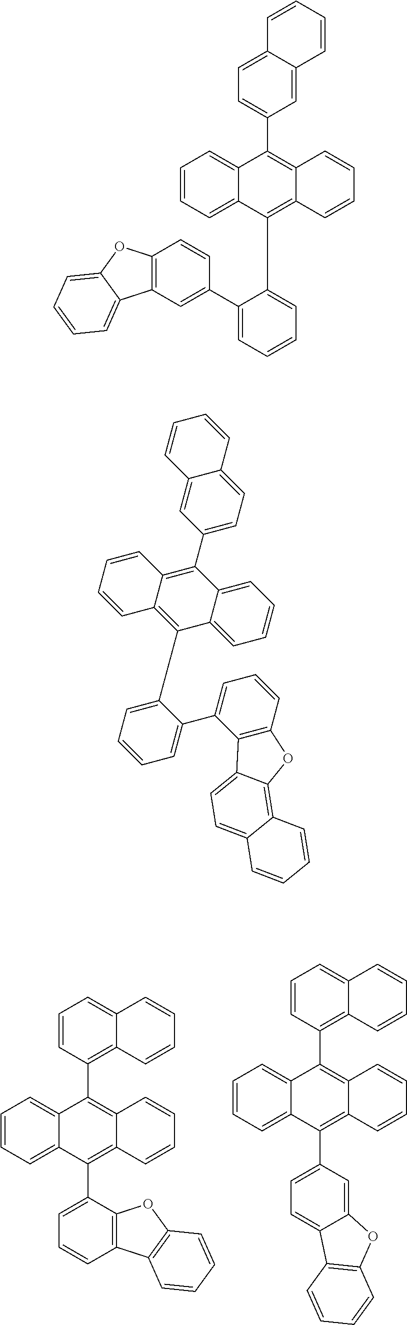 [SMILES: c1ccc(-c2c3ccccc3c(-c3ccc4ccccc4c3)c3ccccc23)c(-c2ccc3oc4ccccc4c3c2)c1 ; c1ccc(-c2cccc3oc4c5ccccc5ccc4c23)c(-c2c3ccccc3c(-c3ccc4ccccc4c3)c3ccccc23)c1 ; c1ccc2c(-c3c4ccccc4c(-c4cccc5c4oc4ccccc45)c4ccccc34)cccc2c1 ; c1ccc2c(-c3c4ccccc4c(-c4ccc5c(c4)oc4ccccc45)c4ccccc34)cccc2c1]

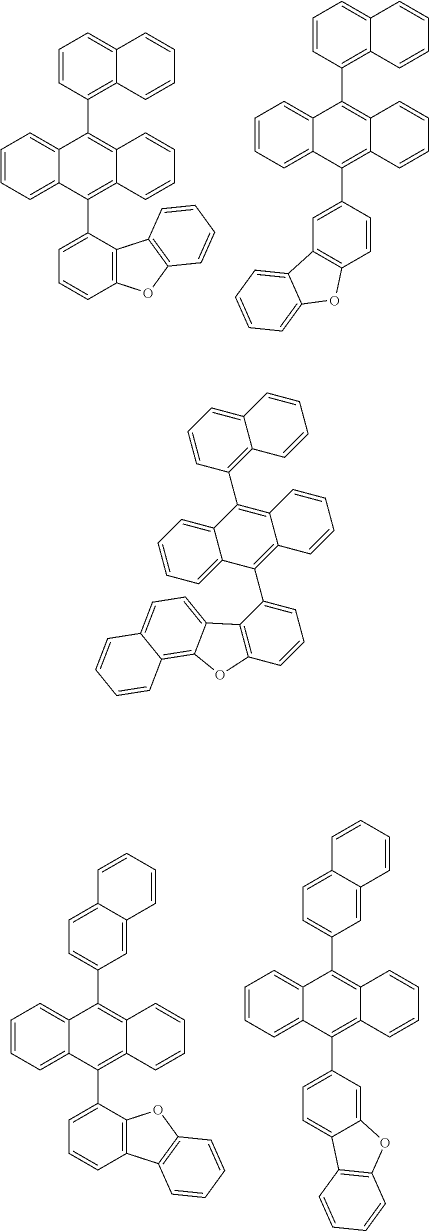 [SMILES: c1ccc2c(-c3c4ccccc4c(-c4cccc5oc6ccccc6c45)c4ccccc34)cccc2c1 ; c1ccc2c(-c3c4ccccc4c(-c4ccc5oc6ccccc6c5c4)c4ccccc34)cccc2c1 ; c1ccc2c(-c3c4ccccc4c(-c4cccc5oc6c7ccccc7ccc6c45)c4ccccc34)cccc2c1 ; c1ccc2cc(-c3c4ccccc4c(-c4cccc5c4oc4ccccc45)c4ccccc34)ccc2c1 ; c1ccc2cc(-c3c4ccccc4c(-c4ccc5c(c4)oc4ccccc45)c4ccccc34)ccc2c1]

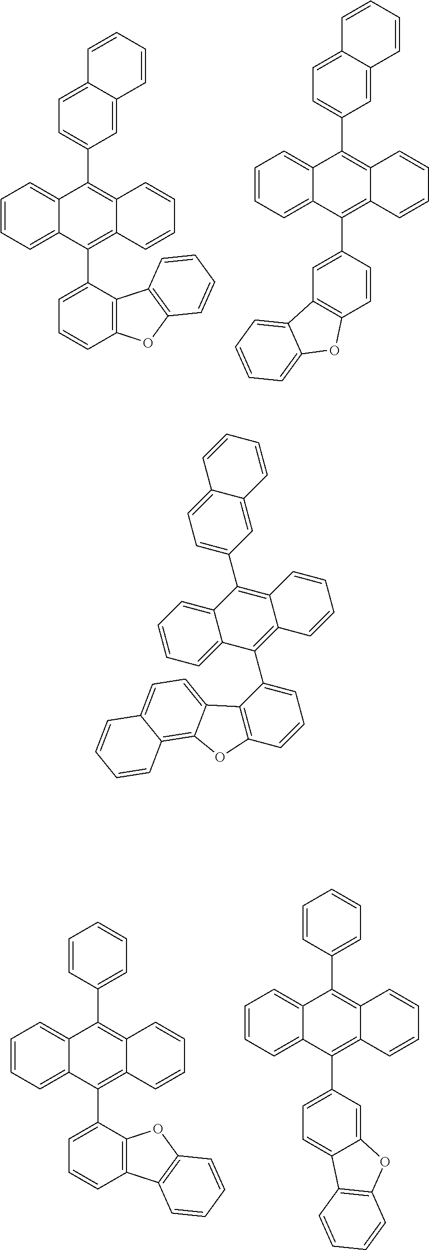 [SMILES: c1ccc2cc(-c3c4ccccc4c(-c4cccc5oc6ccccc6c45)c4ccccc34)ccc2c1 ; c1ccc2cc(-c3c4ccccc4c(-c4ccc5oc6ccccc6c5c4)c4ccccc34)ccc2c1 ; c1ccc2cc(-c3c4ccccc4c(-c4cccc5oc6c7ccccc7ccc6c45)c4ccccc34)ccc2c1 ; c1ccc(-c2c3ccccc3c(-c3cccc4c3oc3ccccc34)c3ccccc23)cc1 ; c1ccc(-c2c3ccccc3c(-c3ccc4c(c3)oc3ccccc34)c3ccccc23)cc1]

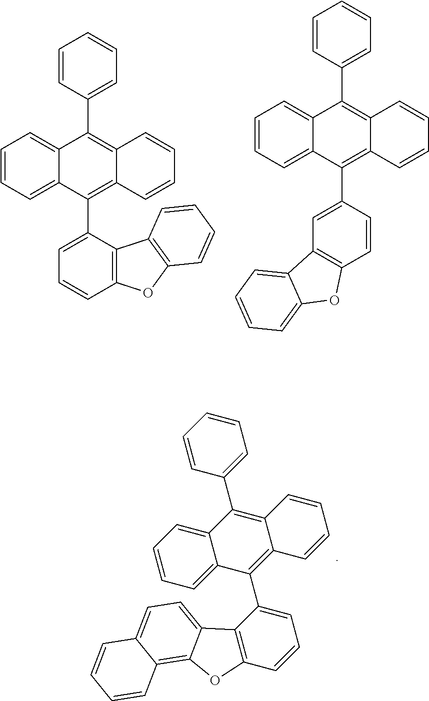 [SMILES: c1ccc(-c2c3ccccc3c(-c3cccc4oc5ccccc5c34)c3ccccc23)cc1 ; c1ccc(-c2c3ccccc3c(-c3ccc4oc5ccccc5c4c3)c3ccccc23)cc1 ; c1ccc(-c2c3ccccc3c(-c3cccc4oc5c6ccccc6ccc5c34)c3ccccc23)cc1]

6. The composition according to claim 4, characterized in that the compound represented by Formula III is selected from any one of the following structures represented by Formulas III-1 to III-2:

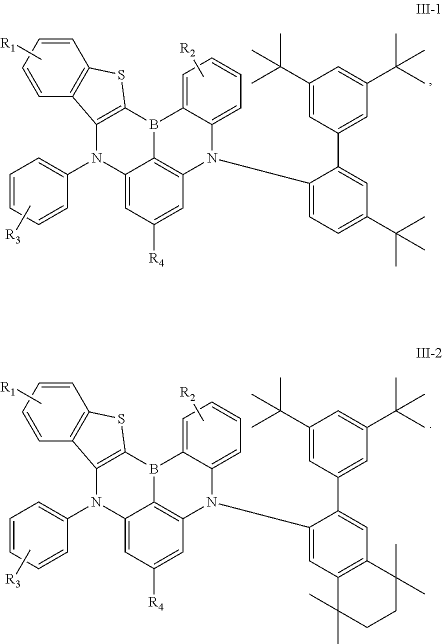

7. The composition according to claim 4, characterized in that the compound represented by Formula III is selected from any one of the following compounds:

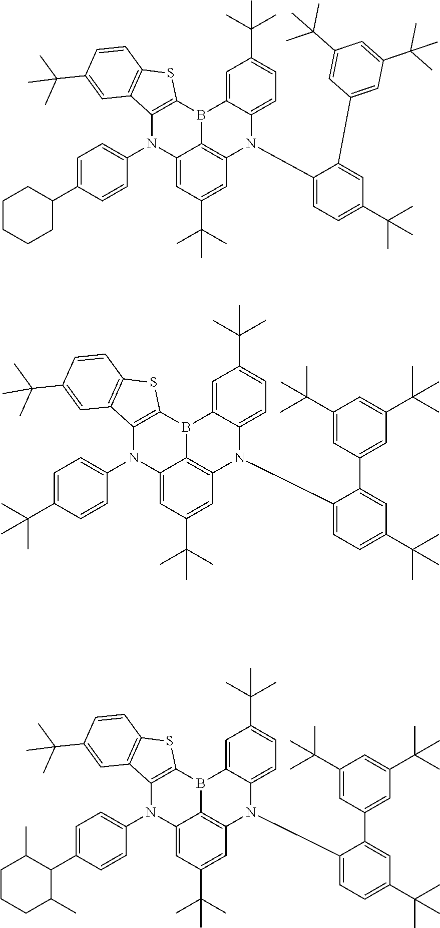

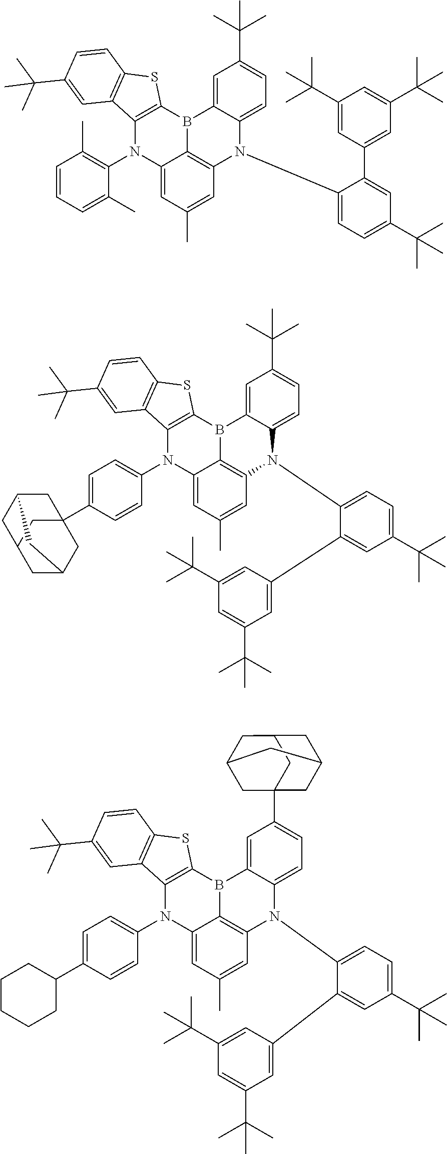

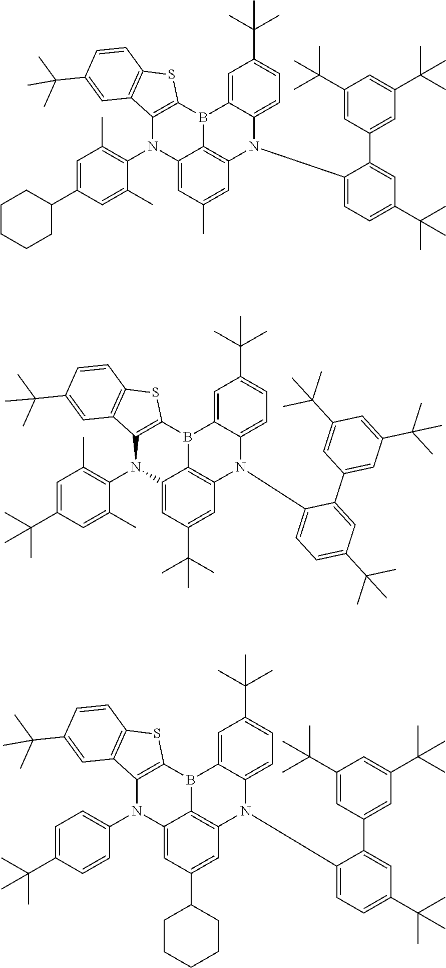

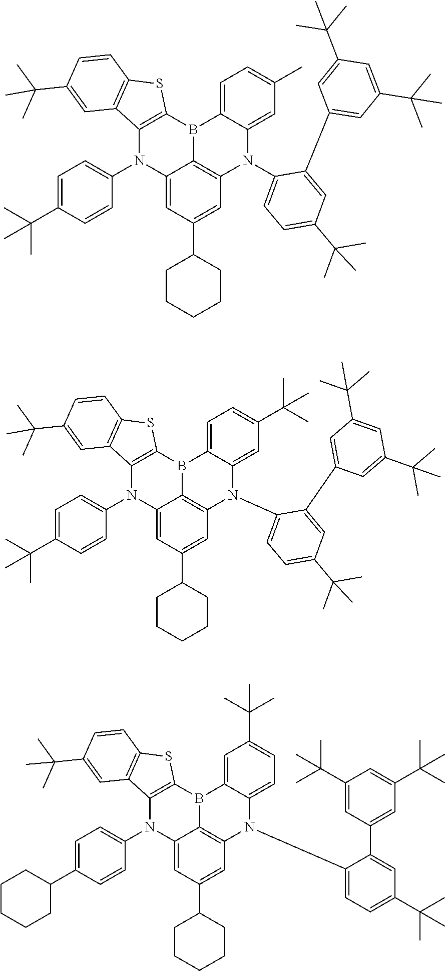

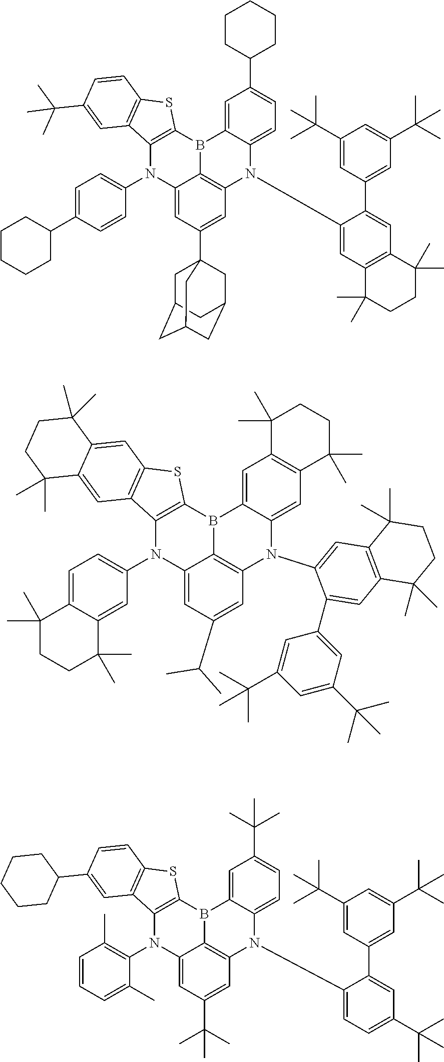

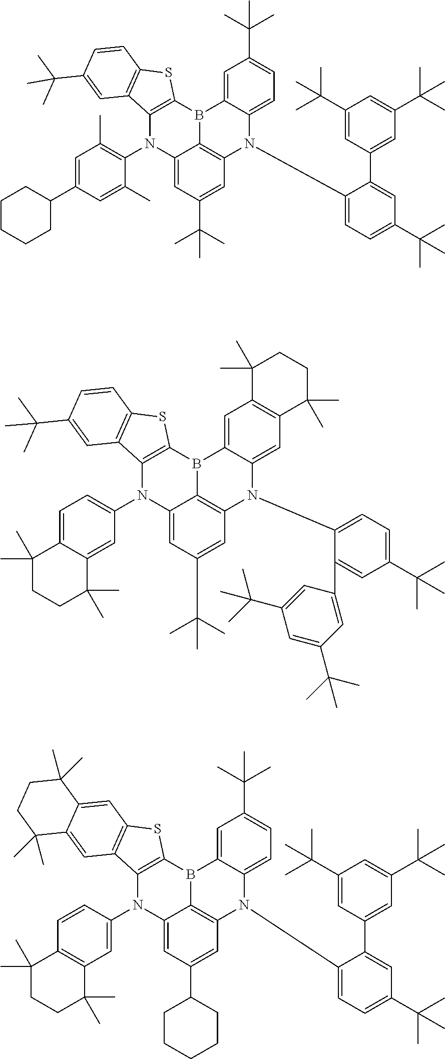

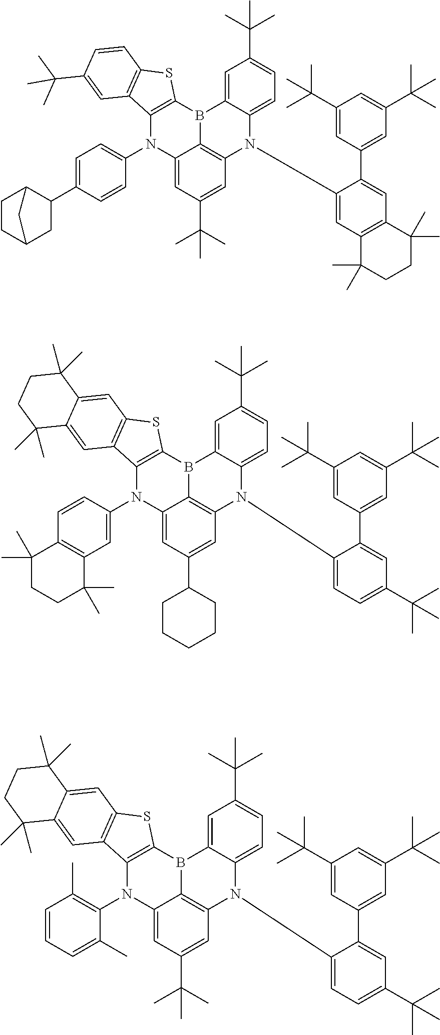

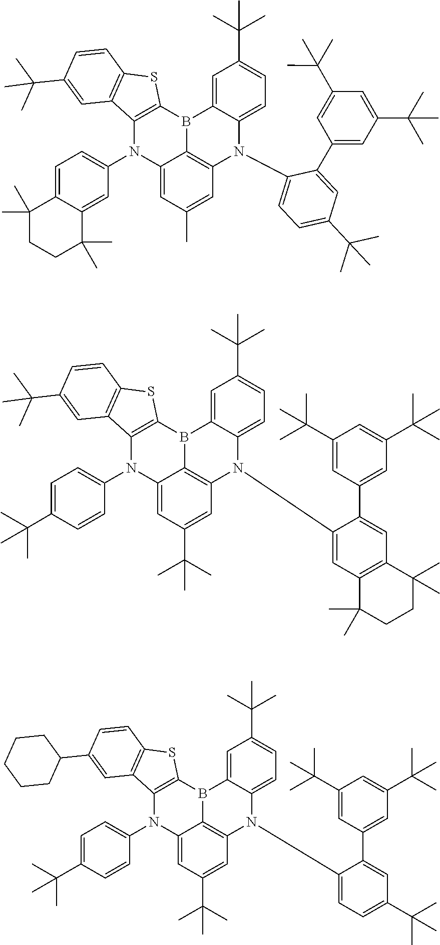

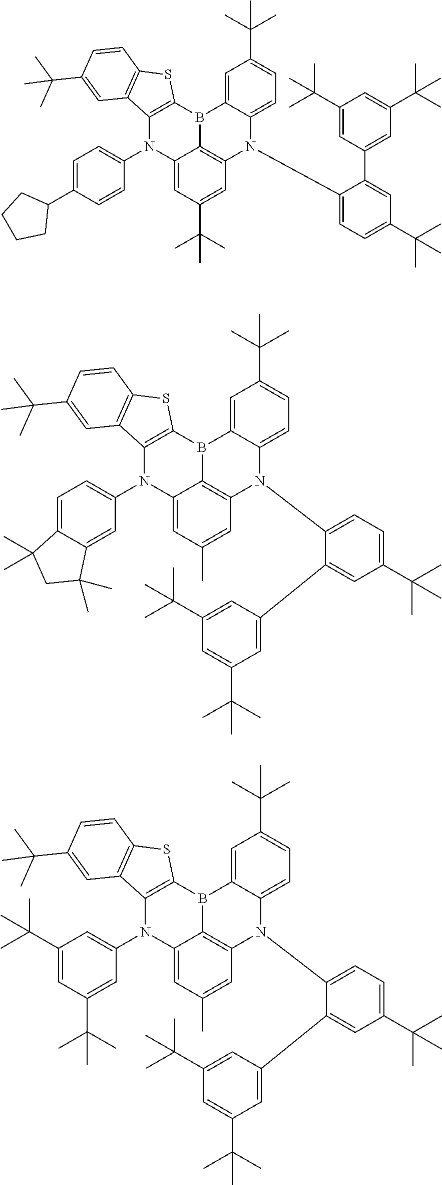

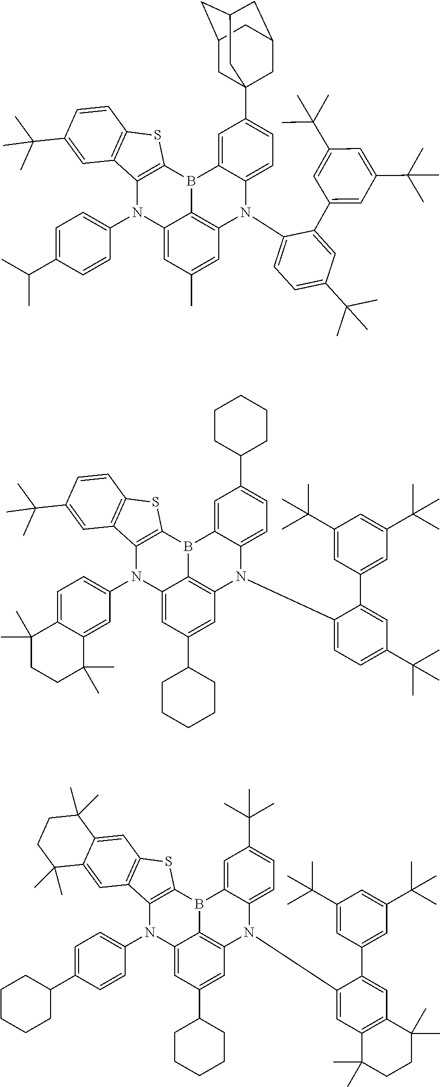

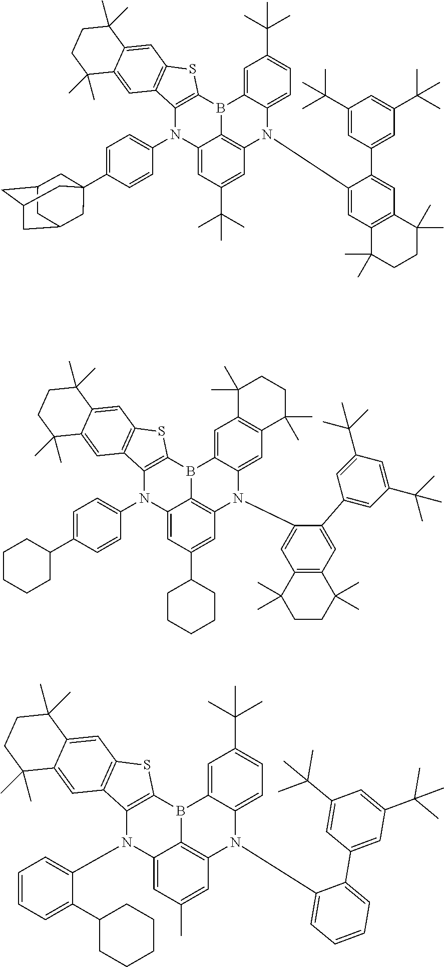

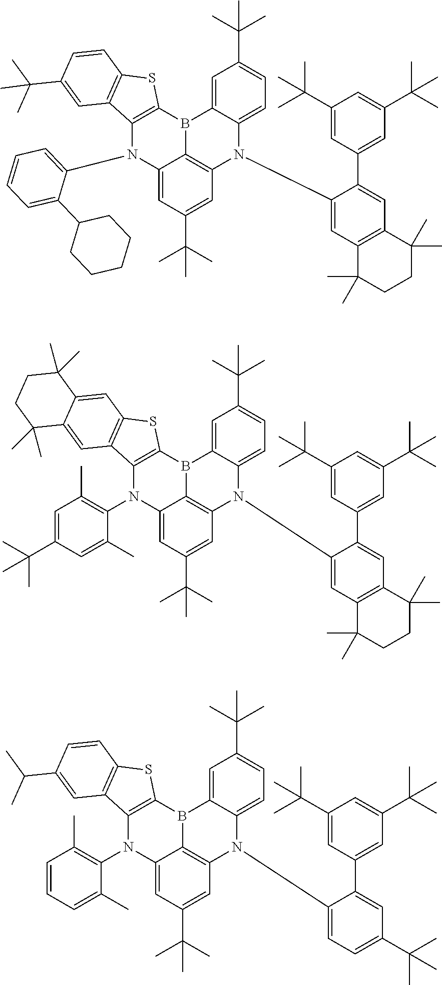

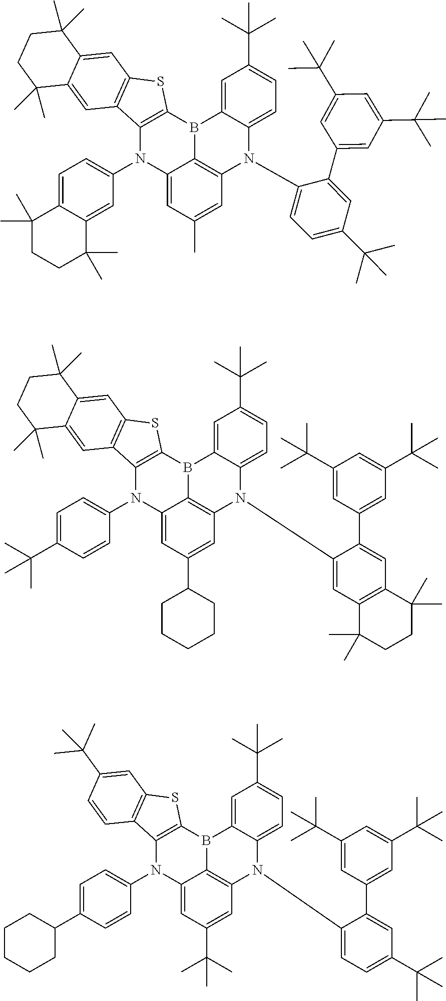

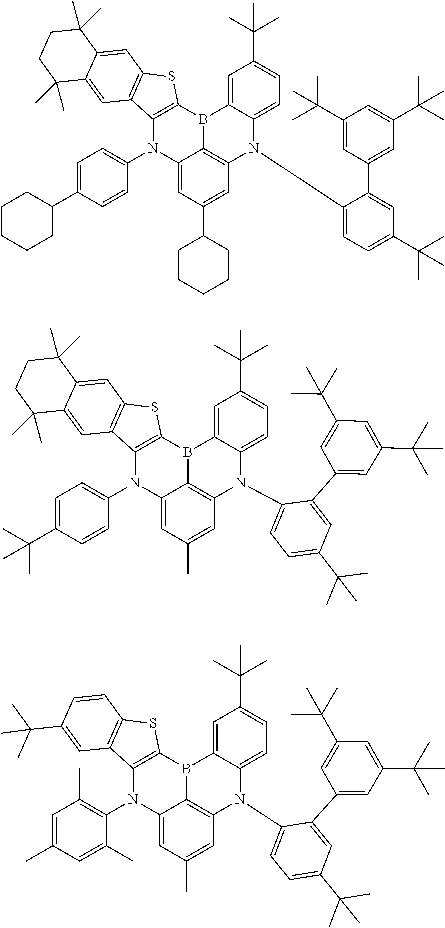

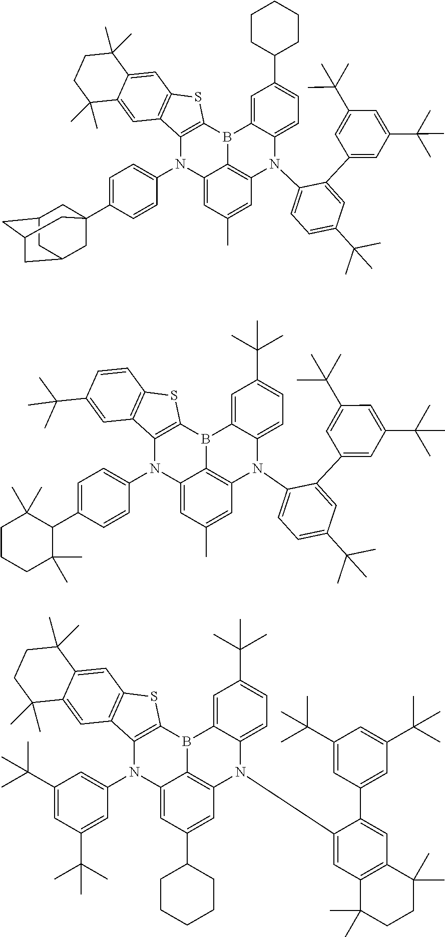

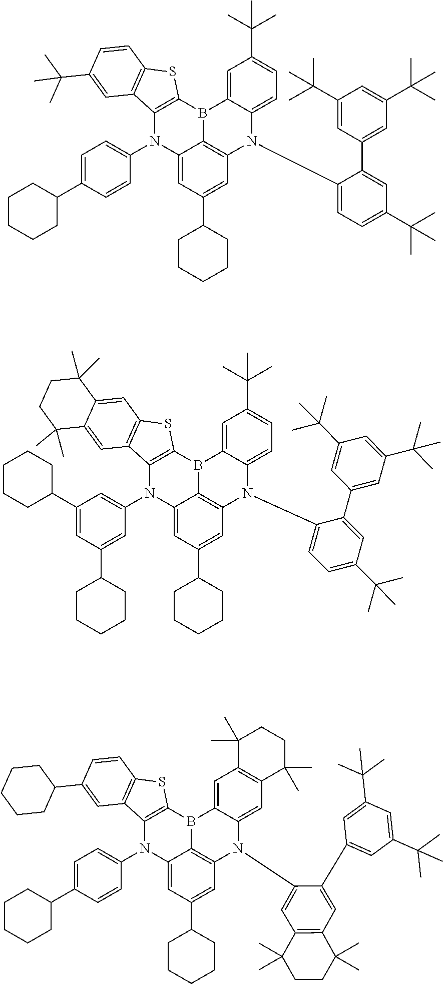 [SMILES: CC(C)(C)c1cc(-c2cc(C(C)(C)C)ccc2N2c3ccc(C(C)(C)C)cc3B3c4sc5ccc(C(C)(C)C)cc5c4N(c4ccc(C5CCCCC5)cc4)c4cc(C5CCCCC5)cc2c43)cc(C(C)(C)C)c1 ; CC(C)(C)c1cc(-c2cc(C(C)(C)C)ccc2N2c3ccc(C(C)(C)C)cc3B3c4sc5cc6c(cc5c4N(c4cc(C5CCCCC5)cc(C5CCCCC5)c4)c4cc(C5CCCCC5)cc2c43)C(C)(C)CCC6(C)C)cc(C(C)(C)C)c1 ; CC(C)(C)c1cc(-c2cc3c(cc2N2c4cc5c(cc4B4c6sc7ccc(C8CCCCC8)cc7c6N(c6ccc(C7CCCCC7)cc6)c6cc(C7CCCCC7)cc2c64)C(C)(C)CCC5(C)C)C(C)(C)CCC3(C)C)cc(C(C)(C)C)c1]

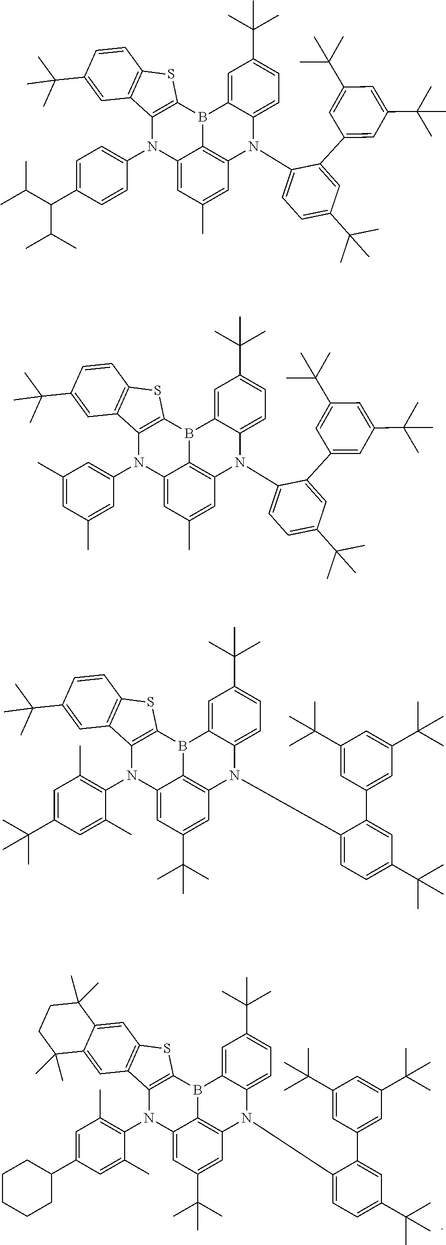

8. Use of the composition according to claim 4 as a luminescent layer material.

9. An organic electroluminescent device, characterized by comprising sequentially a first electrode disposed on a substrate plate, a second electrode disposed opposite to the first electrode, and one or more organic functional layers disposed between the first electrode and the second electrode,
wherein the organic functional layer comprises a luminescent layer comprising the composition according to claim 4.

10. The organic electroluminescent device according to claim 9, characterized in that the luminescent layer comprises a host material and a doping material, wherein the host material comprises one or more compounds represented by Chemical Formula I and one or more compounds represented by Chemical Formula II, and the doping material comprises one or more compounds represented by chemical formula III.
